(19) United States
(12) Patent Application Publication
(10) Pub. No.: US 2024/0260228 A1
(43) Pub. Date: Aug. 1, 2024

(54) IMMERSION COOLING SYSTEMS, APPARATUS, AND RELATED METHODS

(71) Applicant: Intel Corporation, Santa Clara, CA (US)

(72) Inventors: Jimmy Chuang, Taipei (TW); Jin Yang, Hillsboro, OR (US); Yuan-Liang Li, Taipei (TW); David Shia, Portland, OR (US); Yuehong Fan, Shanghai (CN); Hao Zhou, Shanghai (CN); Sandeep Ahuja, Portland, OR (US); Peng Wei, Shanghai (CN); Ming Zhang, Shanghai (CN); Je-Young Chang, Tempe, AZ (US); Paul J. Gwin, Orangevale, CA (US); Ra'anan Sover, Tirat Carmel (IL); Lianchang Du, Kunshan (CN); Eric D. McAfee, Portland, OR (US); Timothy Glen Hanna, Tigard, OR (US); Liguang Du, Shanghai (CN); Qing Jiang, Shanghai (CN); Xicai Jing, Shanghai (CN); Liu Yu, Shanghai (CN); Guoliang Ying, Shanghai (CN); Cong Zhou, Shanghai (CN); Yinglei Ren, Shanghai (CN); Xinfeng Wang, Shanghai (CN)

(21) Appl. No.: 18/565,916

(22) PCT Filed: Apr. 1, 2022
(86) PCT No.: PCT/US2022/023148

§ 371 Date: Nov. 30, 2023

(30) Foreign Application Priority Data
Dec. 24, 2021 (WO) PCT/CN2021/141155

(51) Int. Cl. H05K 7/20

(52) U.S. Cl. CPC H05K 7/20236; H05K 7/20254; H05K 7/20263; H05K 7/20463

(57) ABSTRACT

Immersion cooling systems, apparatus, and related methods for cooling electronic computing platforms and/or associated electronic components are disclosed herein. An example apparatus includes a first chamber including a first coolant disposed therein, the first coolant having a first boiling point. The example apparatus further includes a second chamber disposed in the first chamber, the second chamber to receive an electronic component therein. The second chamber includes a second coolant having a second boiling point different that the first boiling point. The second chamber is to separate the electronic component and the second coolant from the first coolant.

### RELATED APPLICATION

This patent claims the benefit of International Patent Application No. PCT/CN2021/141155, which was filed on Dec. 24, 2021. International Patent Application No. PCT/CN2021/141155 is hereby incorporated herein by reference in its entirety. Priority to International Patent Application No. PCT/CN2021/141155 is hereby claimed.

### FIELD OF THE DISCLOSURE

This disclosure relates generally to cooling systems and, more particularly, to immersion cooling systems, apparatus, and related methods.

### BACKGROUND

The use of liquids to cool electronic components is being explored for its benefits over more traditional air cooling systems, as there is an increasing need to address thermal management risks resulting from increased thermal design power in high performance systems (e.g., CPU and/or GPU servers in data centers, cloud computing, edge computing, and the like). More particularly, relative to air, liquid has inherent advantages of higher specific heat (when no boiling is involved) and higher latent heat of vaporization (when boiling is involved).

### BRIEF DESCRIPTION OF THE DRAWINGS

FIG. 1 illustrates one or more example environments in which teachings of this disclosure may be implemented.

FIG. 2A illustrates an example immersion cooling system constructed in accordance with teachings of this disclosure.

FIG. 2B illustrates another example immersion cooling system constructed in accordance with teaching of this disclosure.

FIG. 2C is a block diagram of the example control system circuitry in accordance with teachings of this disclosure.

FIG. 3 is a flowchart representative of example machine readable instructions and/or example operations that may be executed and/or instantiated by processor circuitry to control the example cooling systems of FIGS. 2A and/or 2B.

FIG. 4 illustrates another example immersion cooling system constructed in accordance with teachings of this disclosure.

FIGS. 5 and 6 illustrate a first example modular immersion cooling system in accordance with teachings of this disclosure.

FIGS. 7 and 8 illustrate a second example modular immersion cooling system in accordance with teachings of this disclosure.

FIGS. 9 and 10 illustrate a third example modular immersion cooling system in accordance with teachings of this disclosure.

FIG. 11 illustrates an example system including lock control circuitry for providing selective access to an immersion tank and/or an environment in which the immersion tank is located in accordance with teachings of this disclosure.

FIG. 12 is a block diagram of the example lock control circuitry of FIG. 11.

FIG. 13 is a flowchart representative of example machine readable instructions and/or example operations that may be executed and/or instantiated by processor circuitry to control access to an immersion tank and/or an environment in which the immersion tank is located.

FIG. 14 illustrates an example server in accordance with teaching of this disclosure.

FIG. 15 is a side view of the example server of FIG. 14.

FIG. 16 illustrates an example storage/memory sled of the example server of FIG. 14.

FIG. 17 illustrates an example compute sled of the example server of FIG. 14.

FIG. 18 illustrates another example of a compute sled of the example server of FIG. 14.

FIG. 19 illustrates an example accelerator sled of the example server of FIG. 14.

FIG. 20A illustrates another example immersion cooling system constructed in accordance with teachings of this disclosure.

FIGS. 20B and 20C illustrate the example immersion cooling system of FIG. 20A with example electronic components in different orientations.

FIG. 21 illustrates another example immersion cooling system constructed in accordance with teachings of this disclosure.

FIG. 22 illustrates another example immersion cooling system constructed in accordance with teachings of this disclosure.

FIG. 23 is a flowchart illustrating an example method of implementing the example immersion cooling systems of FIGS. 20A-22.

FIGS. 24 and 25 illustrate another example immersion cooling system constructed in accordance with teachings of this disclosure.

FIG. 26 illustrates another example immersion cooling system constructed in accordance with teachings of this disclosure.

FIGS. 27-28 illustrate example baffles that may be implemented in the example immersion cooling systems of FIGS. 24-26.

FIGS. 30-32 illustrate an example circuit board with baffles in accordance with teachings of this disclosure.

FIG. 33 illustrates an example circuit board assembly constructed in accordance with teachings of this disclosure to be immersion cooled.

FIG. 34 illustrates another example circuit board assembly constructed in accordance with teachings of this disclosure to be immersion cooled.

FIG. 35 is a flowchart illustrating an example method of manufacturing any one of the example circuit board assemblies of FIGS. 33 and 34.

FIG. 36 illustrates an example CPU assembly 3600 that includes a heat sink in accordance with teachings of this disclosure.

FIG. 37 is a flowchart illustrating an example method of manufacturing the example CPU assembly of FIG. 36.

FIG. 38 illustrates a known liquid cooling system used to cool dual in-line memory modules (DIMMs).

FIG. 39 illustrates an example liquid cooling system constructed in accordance with teachings of this disclosure.

FIG. 40 illustrates a cross-sectional view of an example cooling system assembly that includes an example boiler plate constructed in accordance with teachings of this disclosure.

FIG. 41 illustrates an isometric view of the example boiler plate of FIG. 40.

FIG. 42 is a graph illustrating experimental results for the thermal resistance of boiler plates fabricated with different porosities in accordance with teachings of this disclosure.

FIG. 43 is a diagram representing parameters to determine the size of bubble nucleation sites.

FIGS. 44 and 45 illustrate an example boiler plate constructed in accordance with teachings of this disclosure.

FIG. 46 illustrates another example boiler plate constructed in accordance with teachings of this disclosure.

FIG. 47 is a flowchart illustrating an example method of manufacturing any one of the example boiler plates of FIGS. 44-46.

FIG. 48 is a block diagram of an example processing platform including processor circuitry structured to execute the example machine readable instructions and/or the example operations of FIG. 3 to implement control system circuitry of FIG. 2C.

FIG. 49 is a block diagram of an example processing platform including processor circuitry structured to execute the example machine readable instructions and/or the example operations of FIG. 13 to implement control system circuitry of FIG. 12.

FIG. 50 is a block diagram of an example implementation of the processor circuitry of FIGS. 48 and/or 49.

FIG. 51 is a block diagram of another example implementation of the processor circuitry of FIGS. 48 and/or 49.

FIG. 52 is a block diagram of an example software distribution platform (e.g., one or more servers) to distribute software (e.g., software corresponding to the example machine readable instructions of FIGS. 3 and/or 13) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

FIG. 53 is a simplified diagram of at least one example of a data center for executing workloads with disaggregated resources.

FIG. 54 is a simplified diagram of at least one example of a pod that may be included in the data center of FIG. 53.

FIG. 55 is a perspective view of at least one example of a rack that may be included in the pod of FIG. 54.

FIG. 56 is a side elevation view of the rack of FIG. 55.

FIG. 57 is a perspective view of the rack of FIG. 55 having a sled mounted therein.

FIG. 58 is a is a simplified block diagram of at least one example of a top side of the sled of FIG. 57.

FIG. 59 is a simplified block diagram of at least one example of a bottom side of the sled of FIG. 58.

FIG. 60 is a simplified block diagram of at least one example of a compute sled usable in the data center of FIG. 53.

FIG. 61 is a top perspective view of at least one example of the compute sled of FIG. 60.

FIG. 62 is a simplified block diagram of at least one example of an accelerator sled usable in the data center of FIG. 53.

FIG. 63 is a top perspective view of at least one example of the accelerator sled of FIG. 62.

FIG. 64 is a simplified block diagram of at least one example of a storage sled usable in the data center of FIG. 53.

FIG. 65 is a top perspective view of at least one example of the storage sled of FIG. 64.

FIG. 66 is a simplified block diagram of at least one example of a memory sled usable in the data center of FIG. 53.

FIG. 67 is a simplified block diagram of a system that may be established within the data center of FIG. 53 to execute workloads with managed nodes composed of disaggregated resources.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” refer to dimensions that may not be exact due to manufacturing tolerances and/or other real world imperfections. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmed with instructions to perform specific operations and including one or more semiconductor-based logic devices (e.g., electrical hardware implemented by one or more transistors). Examples of processor circuitry include programmed microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of the processing circuitry is/are best suited to execute the computing task(s).

### DETAILED DESCRIPTION

As noted above, the use of liquids to cool electronic components is being explored for its benefits over more traditional air cooling systems, as there are increasing needs to address thermal management risks resulting from increased thermal design power in high performance systems (e.g., CPU and/or GPU servers in data centers, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic components. An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

Direct immersion cooling can involve at least one of single-phase immersion cooling or two-phase immersion cooling. As used herein, single-phase immersion cooling means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase immersion cooling means the cooling fluid (in this case, a cooling liquid) vaporizes or boils from the heat generated by the electronic components to be cooled, thereby change from the liquid phase to the vapor phase. The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, immersion cooling typically involves at least one cooling liquid (which may or may change to the vapor phase when in use). Example systems, apparatus, and associated methods to improve immersion cooling systems and/or associated cooling processes are disclosed herein.

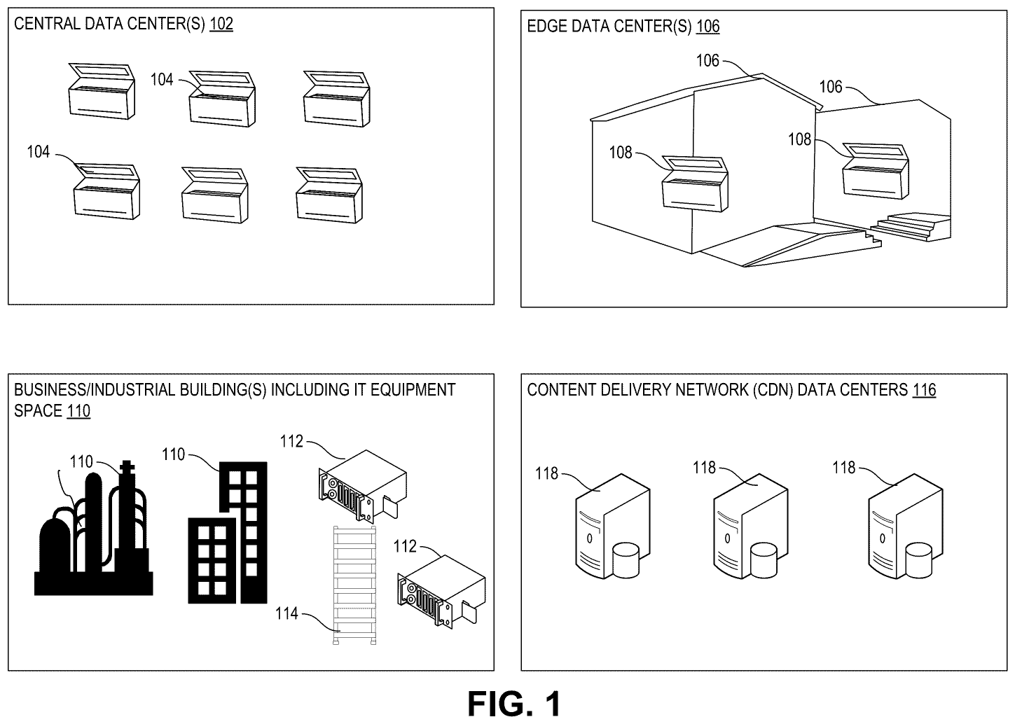

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, edge data center(s) 106 are located at or near a top of a cell tower and/or other utility pole. The edge data center(s) 106 include respective housings that store server(s), where the server(s) can be in communication with, for instance, the servers stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store servers and/or other electronic components located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, servers 112 can be stored using server rack(s) 114 that support the servers 112 (e.g., in an opening of slot of the rack 114). In some examples, the server(s) 112 located at the buildings 110 can include on-premise servers of an edge computing network, where the on-premise servers are in communication with remote servers (e.g., the servers at the edge data center(s) 106) and/or other computing devices within an edge network.

The example environment(s) of FIG. 1 can include content delivery network (CDN) data center(s) 116. The CDN data center(s) 116 can include server(s) 118 that cache content such as images, webpages, videos, etc. accessed via user devices. The server(s) 118 of the CDN data centers 116 can be disposed in immersion cooling tanks such as the immersion tanks 104, 108 shown in connection with the data centers 102, 106.

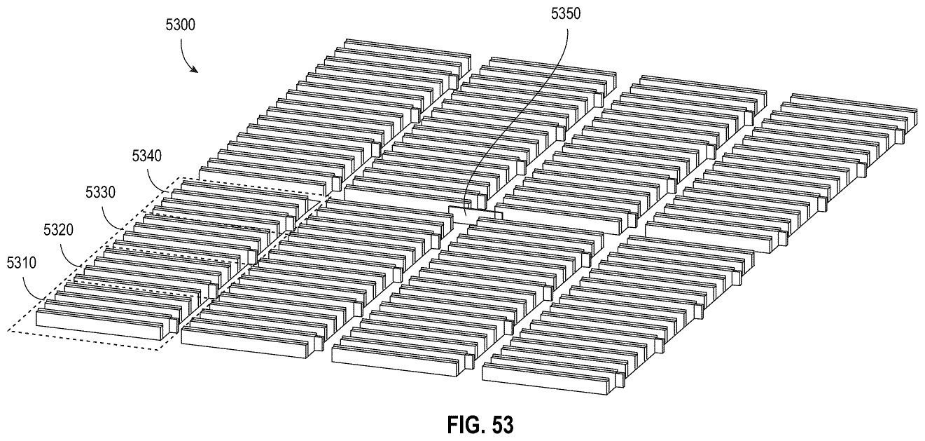

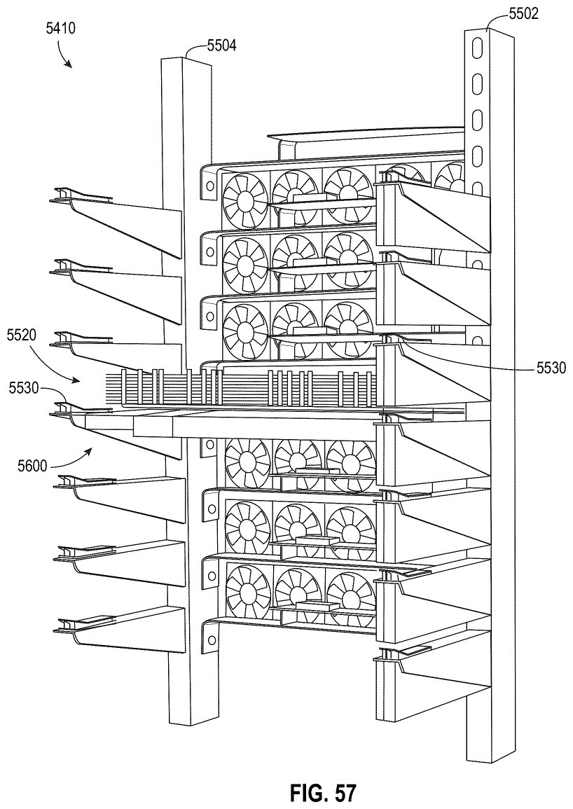

The example data centers 102, 106, 116 and/or building(s) 110 of FIG. 1 can correspond to, be implemented by, and/or be adaptations of the example data center 5300 described in further detail below in connection with FIGS. 53-67.

The example immersion cooling data centers and/or other structures or environments disclosed herein are not limited to arrangements of the size that are depicted in FIG. 1. For instance, the structures containing example immersion cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example immersion cooling systems and/or components thereof disclosed herein can be sized such that access (e.g., the only access) to an interior of the structure is a port for service personnel to reach into the structure. Also, the structures containing example immersion cooling systems and/or components thereof disclosed herein can be sized such that only a tool can reach into the enclosure because the structure may be supported by, for a utility pole or radio tower, or a larger structure.

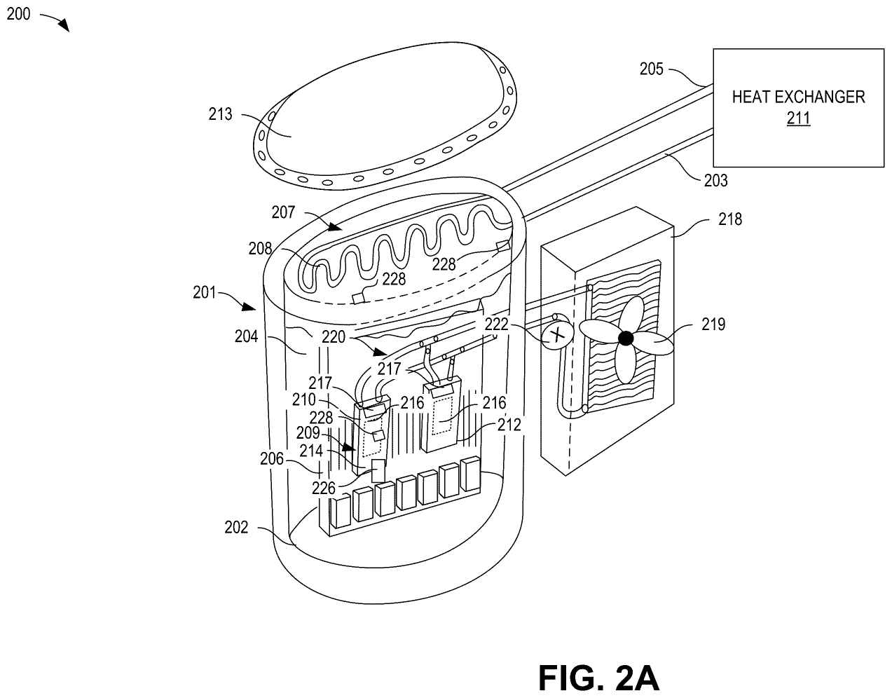

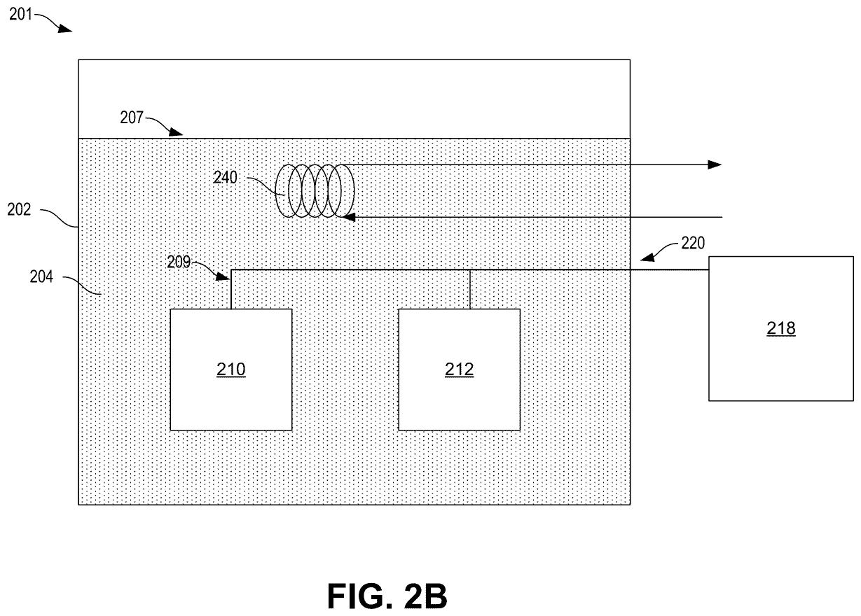

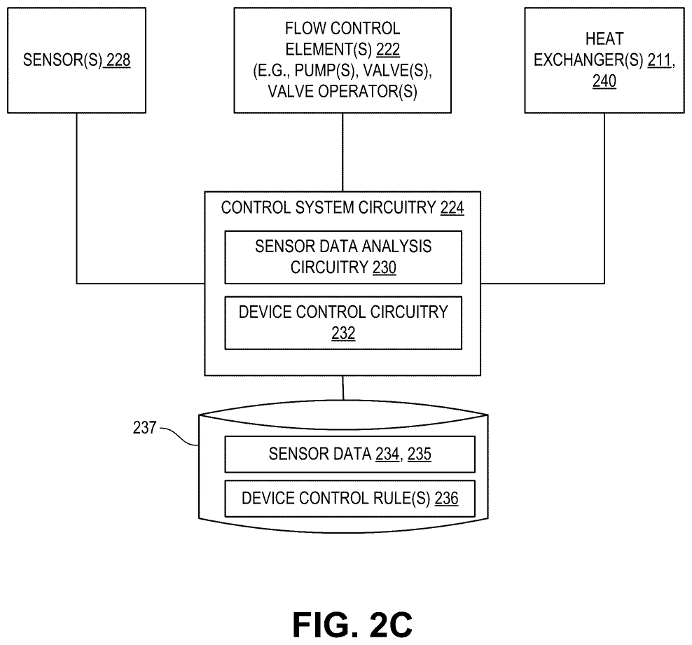

FIG. 2A illustrates an example immersion cooling system 200 constructed in accordance with teachings of this disclosure to provide for localized cooling of electronic components. The example system 200 of FIG. 2A includes an immersion tank 201 defining a first chamber 202 therein. A first cooling fluid 204 (e.g., a dielectric cooling liquid) is disposed in the first chamber 202. Cooling fluids are often in liquid form and, therefore, are sometimes referred to as cooling liquids herein. Cooling fluids are also sometimes referred to as coolants herein. A lid 213 is removably coupled to the immersion tank 201 to cover the first chamber 202. The immersion tank 201, the first chamber 202, and/or the lid 213 can have different shapes and/or sizes than the examples shown in FIG. 2A. In some examples, the first chamber 202 is pressurized and includes one or more pressure relief systems (e.g., valves). As disclosed herein, the example immersion cooling system 200 of FIG. 2A includes a first cooling system 207 and a second cooling system 209. Each of the cooling systems 207, 209 can multiple components fluidly coupled via piping and/or tubing. In some examples, the piping couples the first cooling system 207 and the second cooling system 209. In some such examples, a header (e.g., piping, tubing) couples the cooling systems 207, 209 and valves provide isolation for fill and refill operations and/recirculation of fluid among the respective cooling systems 207, 209.

In the example of FIG. 2A, one or more first electronic components 206 are disposed in the first cooling fluid 204. In some examples, the first electronic components 206 can be disposed in one or more enclosures immersed in the first cooling fluid 204. Heat generated by the first electronic component(s) 206 is transferred to the first cooling fluid 204. In the example of FIG. 2A, the immersion cooling system 200 is a two-phase immersion cooling system. The heat transferred from the first electronic component(s) 206 to the first cooling fluid 204 of FIG. 2A causes the first cooling fluid 204 to boil. The first chamber 202 includes a condenser 208 (also referred to as a condenser segment, a condenser section, a condenser portion, etc.) to collect vapor generated as a result of the boiling of the first cooling fluid 204 (e.g., conversion of the first cooling fluid 204 from the liquid phase to the vapor phase). The condenser 208 can be located in a vapor space of the immersion tank 201 above the first cooling fluid 204. The vapor is condensed into liquid as the vapor cools and the liquid (e.g., condensate droplets) reenters the first chamber 202. The condenser 208 includes an inlet 203 to provide cold water to the condenser 208 to facilitate the phase change of the vapor into liquid. The condenser 208 includes an outlet 205 through which hot water resulting from release of latent heat during the vapor condensation process leaves the condenser 208. The inlet 203 and the outlet 205 can be coupled to a heat exchanger 211.

In the example of FIG. 2A, the first chamber 202 including the first cooling fluid 204 and the condenser 208 defines the first cooling system 207 (e.g., a primary cooling system) to cool the first electronic component(s) 206. In the example of FIG. 2A, the first chamber 202 supports the second cooling system 209 (e.g., a secondary cooling system). The second cooling system 209 of FIG. 2A is defined by one or more chambers, covers, cold plates, housings, etc. disposed in the first chamber 202. For example, as illustrated in FIG. 2A, a second chamber 210 and a third chamber 212 are disposed in the first chamber 202 and define the second cooling system 209 of FIG. 2A. Additional or fewer chambers, cold plates, etc. to provide for secondary cooling systems within the first chamber 202 can be disposed in the first chamber 202.

For illustrative purposes, the second chamber 210 will be discussed in detail with the understanding that the third chamber 212 can be the same or substantially the same as the second chamber 210. The second chamber 210 includes a second cooling fluid 214 (e.g., a second cooling liquid) disposed therein. The second chamber 210 separates (e.g., isolates, seals) the second cooling fluid 214 from the first cooling fluid 204 of the first chamber 202. In some examples, the second chamber 210 can include one or more internal pressure relief systems (e.g., valves) to release pressure in the second chamber 210 while maintaining isolation from first cooling fluid 204. In some examples, pressure relief is provided by external components in communication with the second chamber 210 such as a dry cooler 218.

One or more second electronic components 216 are disposed in the second chamber 210. Heat from the second electronic component(s) 216 is transferred to the second cooling fluid 214 to cool the second electronic component(s) 216. The second chamber 210 includes a condenser 217. The boiling of the heated second cooling fluid 214 generates vapors that collect on the condenser 217. Heat from the vapors is transferred to water flowing through the condenser 217.

In the example of FIG. 2A, the second chamber 210 is fluidly coupled to the dry cooler 218 external to the first chamber 202 via tubing 220. The tubing 220 transports the heated water of the condenser 217 to the dry cooler 218. The tubing 220 isolates the water carried to and from the condenser 217 from the first cooling fluid 204 in the first chamber 202. The example dry cooler 218 of FIG. 2A includes a fan 219 to circulate external air over the heated water from the condenser 217. Although the example dry cooler 218 of FIG. 2A is an air-cooled heat exchanger, in other examples, a liquid-to-liquid heat exchanger could be used.

Flow control element(s) 222 (e.g., pump(s) such as metering pump(s), valve(s) such as a control valve(s), electro-mechanical valve operator(s)) facilitate delivery of the water cooled via the dry cooler 218 to the condenser 217. The tubing 220 can include valves to regulate the flow of the fluid to and from the condenser 217. In some examples, the valves include flow regulation valves that can be manually adjusted and/or include electro-mechanical operators to enable a control system (FIG. 2C) to adjust flow. As disclosed herein, the flow control element(s) 222 are operatively coupled to control system circuitry 224 (FIG. 2C), which generates instructions to control operation of the flow control element(s) 222 to control flow rate of the fluid. In some examples, the cooled water generated by the dry cooler 218 could be provided to the condenser 217 of the first chamber 202 as part of a closed-loop system between the first cooling system 207 and the second cooling system 209. Alternatively, the second chambers 210 and/or the third chamber 212 may be individually sealed and not fluidically coupled to an external cooling element or one another. In some such examples, heat generated in the chamber 210, 212 may be transferred into the first chamber 202.

In the example of FIG. 2A, the first electronic component(s) 206 can be cooled by the first cooling fluid 204 of the first cooling system 207 such that heat generated by the first electronic component(s) 206 is extracted during boiling of the first cooling fluid 204, where the first cooling fluid 204 has a higher boiling point than the second cooling fluid 214. For example, the second electronic component(s) 216 can have a higher thermal design power (TDP) than the thermal design power of the first electronic component(s) 206, thereby requiring a lower boiling point to cool the second electronic component(s) 216. For example, the first electronic components 206 disposed in the first chamber 202 and cooled via the first cooling fluid 204 can include voltage regulators, power supply sources, a semiconductor memory such as dynamic random access memory (DRAM), etc. The second electronic component(s) cooled via heat transfer with the second cooling fluid 214 can include, for example, a CPU, a GPU, an XPU, etc.

As disclosed above, in the example of FIG. 2A the second cooling fluid 214 has a lower boiling point than the first cooling fluid 204. As noted above, the second electronic component(s) 216 may have a higher thermal design power than the first electronic component(s) 206 and, thus, the higher boiling point associated with the first cooling fluid 204 may not adequately cool the second electronic component(s) 216. For instance, the second electronic component(s) 216 can be associated with a TDP of 250 watts and a target cooling temperature (e.g., T_{case}) of 50° C. If the boiling point of the first cooling fluid 204 is 60° C., the heat generated by the second electronic component(s) 216 may not cause localized boiling of the first cooling fluid 204 proximate to the second electronic component(s) 216 because of the higher boiling point of the first cooling fluid 204. Thus, a lower boiling point is needed to extra heat generated by the second electronic component(s) 216 and meet thermal requirements of the second electronic component(s) 216.

Conversely, if a coolant having a boiling point of, for instance, 40° C. is used to cool the second electronic component(s) 216, then the heat transfer between the second electronic component(s) 216 and the coolant can cause the coolant to boil, thereby generating vapors to extract heat to cool the second electronic component(s) 216. However, because the second cooling fluid 214 has a low boiling point (e.g., 40° C.), any water reclaimed from the heated second cooling fluid 214 via the condenser 217 may have a temperature that is too low to be considered low grade hot water. Low grade hot water (e.g., 70° C.-100° C.) can be used for purposes such as heating a facility in which the first chamber 202 is located, agriculture, etc. Although water reclaimed from the boiling of the second cooling fluid 214 may not (e.g., initially) be considered low grade hot water, the heated water can be valuable for other uses and, in some examples, the temperature of the extracted heated water can be increased.

In the example of FIG. 2A, the second chamber 210 of the second cooling system 209 enables the second cooling fluid 214 having a lower boiling point than the first cooling fluid 204 to be used to cool the high TDP second electronic component(s) 216 while allowing hot water generated as a result of cooling the low TDP first electronic component(s) 206 using the first cooling fluid 204 to be reclaimed as low grade hot water and used for heating, agriculture, and/or other energy reclamation efforts. In particular, the boiling of the first cooling fluid 204 during cooling of the first electronic component(s) 206 generates vapor that is collected via the condenser 208. Heat from the vapor is released during the condensation process and the heated water flows out of the condenser 208 via the outlet 205. Because of the higher boiling point of the first cooling fluid 204, the resulting heat transferred from the vapor to the water flowing through the condenser 208 can produce low grade hot water (e.g., via the heat exchanger 211). The low grade hot water can be reclaimed and used for energy harvesting (e.g., for use in heating systems in an environment in which the first chamber 202 is located).

Thus, the example first and second cooling systems 207, 209 provide for selective use of coolant based on the thermal design power of the electronic components to be cooled. Rather than using the lower boiling point second cooling fluid 214 to cool the first and second electronic components 206, 216, the second cooling system 209 provides for isolated, localized cooling of the second electronic component(s) 216. Because the lower TDP first electronic components 206 can be efficiently cooled using the higher boiling point first cooling fluid 204, the example system 200 of FIG. 2A provides for energy reclamation via the first cooling system 207 while cooling the higher TDP components via the second cooling system 209.

In some examples, the first cooling fluid 204 and the second cooling fluid 214 are the same fluid. In such examples, the different boiling points of the fluid can be achieved by adjusting pressure. For example, the second chamber 210 can be disposed in an environment that can enable isolated higher and lower pressure levels. For instance, if the second cooling system 209 were operating at lower pressures than the first cooling system 207, the boiling point of the fluid of the second cooling system 209 would be reduced.

Although in the example of FIG. 2A, the secondary cooling system 209 is implemented by the second chamber 210 (and the third chamber 212) enclosing the second electronic component(s) 216, in some examples the secondary cooling system 209 can include, for instance, a cold plate coupled to the second electronic component(s) 216 in the first chamber 202, where the second cooling fluid 214 flows through channels of the cold plate and circulates via the tubing 220. In such examples, the cold plate can be supported by, for example, a printed circuit board associated with the electronic component(s) 216. In some examples, a chassis or cover could be disposed over particular component(s) on, for instance, a printed circuit board to isolate the particular component(s) of the printed circuit board for cooling via the second cooling system 209. In some such examples, the condenser 217 can be disposed exterior to the first chamber 202.

In some examples, the chamber(s), enclosure(s), plate(s), etc. of the second cooling system 209 can be used to support one or more structures that promote circulation of the first cooling fluid 204 and/or the boiled vapors of the first cooling fluid 204 (e.g., bubbles displacing fluid) in the first chamber 202. For example, a plate 226 including one or more channels to direct or route circulation of the first cooling fluid 204 can be coupled to at least a portion of an exterior surface of the second chamber 210.

In some examples, the tubing 220 fluidly couples the second chamber 210 and the third chamber 212 of the second cooling system 209. For example, the outlets of the respective condensers 217 in the second chamber 210 and the third chamber 212 carrying the heated water can be fluidly coupled via the tubing 220, which transports the heated water to the dry cooler 218. The tubing 220 can provide for serial coupling and/or parallel coupling of the components (e.g., chambers, cold plates) of the second cooling system 209.

Although in the example of FIG. 2A, the first cooling system 207 includes the first cooling fluid 204 having a higher boiling point than the second cooling fluid 214 of the second cooling system 209, in other examples, the systems can be inverted. For instance, the second cooling fluid 214 having the lower boiling point can be disposed in the first chamber 202 and the first cooling fluid 204 having the higher boiling point can be disposed in the chambers 210, 212 of the second cooling system 209. In such examples, because the fluid in the chambers 210, 212 has a higher boiling point, the tubing 220 can be insulated from heat transfer to prevent condensate from forming in the first chamber 202 before reaching the heat condenser 208.

The example system 200 can include one or more sensors 228 to detect conditions at the first cooling system 207 and/or the second cooling system 209 (e.g., conditions in the first chamber 202 and/or the second chamber 210). For example, the sensor(s) 228 can monitor a temperature of the first cooling fluid 204 in the first chamber 202 and/or the second cooling fluid 214 in the second chamber 210 and/or the third chamber 212.

Although in the example of FIG. 2A, the first cooling system 207 (e.g., the first chamber 202, the first cooling fluid 204, the condenser 208) and the second cooling system 209 (e.g., the second chamber 210, the second cooling fluid 214, the condenser 217) provide for two-phase immersion cooling, in some examples, one or more of the first cooling system 207 or the second cooling system 209 is a single phase immersion cooling system. For example, the heated first cooling fluid 204 could be removed from the first chamber 202 via tubing that carries the heated first cooling fluid 204 to a heat exchanger to facilitate a coolant-to-water heat exchange as part of a single-phase immersion cooling process. In some examples, the second cooling system 209 is a single-phase immersion cooling system and the cooled second cooling fluid 214 generated from the second cooling system 209 is provided to the condenser 208 of the first chamber 202 (e.g., instead of a separately provided a single phase fluid such as water or other coolant in the condenser 208) as part of a closed-loop system between the first cooling system 207 and the second cooling system 209.

FIG. 2B illustrates an example in which the first cooling system 207 provides for single-phase immersion cooling. In the example of FIG. 2B, a heat exchanger 240 is disposed in the first cooling fluid 204 of the first chamber 202 of the tank 201. The heat exchanger 240 can facilitate a coolant to water exchange, where the heated water can be reclaimed for other uses. The example immersion tank 201 of FIG. 2B can include other components disclosed in connection with the example of FIG. 2A, such as the sensor(s) 228 to monitor a temperature of the fluids of the cooling systems 207, 209.

FIG. 2C is a block diagram of example control system circuitry 224 to control one or more components of example immersion cooling systems disclosed herein. Although the example control system circuitry 224 of FIG. 2C is discussed in connection with FIGS. 2A and 2B, the example control system circuitry 224 can be used to control the other example immersion cooling systems disclosed herein and/or component(s) thereof.

The control system circuitry 224 of FIG. 2C may be instantiated (e.g., creating an instance of, bring into being for any length of time, materialize, implement, etc.) by processor circuitry such as a central processing unit executing instructions. Additionally or alternatively, the control system circuitry 224 of FIG. 2C may be instantiated (e.g., creating an instance of, bring into being for any length of time, materialize, implement, etc.) by an ASIC or an FPGA structured to perform operations corresponding to the instructions. It should be understood that some or all of the circuitry of FIG. 2C may, thus, be instantiated at the same or different times. Some or all of the circuitry may be instantiated, for example, in one or more threads executing concurrently on hardware and/or in series on hardware. Moreover, in some examples, some or all of the circuitry of FIG. 2C may be implemented by one or more virtual machines and/or containers executing on the microprocessor

In the example of FIG. 2C, the signals output by the sensor(s) 228 of FIG. 2A and/or 2B are transmitted to the control system circuitry 224. In the example of FIG. 2C, the control system circuitry 224 is operatively coupled to the flow control element(s) 222, the dry cooler 218, and the heat exchanger(s) 211, 240 of FIGS. 2A and/or 2B. The example control system circuitry 224 can be operatively coupled to flow control element(s) 222 such as electro-mechanical valve operator(s) that control the valves of the tubing of the cooling systems 207, 209 (e.g., the tubing 220).

In some examples, the control system circuitry 224 includes one or more control system circuitry such as first control system circuitry 224 is associated with the heat exchanger 211 and second control system circuitry 224 is used to control, for instance, the flow control element(s) 222. In some examples, each of the chambers 210, 212 of the secondary cooling system 209 is associated with respective control system circuitry 224. In other examples, each of the chambers 210, 212 of the secondary cooling system 209 is associated with the same control system circuitry 224.

The example control system circuitry 224 of FIG. 2C includes sensor analysis circuitry 230 and device control circuitry 232. The sensor analysis circuitry 230 analyzes sensor data 234 corresponding to signals output by the sensors 228 of the first cooling system 207 and/or sensor data 235 corresponding to signals output by the sensors 228 of the second cooling system 209. The sensor data can be stored in a memory 237. In some examples, the control system circuitry 224 includes the memory 237. In some examples, the memory 237 is located external to the control system circuitry 224 in a location accessible to the control system circuitry 224 as shown in FIG. 2.

The device control circuitry 232 outputs instructions to control, for instance, the flow control element(s) 222 of the second cooling system 209 based on the analysis of the sensor data 234 and one or more device control rules 236 stored in the memory 237. The device control rule(s) 236 can be defined based on user inputs. The device control rule(s) 236 can define operational states and/or behaviors of the control devices such as the flow control element(s) 222 (e.g., a pump, valves) and the heat exchanger 211 in response to conditions in the respective primary cooling system 207 or the second cooling system 209. For example, the device control rule(s) 236 can state that the flow control element(s) 222 should increase a flow rate of the cooled water to the condenser 217 of one or more of the second chamber 210 or the third chamber 212 based on the temperature of the second cooling fluid 214 in the respective chambers. The example device control rule(s) 236 can include instruction(s) for the electro-mechanical valve operator(s) to control flow in the tubing 220. The device control circuitry 232 outputs instructions (e.g., control signals) to the control devices 211, 222, 240 based on the device control rule(s) 236.

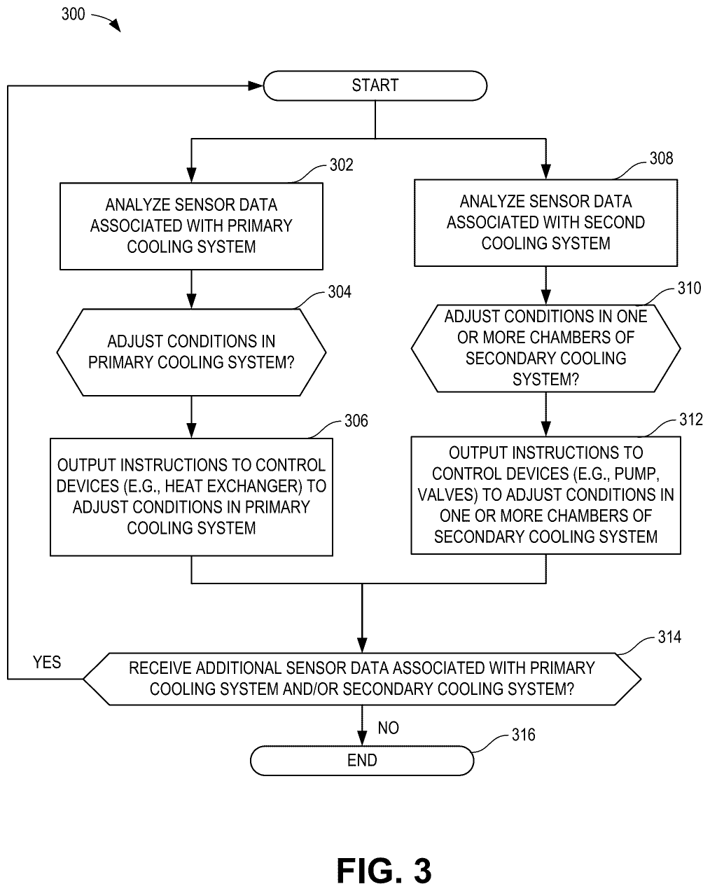

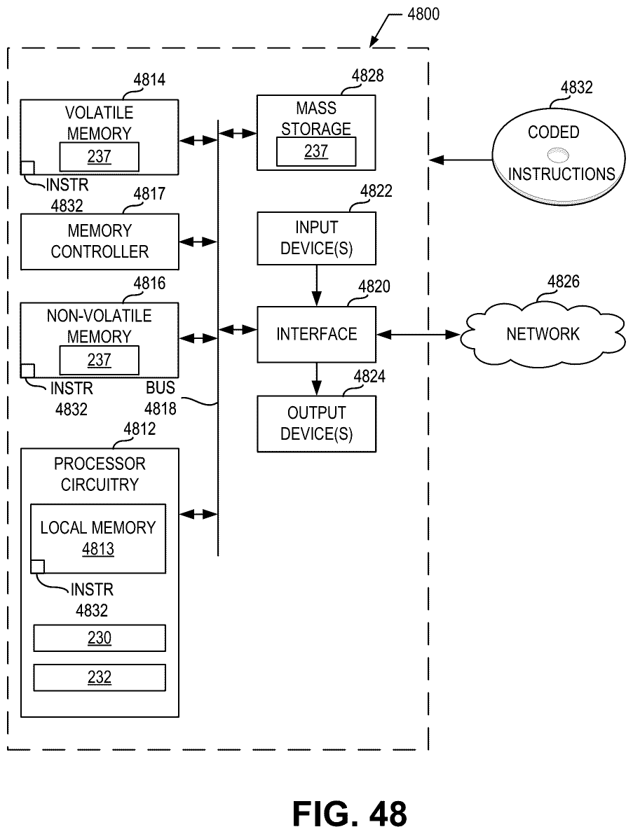

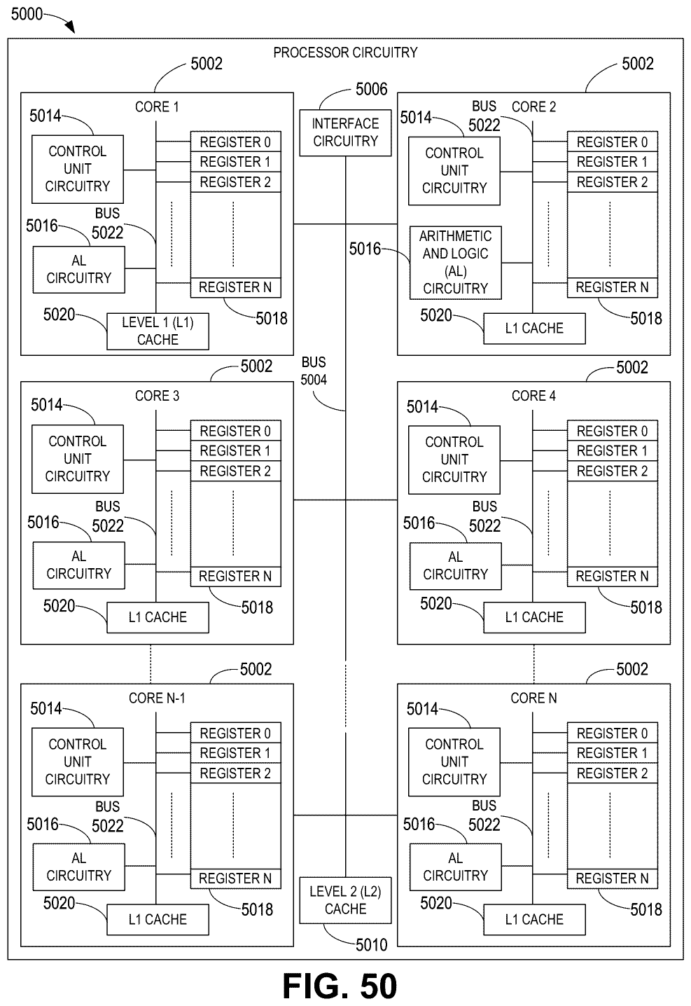

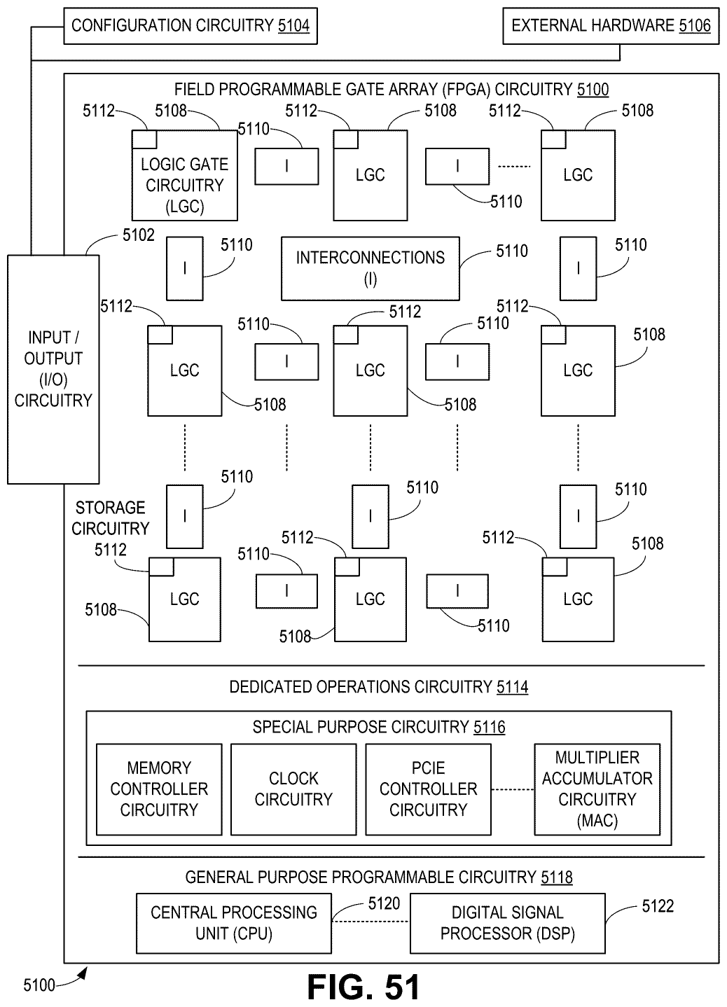

In some examples, the control system circuitry 224 includes means for analyzing sensor data. For example, the means for analyzing sensor data may be implemented by the sensor data analysis circuitry 230. In some examples, the sensor data analysis circuitry 230 may be instantiated by processor circuitry such as the example processor circuitry 4812 of FIG. 48. For instance, the sensor data analysis circuitry 230 may be instantiated by the example general purpose processor circuitry 5000 of FIG. 50 executing machine executable instructions such as that implemented by at least blocks 302, 308, 314 of FIG. 3. In some examples, the sensor data analysis circuitry 230 may be instantiated by hardware logic circuitry, which may be implemented by an ASIC or the FPGA circuitry 5100 of FIG. 51 structured to perform operations corresponding to the machine readable instructions. Additionally or alternatively, the sensor data analysis circuitry 230 may be instantiated by any other combination of hardware, software, and/or firmware. For example, the sensor data analysis circuitry 230 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the control system circuitry 224 includes means for controlling a device. For example, the means for controlling a device may be implemented by the device control circuitry 232. In some examples, the device control circuitry 232 may be instantiated by processor circuitry such as the example processor circuitry 4812 of FIG. 48. For instance, the device control circuitry 232 may be instantiated by the example general purpose processor circuitry 5000 of FIG. 50 executing machine executable instructions such as that implemented by at least blocks 304, 306, 310, 312 of FIG. 3. In some examples, the device control circuitry 232 may be instantiated by hardware logic circuitry, which may be implemented by an ASIC or the FPGA circuitry 5100 of FIG. 51 structured to perform operations corresponding to the machine readable instructions. Additionally or alternatively, the device control circuitry 232 may be instantiated by any other combination of hardware, software, and/or firmware. For example, the device control circuitry 232 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

While an example manner of implementing the control system circuitry 224 is illustrated in FIG. 2C, one or more of the elements, processes, and/or devices illustrated in FIG. 2C may be combined, divided, re-arranged, omitted, eliminated, and/or implemented in any other way. Further, the example sensor data analysis circuitry 230, the example device control circuitry 232, and/or, more generally, the example control system circuitry 224 of FIG. 2C, may be implemented by hardware alone or by hardware in combination with software and/or firmware. Thus, for example, any of the example sensor data analysis circuitry 230, the example device control circuitry 232, and/or, more generally, the example control system circuitry 224 could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example control system circuitry 224 of FIG. 2C may include one or more elements, processes, and/or devices in addition to, or instead of, those illustrated in FIG. 2C, and/or may include more than one of any or all of the illustrated elements, processes and devices.

FIG. 3 is a flowchart representative of example machine readable instructions and/or example operations 300 that may be executed and/or instantiated by processor circuitry to control the first cooling system 207 and/or the second cooling system 209 of FIGS. 2A and/or 2B. Although the example instructions 300 are discussed in connection with FIGS. 2A and/or 2B, the example instructions 300 of FIG. 3 can be used in connection with control system circuitry for the other example immersion cooling systems disclosed herein.

The machine readable instructions and/or the operations 300 of FIG. 3 begin at block 302, at which the sensor data analysis circuitry 230 analyzes the sensor data 234 associated with the first cooling system 207. For example, the sensor data analysis circuitry 230 can determine a temperature of the first cooling fluid 204 in the first chamber 202 based on the sensor data from the sensors 228 in the first chamber 202.

At block 304, the device control circuitry 232 determines whether conditions in the first chamber 202 of the first cooling system 207 should be adjusted based on the sensor data analysis and the device control rule(s) 236. For example, based on the temperature of the first cooling fluid 204, the device control circuitry 232 can instruct the heat exchanger 211 to adjust a flow of water through the condenser 208. The device control circuitry 232 outputs such instructions at block 306.

Additionally or alternatively, at block 308, the sensor data analysis circuitry 230 analyzes the sensor data 235 associated with the second cooling system 209. For example, the sensor data analysis circuitry 230 can determine a temperature of the second cooling fluid 214 in one or more of the second chamber 210 or the third chamber 212 based on the sensor data from the sensors 228 in the respective chambers 210, 212.

At block 310, the device control circuitry 232 determines whether conditions in one or more chambers 210, 212 of the second cooling system 209 should be adjusted based on the sensor data analysis and the device control rule(s) 236. For example, based on the temperature of the second cooling fluid 214 in one or more of the second chamber 210 or the third chamber 212, the device control circuitry 232 can instruct the flow control element(s) 222 to adjust a flow of water through the condenser 217 of one or more of the chamber 210, 212. In some examples, the device control circuitry 232 adjusts a state of the valves associated with the tubing 220. In some examples, the device control circuitry 232 causes electro-mechanical operator(s) (e.g., control valves) of the tubing 220 to adjust flow. In some examples, the instructions generated by the device control circuitry 232 for the electro-mechanical operator(s) is provided in combination with instructions to a metering pump; in other examples, the instructions are independent of the pump (e.g., when the pump is a constant flow rate pump). The device control circuitry 232 outputs such instructions (e.g., control signals) at block 312.

The example instructions 300 of FIG. 3 continues to analyze the sensor data 234, 235 associated with the first cooling system 207 and/or the second cooling system 209 until no further sensor data is received (blocks 314, 316).

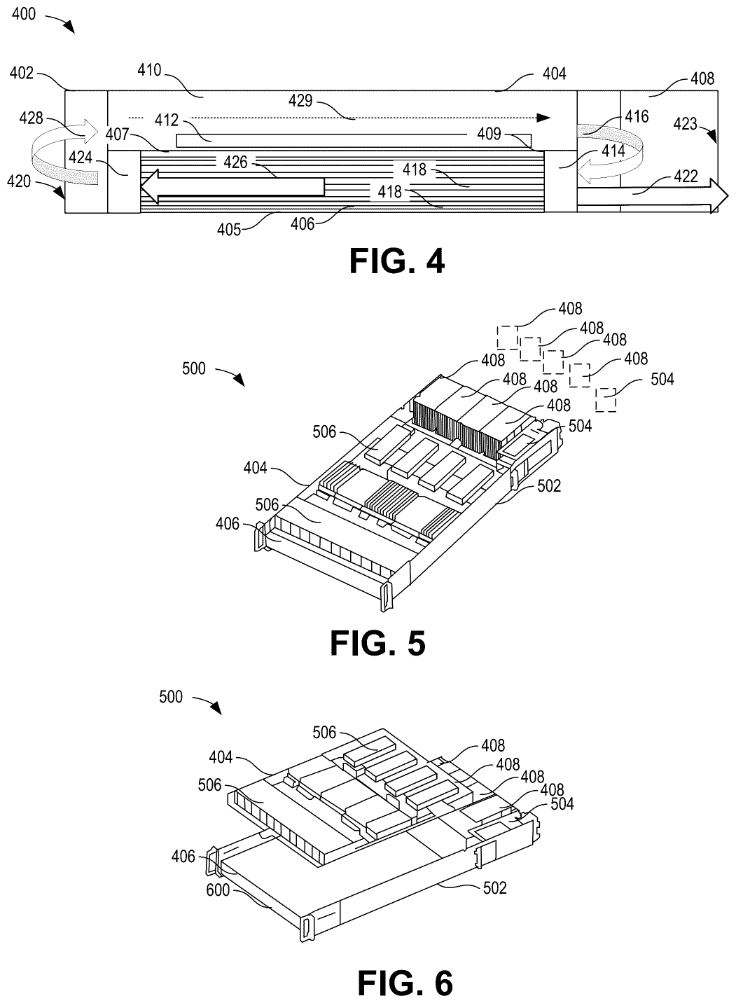

FIG. 4 illustrates an example immersion cooling system 400 constructed in accordance with teachings of this disclosure to provide for modular-based immersion cooling. The example immersion cooling system 400 of FIG. 4 includes a chassis 402 (e.g., a metal housing). The chassis 402 can be disposed in or supported by, for instance, a rack such as the example rack 114 of FIG. 1. In some examples, the chassis 402 can be associated with an edge device to provide for immersion cooling of electronic components of the edge device in an edge network. In the example of FIG. 4, the chassis 402 carries an immersion tank 404, a heat exchanger 406, one or more fans 408, and a power source (FIG. 5). Although in the example of FIG. 4, the fan(s) 408 are supported by the chassis 402, in other examples, the fan(s) 408 can be external to the chassis 402 (e.g., supported by the rack that also supports the chassis 402). The chassis 402 can include electrical interface(s) to facilitate communicative coupling(s) between the electronic components carried by the chassis 402 and electronic components exterior to the chassis 402.

As illustrated in FIG. 4, the immersion tank 404 and the heat exchanger 406 are disposed in a stacked or multi-level configuration when the chassis 402 is in the orientation shown in FIG. 4. The heat exchanger 406 can rest on a surface 405 of the chassis 402. As shown in FIG. 4, the immersion tank 404 is spaced apart from the surface 405 of the chassis 402. In some examples, an exterior surface 407 of the immersion tank 404 directly contacts (e.g., rests on) an opposing exterior surface 409 of the heat exchanger 406. In other examples, one or more materials or other components are disposed between the immersion tank 404 and the heat exchanger 406. Put another way, a first plane extending longitudinally through the heat exchanger 406 is parallel to a second plane extending longitudinally through the immersion tank 404.

A cooling fluid 410 (e.g., a cooling liquid) is disposed in the immersion tank 404. The immersion tank 404 sealingly separates the cooling fluid 410 from other components (e.g., the heat exchanger 406) in the chassis 402. One or more electronic components 412 (e.g., CPUs, printed circuit boards) are disposed in the immersion tank 404. In the example of FIG. 4, heat generated by the electronic component(s) 412 is transferred to the cooling fluid 410. The heat exchanger 406 includes a first pump 414 to draw or provide a flow of the heated cooling fluid 410 from the immersion tank 404 to the heat exchanger 406, as represented by arrow 416 in FIG. 4. The first pump 414 can regulate the flow rate of the cooling fluid 410 based on, for example, a temperature of the cooling fluid and instructions from one or more control systems (e.g., the device control circuitry 232 of FIG. 2C).

The heated cooling fluid 410 flows through piping 418 of the heat exchanger 406. The arrangement and/or size of the piping 418 can differ from the example shown in FIG. 4. The illustration of 418 in FIG. 4 shows a linear arrangement of the liquid piping or tubing in the air to liquid heat exchanger 406. However, wavy or curved patterns in the liquid piping 418 may enhance heat removal and could be selected in some examples.

The fan(s) 408 draw cool air from the ambient environment into the chassis 402 via an inlet 420 of the chassis. The cool air circulates about the piping 418 of the heat exchanger 406 to cool the heated cooling fluid 410 flowing through the piping 418 of the liquid-to-air heat exchanger 406. In some examples, the piping 418 includes baffles to increase the turbulence of the fluid flow and, as a result, the heat transferred from the fluid to the air. The air exits the chassis 402 via an outlet 423 provided by the fan(s) 408, as represented by arrow 422 in FIG. 4. A second pump 424 facilitates delivery of the cooled fluid 410 back to the immersion tank 404, as represented by arrows 426, 428, 429 of FIG. 4. In some examples, the immersion cooling system 400 includes both the first pump 414 and the second pump 424. In some examples, the immersion cooling system 400 includes one of the first pump 414 or the second pump 424 for forced circulation.

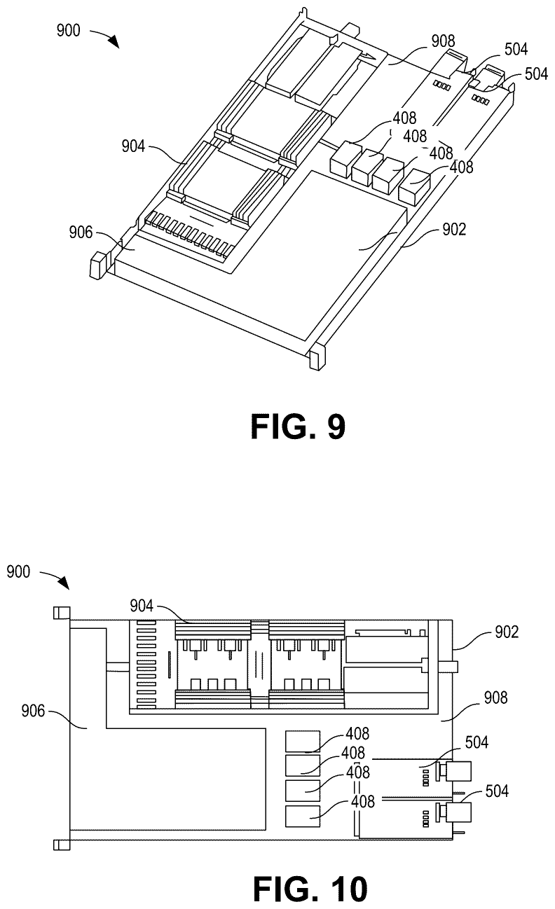

Thus, the chassis 402 of FIG. 4 supports a modular immersion cooling system 400. The chassis 402 can be disposed in an opening or slot in a rack such as the rack 114 of FIG. 1. The chassis 402 can be sized to fit in an opening of a rack having, for example, a width of 19 inches, 23 inches, etc. As disclosed herein, a height of the chassis 402 and the arrangement of the components such as the immersion tank 404 and the heat exchanger 406 within the chassis 402 can be designed to accommodate different sized racks and/or other form factors variables (e.g., components to be cooled). For instance, although in the example of FIG. 4, the immersion tank 404 and the heat exchanger 406 are arranged in the stacked configuration when the chassis is oriented as shown in FIG. 4, in some examples, the immersion tank 404 and the heat exchanger 406 rest on a same surface of the chassis 402 (e.g., as disclosed in connection with FIGS. 9 and 10).

Although the example immersion system 400 of FIG. 4 implements a single phase immersion cooling system, in some examples, the immersion system 400 of FIG. 4 is a two-phase immersion cooling system. For example, a condenser or cold plate could be disposed in the immersion tank 404 to cause vapor generated as a result of boiling the cooling fluid 410 to condense.

FIG. 5 illustrates a first example modular immersion cooling system 500 in accordance with teachings of this disclosure. FIG. 6 is a partially exploded view of the first example modular immersion cooling system 500 of FIG. 5. The first modular immersion cooling system 500 of FIGS. 5 and 6 is similar to the immersion cooling system 400 of FIG. 4 in that a chassis 502 supports the immersion tank 404 and the heat exchanger 406 in a stacked or multi-level configuration when the chassis 502 is oriented as shown in FIG. 5. The respective sizes and/or shapes of the immersion tank 404 and/or the heat exchanger 406 can differ from the examples shown in FIGS. 5 and 6.

The example modular immersion cooling system 500 of FIGS. 5 and 6 includes four fans 408 in the chassis 402. The example modular immersion cooling system 500 of FIG. 5 can include additional or fewer fans 408. One or more power supply units 504 are disposed in the chassis 502 to provide power to, for example, the pumps 414, 424 (FIG. 4) of the heat exchanger 406. Although in the example of FIG. 5 the power supply unit(s) 504 and the fan(s) 408 are supported by the chassis 502, in other examples, the power supply unit(s) 504 and/or the fan(s) 408 can be external to the chassis 502 (e.g., supported by a rack that also supports the chassis 502), as illustrated by the dashed representation of the fan(s) 480 and the power supply unit(s) 504 in FIG. 5. Also, the respective sizes and/or shapes of the fan(s) 408 and/or the power supply unit(s) 504 and the location(s) thereof in the chassis 502 can differ from the examples shown in FIGS. 5 and 6.

As disclosed herein, the chassis 502 of FIGS. 5 and 6 supports a multi-level configuration of the immersion tank 404 and the heat exchanger 406. For example, the heat exchanger 406 rests on a surface 600 (FIG. 6) of the chassis 502 and defines a first component level of the chassis 502. The immersion tank 404 is spaced apart from the surface 600 of the chassis and defines a second component level of the chassis 502. Put another way, a plane extending longitudinally through the heat exchanger 406 is parallel to a plane extending longitudinally through the immersion tank 404. In the example of FIG. 5, the fan(s) 408, the power supply unit(s) 504, and the pump(s) 414, 424 (FIG. 4) are be supported by the surface 600 of the chassis 502.

To facilitate integration with existing rack in, for instance, a data center, a height of the chassis 502 can be measured in “U” values, where 1U equals 1.75 inches. Thus, the example chassis 502 can accommodate existing form factors of racks or other structures that support chassis. The example chassis 502 of FIGS. 5 and 6 is a 2U chassis that supports the multi-level arrangement of the heat exchanger 406 and the immersion tank 404. The chassis 502 can be larger than 2Us (e.g., 3Us, 4Us) to accommodate, for example, an immersion tank of a different size and/or more than one immersion tank in the chassis 502.

As illustrated in FIG. 5, electronic component(s) 506 are disposed in the immersion tank 404 in the cooling fluid 410. In some examples, the electronic component(s) 506 in the immersion tank 404 can be arranged to facilitate cooling of higher TDP electronic components. For example, a CPU can be disposed in the tank 404 proximate to an inlet of the tank 404 that receives the cooled fluid 410 (FIG. 4) from the heat exchanger 406 to promote cooling of the CPU as compared to a location of lower TDP components such as memory in the tank 404.

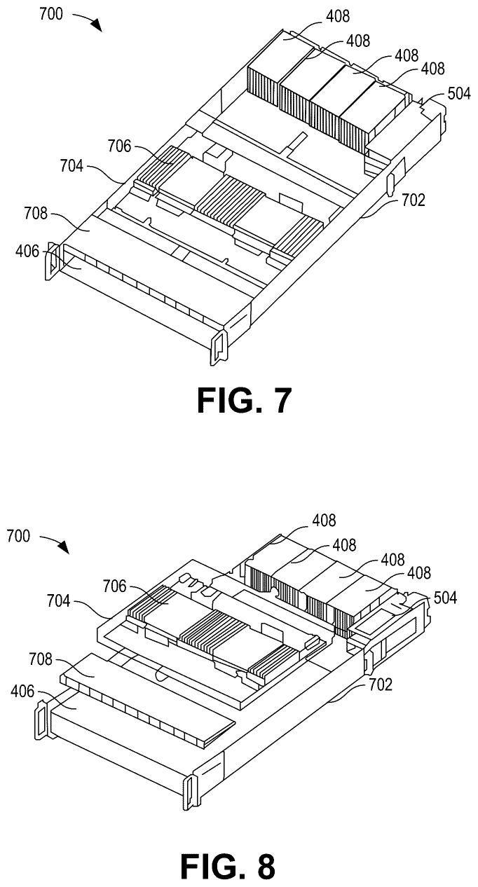

FIG. 7 illustrates a second example modular immersion cooling system 700 in accordance with teachings of this disclosure. FIG. 8 is a partially exploded view of the first example modular immersion cooling system 700 of FIG. 7. The example immersion cooling system 700 of FIGS. 7 and 8 includes a chassis 702 to support an immersion tank 704, the heat exchanger 406, the fan(s) 408, and the power supply unit(s) 504. In some examples, the fan(s) 408 and/or the power supply unit(s) 504 is external to the chassis 702

As illustrated in FIGS. 7 and 8, the chassis 702 supports the multi-level arrangement of the immersion tank 704 and the heat exchanger 406 disclosed in connection with FIGS. 4-6. However, in the example of FIGS. 7 and 8, first electronic component(s) 706 are disposed in the immersion tank 704 and second electronic component(s) 708 are carried by the chassis 702 exterior to the immersion tank 704. In the examples of FIGS. 7 and 8, the immersion tank 704 has a smaller size than the example immersion tanks 404 of FIGS. 4-6 to accommodate the second electronic components 708 disposed outside the immersion tank 704. However, a size and/or shape of the immersion tank 704 and/or the other components of the chassis 702 (e.g., the heat exchanger 406, the fan(s) 408) can differ from the example show in FIGS. 7 and 8.

In some examples, the second electronic component(s) 706 exterior to the immersion tank 704 have a lower thermal design power (TDP) than the electronic component(s) 502 disposed in the tank 404 and can be cooled via air cooling provided by the fan(s) 408. In some examples, the second electronic component(s) 706 include components such as memory DIMMS that are disposed external to the immersion tank 404 to provide for case of access with respect to memory configuration. Higher TDP components such as a CPU can be disposed in the immersion tank 704 for cooling via immersion cooling. Thus, the example immersion cooling system 700 of FIGS. 7 and 8 provides for selective cooling of the electronic components 706, 708 via air cooling or immersion cooling.

FIG. 9 illustrates a third example modular immersion cooling system 900 in accordance with teachings of this disclosure. FIG. 10 is a top view of the third example modular immersion cooling system 900 of FIG. 9. The example immersion cooling system 900 of FIGS. 9 and 10 includes a chassis 902. The example chassis 902 of FIGS. 9 and 10 can be a 1U chassis (e.g., having a height of 1.75 inches). As shown in FIGS. 9 and 10, the chassis 902 supports an immersion tank 904 and a heat exchanger 906. The immersion tank 904 and the heat exchanger 906 can be substantially similar to the immersion tank 404, 704 and the heat exchanger 406 of FIGS. 4-8. However, as shown in FIGS. 9 and 10, in this example, the immersion tank 904 and the heat exchanger 906 both rest on a surface 908 of the chassis 902 rather than being arranged in the multi-level configuration of FIGS. 4-8. In the example of FIGS. 9 and 10, the fan(s) 408 and the power supply unit(s) 504 are also disposed on the surface 908 of the chassis 902. The size(s), shape(s) of the respective immersion tank 904, the heat exchanger 906, the fan(s) 408, and/or the power supply unit(s) 504 relative to the surface 908 of the chassis 902 can differ from the example shown in FIGS. 9 and 10. Also, the location(s) of respective the immersion tank 904, the heat exchanger 906, the fan(s) 408, and/or the power supply unit(s) 504 relative to the surface 908 of the chassis 902 can differ from the example show in FIGS. 9 and 10. In some examples, the fan(s) 408 and/or the power supply unit(s) 504 are disposed outside the chassis 902.

Thus, the example modular immersion cooling systems 400, 500, 700, 900 of FIGS. 4-10 provide for immersion cooling within a chassis having a form factor (e.g., 1U, 2U chassis) that can be used with existing racks in, for instance, a data center or other building. For instance, the modular immersion cooling systems 400, 500, 700, 900 of FIGS. 4-10 can be implemented at data centers that use air cooling to enable immersion cooling to be integrated into the exiting infrastructures (e.g., mounting racks). Further, the example modular immersion cooling systems 400, 500, 700, 900 of FIGS. 4-10 combine air cooling and immersion cooling to facilitate cooling of electronic component(s) carried by the chassis and, in particular, high TDP components that benefit from immersion cooling.

Although the example modular immersion cooling systems 400, 500, 700, 900 of FIGS. 4-10 are disclosed in connection with a chassis, examples disclosed herein could be used in connection with sleds of a server chassis. For example, a 2U server chassis can contain four 1U half width sleds, or two 2U half width sleds. The immersion tank 404 could be disposed in the upper U space of the sled and the heat exchanger 406 could be disposed in the lower U space of the sled. In this example, two 2U half width sleds could be supported in a 2U server chassis and the fan(s) 408 could be supported by the sled or in the server chassis. In another example, the immersion tank 404 can be located in a front portion of the server chassis and the heat exchanger 406 can be located in a rear portion of the server chassis (or vice versa). Such examples could support four 1U half width sleds in a 2U server chassis and the fan(s) could be supported by the sled or the server chassis.

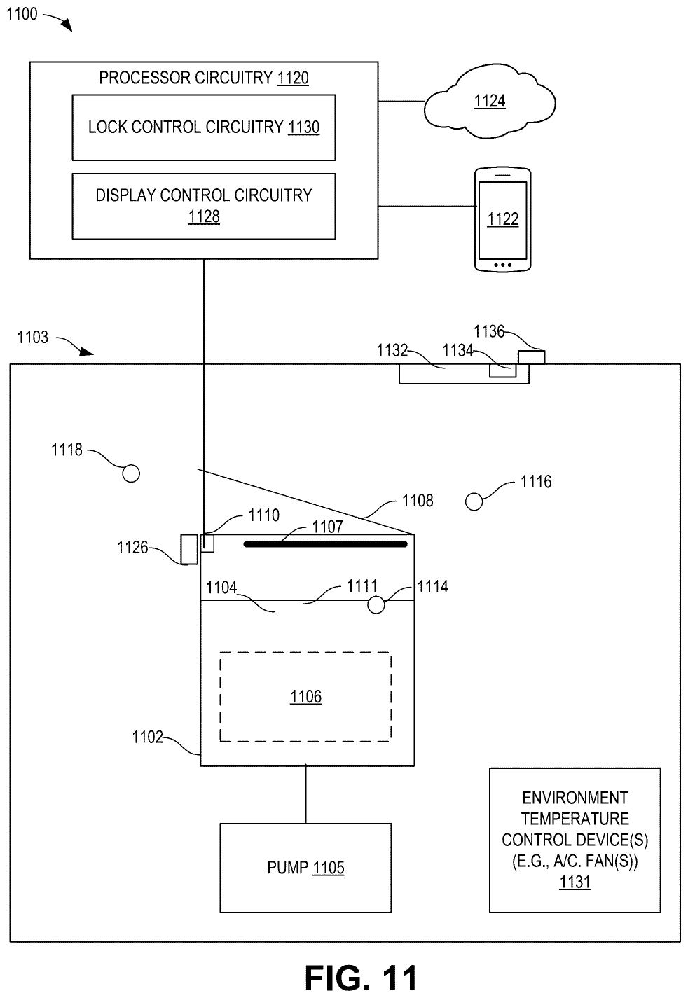

FIG. 11 illustrates an example immersion cooling system 1100 for providing selective access to an immersion tank 1102 (e.g., an interior of the immersion tank 1102) in accordance with teachings of this disclosure. In some examples, the immersion tank 1102 corresponds to the example immersion tanks 104, 108 of FIG. 1, the example immersion tank 201 of FIG. 2A and/or 2B, and/or the immersion tank(s) 404, 704, 904 of the example modular immersion systems 400, 500, 700, 900 of FIGS. 4-10.

The immersion tank 1102 of FIG. 11 is located in an environment 1103. The environment 1103 can include any of the example environments 102, 106, 110, 116 of FIG. 1 including, for example, a data center in which one or more immersion tanks 1102 are located; a micro-data center in which one or more immersion tanks are disposed to cool, for instance, servers in an edge network, etc. The example environment 1103 can include sheds that serve a micro-data centers and/or smaller application units (e.g., structures to support immersion cooling systems that are sized such that only an access port is provided for service personnel or a tool to reach into the structure).

The example immersion tank 1102 of FIG. 11 can be used in connection with single-phase immersion cooling or two-phase immersion cooling. A cooling fluid 1104 (e.g., a cooling liquid or coolant) is disposed in the immersion tank 1102 to facilitate cooling of electronic component(s) 1106 disposed in (e.g., immersed in) the immersion tank 1102. The cooling fluid 1104 is an electrically non-conductive fluid. In the example of FIG. 11, a pump 1105 is fluidly coupled to the tank 1102 to deliver cooling fluid 1104 to the tank 1102 and/or to facilitate removal of heated cooling fluid 1104 from the tank 1102 (e.g., as in single-phase immersion cooling).

Also, in the example of FIG. 1, one or more heaters 1107 (e.g., low wattage heaters) are disposed in the tank 1102. As disclosed herein, the heater(s) 1107 can be selectively activated to regulate (e.g., increase) a temperature of the cooling fluid 1104 or a vapor space of the immersion tank 1102 (e.g., a space above the cooling fluid 1104). In some examples, the heaters 1107 can heat the immersion tank 1102 to moderate a possibility of condensation on the immersion tank 1102 by heating exterior portions of a lid or cover 1108 of the tank 1102 prior to opening. The heater(s) 1107 can be disposed at different location(s) than shown in the example of FIG. 11.

As noted above, the example immersion tank 1102 of FIG. 11 includes the cover or lid 1108 (e.g., the lid 213 of FIG. 2A). The lid 1108 can be used to selectively cover an interior of the immersion tank 1102. For example, the lid 1108 can be coupled to the tank 1102 via a hinge and/or other mechanical fasteners to enable the lid 1108 to move between a covered position and an uncovered position. Thus, the immersion tank switches between a closed position and an opened position. The lid 1108 includes a digital lock 1110 (e.g., a lock including a keypad, a smartlock, etc.) to secure the lid 1108 to the immersion tank 1102. As disclosed herein, the lock 1110 selectively moves between a locked state and an unlocked state to enable a user to access to an interior of the immersion tank 1102. The user can move the lid 1108 from the covered position to the uncovered position when the lock 1110 is unlocked to access an interior of the immersion tank 1102 to, for instance, retrieve the electronic component(s) 1106 in the tank 1102 for maintenance. Although example disclosed herein are disclosed in connection with the lid 1108 of the immersion tank 1102, in some examples, the lock 1110 can be associated with, for example, an access port or other opening of the immersion tank 1102 and/or an enclosure in which the immersion tank is disposed. Examples disclosed herein can be used to control access to the access port and/or opening of the immersion tank 1102 and/or the enclosure in which the immersion tank is disposed.

When the lid 1108 is in the uncovered position as shown in FIG. 11, the cooling fluid 1104 is exposed to ambient environment 1103 in which the immersion tank 1102 is located. Air from the ambient environment 1103 comes into contact with a surface 1111 (e.g., a top surface) of the cooling fluid 1104 disposed in the tank 1102. If a temperature of the surface of the cooling fluid 1104 is below a dew point of the air, moisture in the air can condense into water at the surface 1111 of the cooling fluid 1104. Because water is electrically conductive, the formation of water in the immersion tank 1102 can cause the electronic component(s) 1106 to short. In some instances, the water can react with the cooling fluid 1104 and cause an acid (e.g., perfluropropionic acid) to form. The acid can react with the electronic component(s) 1106 and cause the component(s) 1106 to fail or otherwise damage the component(s) 1106.

The example immersion cooling system 1100 of FIG. 11 includes one or more temperature sensors 1114 (e.g., thermistor(s)) to monitor a temperature of the cooling fluid 1104. The temperature sensor(s) 1114 can be coupled to one or more walls of the tank 1102. As illustrated in FIG. 11, the temperature sensor(s) 1114 can be disposed in the tank 1102 such that temperature sensor(s) 1114 output signals representing data indicative of a temperature of the cooling fluid 1104 at or proximate to a surface of the cooling fluid 1104. The tank 1102 can include additional temperature sensors 1114 than show in FIG. 11.

The example system 1100 of FIG. 11 also includes sensors to measure condition(s) of the air in the ambient environment 1103 in which the immersion tank 1102 is located. For example, one or more temperature sensor(s) 1116 (e.g., dry bulb temperature sensor(s)) are located in the environment 1103 to measure air temperature. Also, one or more humidity sensors 1118 (e.g., capacitive humidity sensor(s), resistive humidity sensor(s), thermal humidity sensor(s)) are located in the environment 1103 to measure humidity in the air. In some examples, the humidity sensor(s) 1118 also measure air temperature. In some such examples, the humidity sensor(s) 1118 includes the temperature sensor(s) 1116. In some examples, the heater(s) 1107 are disposed in an environment surrounding the immersion tank 1102 (e.g., within a shed or other enclosure).

The example system 1100 of FIG. 1 includes semiconductor-based processor circuitry to process signals output by the sensor data generated by the temperature sensor(s) 1114 of the immersion tank 1102 and the signals output by the temperature sensor(s) 116 and the humidity sensors 1116, 1118 in the environment 1103. For example, the sensor(s) 1114, 1116, 1118 can transmit data to on-board processor circuitry 1120 of the digital lock 1110. In other examples, the sensor(s) 1114, 1116, 1118 can transmit data to processor circuitry of another user device 1122, such as a smartphone or a wearable device such as a smartwatch. In other examples, the sensor(s) 1114, 1116, 1118 can transmit data to a cloud-based device 1124 (e.g., one or more server(s), processor(s), and/or virtual machine(s)).

The example immersion tank 1102 of FIG. 11 includes a display screen 1126. As disclosed herein, the display screen 1126 can present messages, notifications, and/or alerts to a user in connection with the opening of lid 1108 of the immersion tank 1102. In some examples, the display screen 1126 is a touch screen and the lock 1110 unlocks (or locks) in response to a user input received via the display screen 1126. In the example of FIG. 11, the processor circuitry 1120 implements display control circuitry 1128. The display control circuitry 1128 facilitates rendering of content (e.g., display frame(s) associated with graphical user interface(s)) via the display screen 1126.

In the example of FIG. 11, the signals output by the temperature sensor(s) 1114 of the immersion tank 1102 and the signals output by the temperature sensor(s) 1116 and the humidity sensors 1116, 1118 in the environment 1103 are processed by lock control circuitry 1130 to control a state of the lock 1110. In the example of FIG. 1, the lock control circuitry 1130 is implemented by executable instructions executed on the processor circuitry 1120 of the digital lock 1110. However, in other examples, the lock control circuitry 1130 is implemented by instructions executed on processor circuitry of the wearable or non-wearable user device 1122 and/or on the cloud-based device(s) 1124. In other examples, the lock control circuitry 1130 is implemented by dedicated circuitry located on one or more of the digital lock 1110 and/or the user device 1122. In some examples, one or more components of the example lock control circuitry 1130 are implemented by the on-board processor circuitry 1120 of the digital lock 1110 and one or more other components are implemented by the processor circuitry of the user device 1122 and/or the cloud-based device(s) 1124.

In the example system 1100, the lock control circuitry 1130 serves to process the sensor data generated by the respective sensor(s) 1114, 1116, 1118 to determine whether the lid 1108 of the immersion tank 1102 can be opened without the risk of air from the environment condensing into water on the surface of the cooling fluid 1104. In response to a request to unlock the lock 1110 and open the lid 1108 (e.g., received via a user input at the display screen 1126), the lock control circuitry 1130 determines, based on the sensor data, if the tank 1102 can be opened without a risk of introducing water into the tank 1102. In particular, the lock control circuitry 1130 determines, based on the sensor data, if a temperature of the cooling fluid 1104 is less than a dew point of the air in the environment. In the example of FIG. 11, if the temperature of the cooling fluid 1104 is less than the temperature of the air dew point, the lock control circuitry 1130 determines that the lid 1108 of the immersion tank 1102 can move to the open position without resulting in the introduction of water into the tank 1102. In such examples, the lock control circuitry 1130 causes the lock 1110 to unlock to enable a user to access an interior of the tank 1102.

In some examples, based on the temperature data for the cooling fluid 1104 and the temperature and humidity data for the air in the environment 1103, the lock control circuitry 1130 determines that the temperature of the cooling fluid 1104 is lower than the dew point of the air. In such examples, the lock control circuitry 1130 determines that if the lid 1108 is opened, moisture in the air can condense and damage the electronic component(s) 1106 in the tank. In response, the lock control circuitry 1130 maintains the lock 1110 in the locked state and generates an alert to be output via, for instance, the display screen 1126 to inform the user that the conditions in the tank 1102 and/or the environment 1103 are not appropriate for exposing the interior of the tank 1102 to the ambient environment.

In examples in which the lock control circuitry 1130 determines that the temperature of the cooling fluid 1104 is lower than the dew point of the air, the lock control circuitry 1130 outputs one or more instructions to adjust an operational state and/or behavior of one or more immersion cooling system components and/or devices in the environment in an effort to affect conditions in the tank 1102 and/or the environment 1103 that would permit the lock 1110 to move to the unlocked state. For example, as disclosed herein, the lock control circuitry 1130 can output instructions to cause the pump 1105 to temporarily stop operating and/or to adjust a fluid flow rate to increase a temperature of the cooling fluid 1104. In some examples, the lock control circuitry 1130 can output instructions to cause the heater 1107 in the tank 1102 to activate to increase a temperature of the cooling fluid 1104. In some examples, the lock control circuitry 1130 outputs instructions to one or more environmental temperature control devices 1131 to cause the device(s) 1131 to affect the humidity in the ambient environment 1103. For example, the lock control circuitry 1130 can cause an air conditioner or a fan in the room in which the tank 1102 is located to be activated.

The lock control circuitry 1130 monitors changes in conditions in the tank 1102 and/or the environment 1103 over time to determine if the lid 1108 of the tank 1102 can be opened without resulting in the condensation of moisture from the environment 1103 in the tank 1102. The lock control circuitry 1130 causes the lock 1110 to unlock when the lock control circuitry 1130 determines that the temperature of the cooling fluid 1104 is higher than the dew point of the air in the environment 1103.

Although the example lock 1110 is discussed in connection with the immersion tank 1102, the lock control circuitry 1130 can additionally or alternatively control access to a chassis carrying the immersion tank 1102, such as the chassis 402, 502, 702, 902 of the example immersion cooling systems 400, 500, 700, 900 of FIGS. 4-10. Additionally or alternatively, the lock control circuitry 1130 can control access to the environment 1103 in which one or more of the immersion tanks 1102 are located. For example, the environment 1103 of FIG. 11 can be a housing (e.g., the edge data center 106 of FIG. 1) including a door 1132. The immersion tank(s) 1102 in the housing 1103 can be used to cool, for instance, servers in an edge network. A digital lock 1134 (e.g., the same or substantially similar to the lock 1110) can be coupled to the door 1132 to provide selective access to the housing 1103 and, thus, the immersion tank 1102. A (e.g., second) display screen 1136 can be associated with lock 1134 to receive user requests to enter the housing 1103 and to display messages to a user. In such examples, the lock control circuitry 1130 can obtain temperature and humidity data for an environment exterior to the housing from the sensors 1116, 1118 located in the external environment to determine if opening the door 1132 will disrupt the conditions inside the housing and, thus, result in the condensation of moisture in the tank 1102.

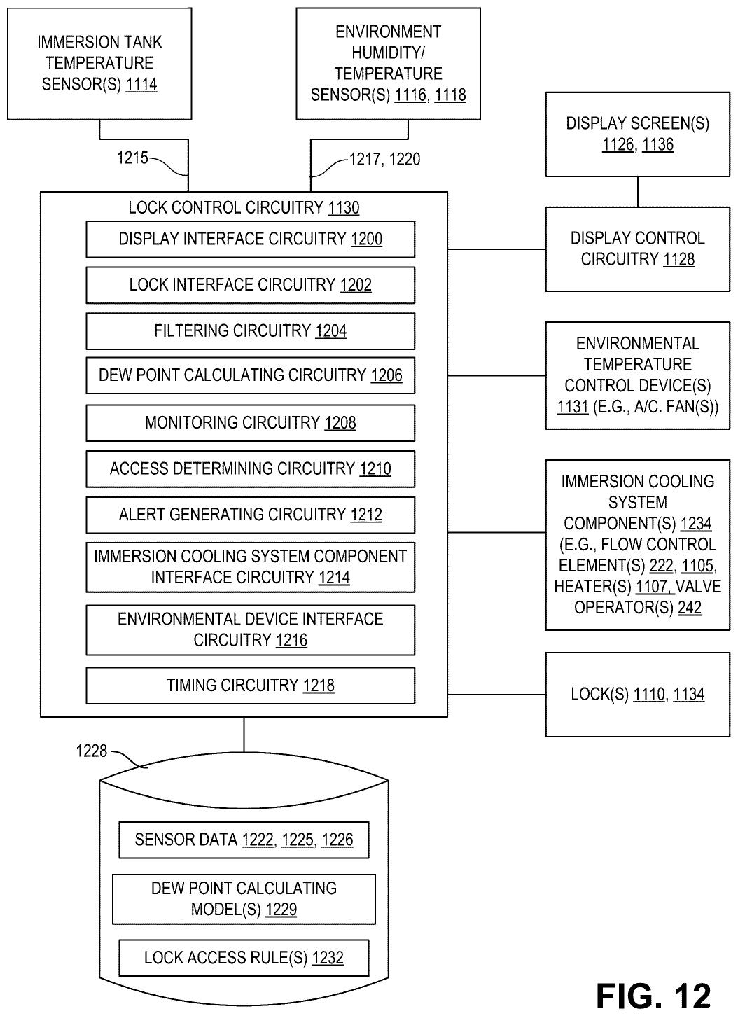

FIG. 12 is a block diagram of the example lock control circuitry 1130 to control access to an immersion tank (e.g., the immersion tanks 104, 108, 201, 404, 704, 904, 1102 of FIGS. 1, 2, 4-11) and/or an environment in which the immersion tank is located. The lock control circuitry 1130 of FIG. 12 may be instantiated (e.g., creating an instance of, bring into being for any length of time, materialize, implement, etc.) by processor circuitry such as a central processing unit executing instructions. Additionally or alternatively, the lock control circuitry 1130 of FIG. 12 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 12 may, thus, be instantiated at the same or different times. Some or all of the circuitry may be instantiated, for example, in one or more threads executing concurrently on hardware and/or in series on hardware. Moreover, in some examples, some or all of the circuitry of FIG. 12 may be implemented by one or more virtual machines and/or containers executing on the microprocessor.

The example lock control circuitry 1130 of FIG. 12 includes display interface circuitry 1200, lock interface circuitry 1202, filtering circuitry 1204, dew point calculating circuitry 1206, monitoring circuitry 1208, access determining circuitry 1210, alert generating circuitry 1212, immersion cooling system component interface circuitry 1214, environmental device interface circuitry 1216, and timing circuitry 1218.

In some examples, the display interface circuitry 1200 of the example lock control circuitry 1130 of FIG. 12 receives user request(s) to access the tank 1102 provided via the display screen 1126 associated with tank 1102 and/or user request(s) to access the environment 1103 including the tank 1102 via the display screen 1136 in the environment 1103. In some examples, the lock interface circuitry 1202 of the example lock control circuitry 1130 of FIG. 12 receives the user request(s) provided as input(s) at the lock(s) 1110, 1134 (e.g., keypad input(s)).

In the example of FIG. 12, signals 1215 output by the immersion tank temperature sensor(s) 1114 are transmitted to the lock control circuitry 1130. Also, signals 1217, 1220 output by the humidity and temperature sensors 1116, 1118, respectively, in the environment 1103 are transmitted to the lock control circuitry 1130. The filtering circuitry 1204 of the example lock control circuitry 1130 of FIG. 12 performs operations such as filtering the raw signal data, removing noise from the signal data, converting the signal data from analog data to digital data, etc. Sensor data 1222, 1225, 1226 corresponding to the filtered signals 1215, 1217, 1220 can be stored in a memory 1228. In some examples, the lock control circuitry 1130 includes the memory 1228. In some examples, the memory 1228 is located external to the lock control circuitry 1130 in a location accessible to the lock control circuitry 1130 as shown in FIG. 12.

In response to a user request to unlock the lock(s) 1110, 1134, the dew point calculating circuitry 1206 of the example lock control circuitry 1130 of FIG. 12 calculates a dew point for the air in the ambient environment (e.g., the environment 1103, or an environment external to the environment 1103 when access to be provided with respect to, for example the housing 1103). The dew point calculating circuitry 1206 determines the dew point for the ambient air based on the sensor data 1225 from the temperature sensor(s) 1116 in the environment and the humidity sensor(s) 1118. The dew point calculating circuitry 1206 calculates the dew point based on one or more dew point calculating model(s) 1229 stored in the memory 1228. The dew point calculating model(s) 1229 can include, for instance, reference data associating air temperature with relative humidity.

The monitoring circuitry 1208 of the example lock control circuitry 1130 of FIG. 12 determines a temperature of the cooling fluid 1104 in the immersion tank 1102 based on the sensor data 1222 from the temperature sensor(s) 1114 of the immersion tank 1102. The monitoring circuitry 1208 performs a comparison between the dew point for the air calculated by the dew point calculating circuitry 1206 and the temperature of the cooling fluid 1104. In the example of FIG. 12, the monitoring circuitry 1208 outputs a first indicator if the temperature of the cooling fluid 1104 is higher than the dew point and a second indicator if the temperature of the cooling fluid 1104 is less than the dew point of the ambient air.

The example access determining circuitry 1210 analyzes the indicator(s) received from the monitoring circuitry 1208 in response to the user request to unlock the lock(s) 1110, 1134. The access determining circuitry 1210 determines, based on lock access rule(s) 1232, if the conditions in the tank 1102 and/or the ambient environment permit the immersion tank 1102 to be opened or uncovered without water forming in the tank from the condensation of the ambient air. The lock access rule(s) 1232 can be defined by user inputs and stored in the memory 1228.

In examples in which the indicator received from the monitoring circuitry 1208 represents that that temperature of the cooling fluid 1104 is higher than the dew point, the access determining circuitry 1210 determines, based on the rule(s) 1232, that the lock(s) 1110, 1134 can be unlocked such that the lid 1108 of the tank 1102 can be opened without air in the ambient environment condensing into water on a surface of the cooling fluid 1104. In response, the access determining circuitry 1210 outputs instructions to cause the lock(s) 1110, 1134 to unlock. The instruction(s) can be transmitted via the lock interface circuitry 1202.

In some examples, in response to permitting the lock 1110, 1134 to unlock, the alert generating circuitry 1212 of the example lock control circuitry 1130 causes message(s) or notification(s) to be presented via the display screen(s) 1126, 1136 and/or a display screen of the user device 1122 of FIG. 11 informing the user that the lock(s) 1110, 1134 are unlocked. In some examples, the user can provide input(s) via the display screen 1126, 1136 and/or the user device 1122 to cause the lid 1108 or the door 1132 to open (e.g., automatically open).

If the indicator from the monitoring circuitry 1208 represents that the temperature of the cooling fluid 1104 is less than the dew point, then the access determining circuitry 1210 determines, based on the lock access rule(s) 1232, that the lock(s) 1110, 1134 should not be unlocked to permit access to the immersion tank 1102 and/or environment 1103 at the given time. In such examples, the access determining circuitry 1210 refrains from generating the instructions that would cause the lock(s) 1110, 1134 to unlock.

When the access determining circuitry 1210 determines that the lock(s) 1110, 1134 should not be unlocked, the alert generating circuitry 1212 causes a notification or alert to be output via the display screen(s) 1126, 1136 and/or the user device 1122 informing the user that the conditions at the tank 1102 and/or the environment 1103 are not favorable for accessing the tank 1102 and/or the environment 1103 due to the risk of moisture in the air condenses and, thus, the lock(s) 1110, 1134 have not been unlocked. In some examples, the messages, notifications, and/or alerts displayed by the display screen(s) 1126, 1136 include alpha-numeric code(s) representing the status or conditions and/or controls for scrolling through the presented statuses.

In some examples, when the access determining circuitry 1210 determines that the lock(s) 1110, 1134 should not be unlocked, the access determining circuitry 1210 outputs instructions to cause conditions in the tank 1102 to be adjusted such that temperature of the cooling fluid 1104 will be higher than the dew point. For example, the access determining circuitry 1210 can generate instruction(s) to cause the pump 1105 to be disabled such that heated cooling fluid 1104 is not removed from the immersion tank 1102 for a period of time to increase the temperature of the cooling fluid 1104. The access determining circuitry 1210 can generate instruction(s) to cause the pump 1105 to adjust a flow rate of fluid. In some examples, the access determining circuitry 1210 generates instruction(s) to control electro-mechanical valve operator(s) (e.g., electro-mechanical valve operator(s) 222 of FIGS. 2A, 2C) associated with tubing of the immersion cooling tank 1102 to adjust state(s) of fluid flow valve(s) associated with the tank 1102. In some examples, the access determining circuitry 1210 generates instruction(s) to activate the heater(s) 1107 or to cause a temperature of heat generated by the heater(s) 1107 of the immersion tank 1102 to increase the temperature of the cooling fluid 1104. The instructions to immersion cooling system components 1234 such as the flow control element(s) 222, 1105 of FIGS. 2A and/or 11 (e.g., pumps, electro-mechanical valve operator(s)) and/or the heater(s) 1107 can be transmitted via the immersion cooling system component interface circuitry 1214. In some examples, the instruction(s) are transmitted to control system circuitry of the immersion cooling system 1100, such as the example control system circuitry 224 of FIG. 2C. The control system circuitry 224 can communicate the instructions to the immersion cooling system component(s) 1234 for execution.

In some examples, when the access determining circuitry 1210 determines that the lock(s) 1110, 1134 should not be unlocked, the access determining circuitry 1210 outputs instructions to cause conditions in the ambient environment (e.g., the environment 1103) to be adjusted such that temperature of the cooling fluid 1104 will be higher than the dew point of the air. For example, the access determining circuitry 1210 can generate instructions to activate an air conditioner in the environment 1103 to decrease the humidity in the air and/or lower the air temperature in the environment 1103. In some examples, the access determining circuitry 1210 generates instructions to activate fan(s) in the environment 1103 to decrease the temperature in the environment 1103. The instructions to the environmental temperature control device(s) 1131 can be transmitted via the environmental device interface circuitry 1216.

In some examples, when the access determining circuitry 1210 determines that the lock(s) 1110, 1134 should not be unlocked, the accessing circuitry 1210 calculates or estimates a time for conditions in the tank 1102 and/or the environment 1103 to be adjusted such that the temperature of the cooling fluid 1104 will be higher than the dew point. For example, the access determining circuitry 1210 can determine an amount of time to increase the temperature of the cooling fluid 1104 to a particular temperature based on specific heat capacity of the cooling fluid 1104. In some examples, the message(s) generated by the alert generating circuitry 1212 and presented via the display screen(s) 1126, 1136 inform the user of the estimated time after which conditions in the tank 1102 and/or the ambient environment may be adequate to enable the lock(s) 1110, 1134 to be unlocked.

In some such examples, although the access determining circuitry 1210 determines that the lock(s) 1110, 1134 should not be unlocked, the access determining circuitry 1210 permits a manual override of the lock state. For example, when the user selects the override option (e.g., the via the display screen(s) 1126, 1136), the access determining circuitry 1210 generates instructions to cause the lock(s) 1110, 1134 to unlock despite the temperature of the cooling fluid 1104 being less than the dew point.

In examples in which the lock(s) 1110, 1134 remain in the locked state, the dew point calculating circuitry 1206 and the monitoring circuitry 1208 continue to analyze the sensor data 1222, 1225, 1226 to determine if the dew point and/or the temperature of the cooling fluid 1104 has changed over time (e.g., due to the disabling of the pump, activation of the fans, etc.). The monitoring circuitry 1208 outputs the indicators to the access determining circuitry 1210 as to whether or not the temperature of the cooling fluid 1104 is higher than the dew point based on the dew point calculations and fluid temperature readings over time.

When the access determining circuitry 1210 receives the indicator from the monitoring circuitry 1208 that the temperature of the cooling fluid 1104 is higher than the dew point, the alert generating circuitry 1212 can cause a message or notification to be displayed via the display screen(s) 1126, 1136 indicating that the lock(s) 1110, 1134 can be unlocked. In some such examples, the access determining circuitry 1210 generates instructions to cause the lock(s) 1110, 1134 to move to the unlocked state in response to receiving a user input confirming that the lock(s) 1110, 1134 should be unlocked (e.g., another user request or input after the initial user request). In some examples, the access determining circuitry 1210 automatically causes the lock(s) 1110, 1134 to move to the unlocked state in response to determining that the lock access rule(s) 1232 are satisfied.

The timing circuitry 1218 of the example lock control circuitry 1130 of FIG. 12 monitors a time for which, for instance, the pump(s) 1105 are disabled and/or the heater(s) 1107 of the immersion tank 1102 are activated when access determining circuitry 1210 generates instructions for the temperature of the cooling fluid 1104 to increase. In some examples, the timing circuitry 1218 generates instructions for the pump(s) 1105 to be re-activated and/or to adjust a fluid flow rate after predefined time threshold(s) to prevent overheating of the cooling fluid 1104. In some examples, the timing circuitry 1218 generates instructions for the heater(s) 1107 to turn off or decrease in temperature after predefined time threshold(s) to prevent overheating of the cooling fluid 1104. Additionally or alternatively, in some examples, the timing circuitry 1218 generates instructions with respect to operational states and/or behaviors of the immersion cooling system component(s) 1234 and/or the environmental temperature control device(s) 1131 based on temperature of the cooling fluid 1104 over time and/or the changes in the dew point of the air over time. The time-based monitoring performed by the timing circuitry 1218 prevents, for instance, overheating of the cooling fluid 1104, the dew point of the air in the ambient environment from falling below a predefined threshold, etc.

In some examples, the dew point calculating circuitry 1206, the monitoring circuitry 1208, the access determining circuitry 1212, and/or the timing circuitry 1218 monitor conditions in the tank 1102 and/or the ambient environment when the lock(s) 1110, 1134 are unlocked and, thus, the lid 1108 of the tank 1102 is open and/or the door 1135 of the environment 1103 is opened. For example, the monitoring circuitry 1208 can detect trend(s) in the temperature of the cooling fluid 1104 over time when the lid 1108 of the tank 1102 is opened. Based on the trend(s), the monitoring circuitry 1208 can determine that the fluid temperature will no longer be higher than the dew point within a particular duration of time. In response, the alert generating circuitry 1212 can output alert(s) (e.g., visual alerts via the display screen(s) 1126, 1136, audio alerts via the user device 1122 of FIG. 11) indicating that lid 1108 should be closed to prevent moisture in the air from condensing in the tank 1102. The timing circuitry 1218 can also monitor a time for which the lid 1108 is opened relative to a threshold (e.g., a user-defined threshold setting).

In some examples, the monitoring performed by one or more of the dew point calculating circuitry 1206, the monitoring circuitry 1208, the access determining circuitry 1212, and/or the timing circuitry 1218 is based on a safety envelope or interlock settings with respect to the performance of immersion cooling. For example, the monitoring circuitry 1208 and/or the timing circuitry 1218 can receive warnings from control system circuitry (e.g., the control system circuitry 224 of FIG. 2C) regarding adverse developing condition(s) in the immersion cooling unit 1102 when the lid 1108 is open and/or before the lid 1108 is opened. The warnings can indicate, for instance, a stoppage of flow, excessive coolant temperature at a level that may result in damage to the electronic component(s), a time for which the lid 1108 has been open, etc. The lock control circuitry 1130 can control access to the immersion tank 1102 and/or the environment 1103 based on the information from the control system circuitry for the immersion tank 1102.

The lock(s) 1110, 1134 can move from the unlocked state to the locked state in response to, for example, a user closing the lid 1108 of the tank 1102 and/or the door 1132 of the housing 1103.

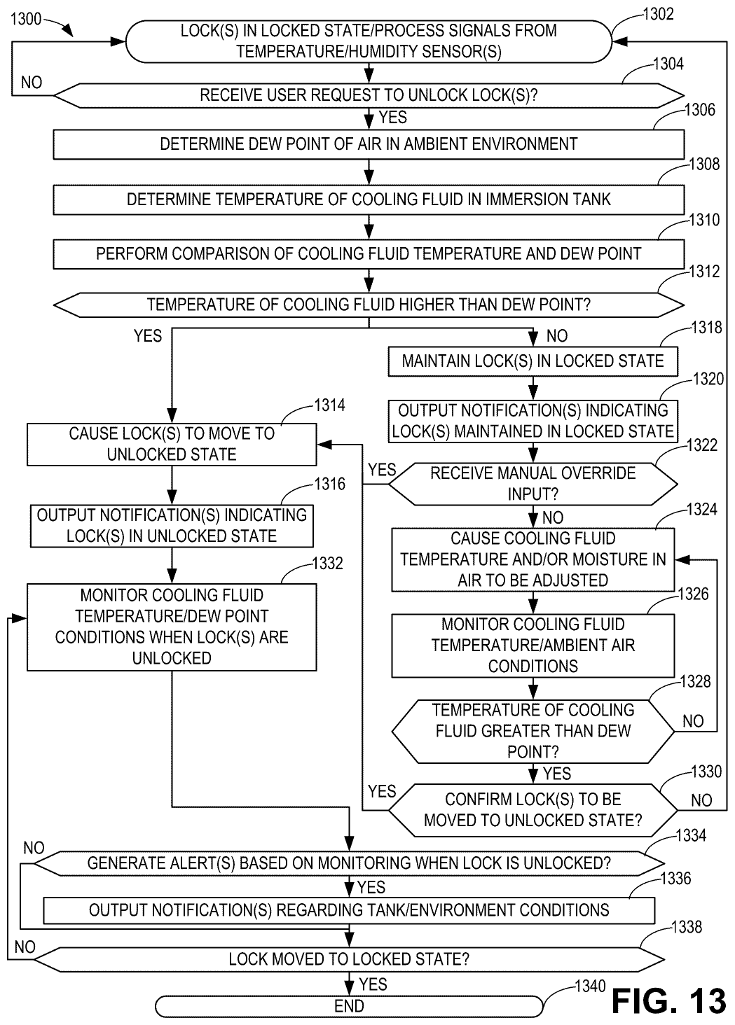

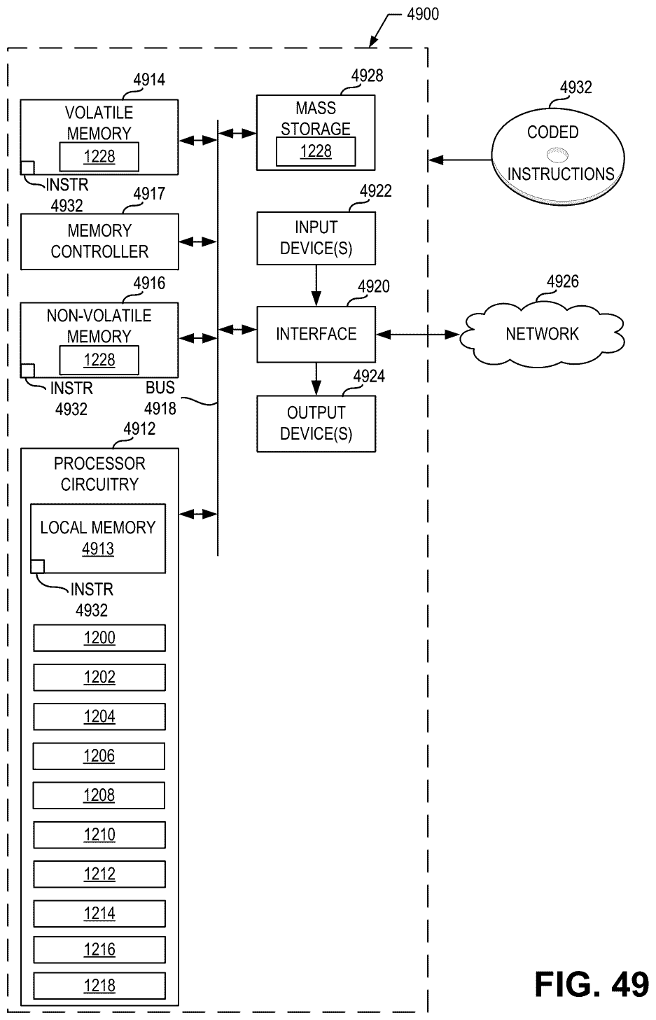

In some examples, the lock control circuitry 1130 includes means for interfacing with a display. For example, the means for interfacing with a display may be implemented by the display interface circuitry 1200. In some examples, the display interface circuitry 1200 may be instantiated by processor circuitry such as the example processor circuitry 4912 of FIG. 49. For instance, the display interface circuitry 1200 may be instantiated by the example general purpose processor circuitry 5000 of FIG. 50 executing machine executable instructions such as that implemented by at least blocks 1304, 1316, 1320, 1336 of FIG. 13. In some examples, the display interface circuitry 1200 may be instantiated by hardware logic circuitry, which may be implemented by an ASIC or the FPGA circuitry 5100 of FIG. 51 structured to perform operations corresponding to the machine readable instructions. Additionally or alternatively, the display interface circuitry 1200 may be instantiated by any other combination of hardware, software, and/or firmware. For example, the display interface circuitry 1200 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for interfacing with a lock. For example, the means for interfacing with a lock may be implemented by the lock interface circuitry 1202. In some examples, the lock interface circuitry 1202 may be instantiated by processor circuitry such as the example processor circuitry 4912 of FIG. 49. For instance, the lock interface circuitry 1202 may be instantiated by the example general purpose processor circuitry 5000 of FIG. 50 executing machine executable instructions such as that implemented by at least blocks 1302, 1304, 1314, 1338 of FIG. 13. In some examples, the lock interface circuitry 1202 may be instantiated by hardware logic circuitry, which may be implemented by an ASIC or the FPGA circuitry 5100 of FIG. 51 structured to perform operations corresponding to the machine readable instructions. Additionally or alternatively, the display interface circuitry 1200 may be instantiated by any other combination of hardware, software, and/or firmware. For example, the display interface circuitry 1200 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for filtering. For example, the means for filtering may be implemented by the filtering circuitry 1204. In some examples, the filtering circuitry 1204 may be instantiated by processor circuitry such as the example processor circuitry 4912 of FIG. 49. For instance, the filtering circuitry 1204 may be instantiated by the example general purpose processor circuitry 5000 of FIG. 50 executing machine executable instructions such as that implemented by at least blocks 1302 of FIG. 13. In some examples, the filtering circuitry 1204 may be instantiated by hardware logic circuitry, which may be implemented by an ASIC or the FPGA circuitry 5100 of FIG. 51 structured to perform operations corresponding to the machine readable instructions. Additionally or alternatively, the filtering circuitry 1204 may be instantiated by any other combination of hardware, software, and/or firmware. For example, the filtering circuitry 1204 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for calculating a dew point. For example, the means for calculating a dew point may be implemented by the dew point calculating circuitry 1206. In some examples, the dew point calculating circuitry 1206 may be instantiated by processor circuitry such as the example processor circuitry 4912 of FIG. 49. For instance, the dew point calculating circuitry 1206 may be instantiated by the example general purpose processor circuitry 5000 of FIG. 50 executing machine executable instructions such as that implemented by at least blocks 1306, 1326, 1332 of FIG. 13. In some examples, the dew point calculating circuitry 1206 may be instantiated by hardware logic circuitry, which may be implemented by an ASIC or the FPGA circuitry 5100 of FIG. 51 structured to perform operations corresponding to the machine readable instructions. Additionally or alternatively, the dew point calculating circuitry 1206 may be instantiated by any other combination of hardware, software, and/or firmware. For example, the dew point calculating circuitry 1206 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for monitoring. For example, the means for monitoring may be implemented by the monitoring circuitry 1208. In some examples, the monitoring circuitry 1208 may be instantiated by processor circuitry such as the example processor circuitry 4912 of FIG. 49. For instance, the monitoring circuitry 1208 may be instantiated by the example general purpose processor circuitry 5000 of FIG. 50 executing machine executable instructions such as that implemented by at least blocks 1308, 1310, 1312, 1326, 1328, 1332 of FIG. 13. In some examples, the monitoring circuitry 1208 may be instantiated by hardware logic circuitry, which may be implemented by an ASIC or the FPGA circuitry 5100 of FIG. 51 structured to perform operations corresponding to the machine readable instructions. Additionally or alternatively, the monitoring circuitry 1208 may be instantiated by any other combination of hardware, software, and/or firmware. For example, the monitoring circuitry 1208 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for determining access. For example, the means for determining access may be implemented by the access determining circuitry 1210. In some examples, the access determining circuitry 1210 may be instantiated by processor circuitry such as the example processor circuitry 4912 of FIG. 49. For instance, the access determining circuitry 1210 may be instantiated by the example general purpose processor circuitry 5000 of FIG. 50 executing machine executable instructions such as that implemented by at least blocks 1314, 1318, 1322, 1324, 1330, 1332 of FIG. 13. In some examples, the access determining circuitry 1210 may be instantiated by hardware logic circuitry, which may be implemented by an ASIC or the FPGA circuitry 5100 of FIG. 51 structured to perform operations corresponding to the machine readable instructions. Additionally or alternatively, the access determining circuitry 1210 may be instantiated by any other combination of hardware, software, and/or firmware. For example, the access determining circuitry 1210 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for generating alerts. For example, the means for generating alerts may be implemented by the alert generating circuitry 1212. In some examples, the alert generating circuitry 1212 may be instantiated by processor circuitry such as the example processor circuitry 4912 of FIG. 49. For instance, the alert generating circuitry 1212 may be instantiated by the example general purpose processor circuitry 5000 of FIG. 50 executing machine executable instructions such as that implemented by at least blocks 1316, 1320, 1334, 1336 of FIG. 13. In some examples, the alert generating circuitry 1212 may be instantiated by hardware logic circuitry, which may be implemented by an ASIC or the FPGA circuitry 5100 of FIG. 51 structured to perform operations corresponding to the machine readable instructions. Additionally or alternatively, the alert generating circuitry 1212 may be instantiated by any other combination of hardware, software, and/or firmware. For example, the alert generating circuitry 1212 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for interfacing with a system component. For example, the means for interfacing with a system component may be implemented by the immersion cooling system component interface circuitry 1212. In some examples, the immersion cooling system component interface circuitry 1212 may be instantiated by processor circuitry such as the example processor circuitry 4912 of FIG. 49. For instance, the immersion cooling system component interface circuitry 1212 may be instantiated by the example general purpose processor circuitry 5000 of FIG. 50 executing machine executable instructions such as that implemented by at least block 1324 of FIG. 13. In some examples, the immersion cooling system component interface circuitry 1212 may be instantiated by hardware logic circuitry, which may be implemented by an ASIC or the FPGA circuitry 5100 of FIG. 51 structured to perform operations corresponding to the machine readable instructions. Additionally or alternatively, the immersion cooling system component interface circuitry 1212 may be instantiated by any other combination of hardware, software, and/or firmware. For example, the immersion cooling system component interface circuitry 1212 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for interfacing with an environmental device. For example, the means for interfacing with an environmental device may be implemented by the environmental device interface circuitry 1216. In some examples, the environmental device interface circuitry 1216 may be instantiated by processor circuitry such as the example processor circuitry 4912 of FIG. 49. For instance, the environmental device interface circuitry 1216 may be instantiated by the example general purpose processor circuitry 5000 of FIG. 50 executing machine executable instructions such as that implemented by at least block 1324 of FIG. 13. In some examples, the environmental device interface circuitry 1216 may be instantiated by hardware logic circuitry, which may be implemented by an ASIC or the FPGA circuitry 5100 of FIG. 51 structured to perform operations corresponding to the machine readable instructions. Additionally or alternatively, the environmental device interface circuitry 1216 may be instantiated by any other combination of hardware, software, and/or firmware. For example, the environmental device interface circuitry 1216 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the lock control circuitry 1130 includes means for timing. For example, the means for timing may be implemented by the timing circuitry 1218. In some examples, the timing circuitry 1218 may be instantiated by processor circuitry such as the example processor circuitry 4912 of FIG. 49. For instance, the timing circuitry 1218 may be instantiated by the example general purpose processor circuitry 5000 of FIG. 50 executing machine executable instructions such as that implemented by at least blocks 1326, 1332 of FIG. 13. In some examples, the timing circuitry 1218 may be instantiated by hardware logic circuitry, which may be implemented by an ASIC or the FPGA circuitry 5100 of FIG. 51 structured to perform operations corresponding to the machine readable instructions. Additionally or alternatively, the timing circuitry 1218 may be instantiated by any other combination of hardware, software, and/or firmware. For example, the timing circuitry 1218 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

While an example manner of implementing the lock control circuitry 1130 of FIG. 11 is illustrated in FIG. 12, one or more of the elements, processes, and/or devices illustrated in FIG. 12 may be combined, divided, re-arranged, omitted, eliminated, and/or implemented in any other way. Further, the example display interface circuitry 1200, the example lock interface circuitry 1202, the example filtering circuitry 1204, the example dew point calculating circuitry 1206, the example monitoring circuitry 1208, the example access determining circuitry 1210, the example alert generating circuitry 1212, the example immersion cooling system component interface circuitry 1214, the example environmental device interface circuitry 1216, the example timing circuitry 1218, and/or, more generally, the example lock control circuitry 1130 of FIG. 11, may be implemented by hardware alone or by hardware in combination with software and/or firmware. Thus, for example, any of the example display interface circuitry 1200, the example lock interface circuitry 1202, the example filtering circuitry 1204, the example dew point calculating circuitry 1206, the example monitoring circuitry 1208, the example access determining circuitry 1210, the example alert generating circuitry 1212, the example immersion cooling system component interface circuitry 1214, the example environmental device interface circuitry 1216, the example timing circuitry 1218, and/or, more generally, the example lock control circuitry 1130, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example lock control circuitry 1130 of FIG. 11 may include one or more elements, processes, and/or devices in addition to, or instead of, those illustrated in FIG. 12, and/or may include more than one of any or all of the illustrated elements, processes and devices.

FIG. 13 is a flowchart representative of example machine readable instructions and/or example operations 1300 that may be executed and/or instantiated by processor circuitry to control access to an immersion tank and/or an environment (e.g., the environment 1103) in which the immersion tank is located. The machine readable instructions and/or the operations 1300 of FIG. 13 begin at block 1302, at which the filtering circuitry 1204 of the lock control circuitry 1130 of FIG. 12 processes the signals (e.g., removes noise from the signals) from the temperature sensor(s) 1114 in the immersion tank 1102 and the humidity and temperature sensor(s) 1116, 1118 in the ambient environment (e.g., the environment 1103). Also, at block 1302, the lock(s) 1110, 1134 are in the locked state.

At block 1304, the display interface circuitry 1200 and/or the lock interface circuitry 1202 determines if a request to unlock the lock(s) 1110, 1134 has been received. If a request to unlock the lock(s) 1110, 1134 has been received, then at block 1306, the dew point calculating circuitry 1206 calculates a dew point of the air in the ambient environment based on the sensor data 1125, 1226 from the humidity and temperature sensor(s) 1116, 1118 in the environment and the dew point calculating model(s) 1229. Also, at block 1308, the monitoring circuitry 1208 determines the temperature of the cooling fluid 1104 in the immersion tank 1102 based on the temperature sensor(s) 1114 in the tank 1102.

At block 1310, the monitoring circuitry 1208 performs a comparison of the cooling fluid temperature and the dew point of the air in the ambient environment. At block 1312, the monitoring circuitry 1208 determines if the temperature of the cooling fluid 1104 in the immersion tank 1102 is higher than the dew point of the air in the ambient environment.

If, at block 1312, the monitoring circuitry 1208 determines that the cooling fluid temperature is higher than the dew point, then at block 1314, the access determining circuitry 1210 generates instruction(s) to cause the lock(s) 1110, 1134 to move to the unlocked state. Also, at block 1316, the alert generating circuitry 1212 causes notification(s) to be presented via, for instance, the display screen(s) 1126, 1136 and/or the user device 1122 to inform a user that the lock(s) 1110, 1134 are unlocked.

If, at block 1312, the monitoring circuitry 1208 determines that the cooling fluid temperature is less than the dew point, then at block 1318, the access determining circuitry 1210 determines that the lock(s) 1110, 1134 should not be unlocked due to the risk of moisture in the air condensing in the opened immersion tank 1102 (e.g., based on the lock access rule(s) 1232). At block 1320, the alert generating circuitry 1212 output(s) notification(s) indicating that the lock(s) 1110, 1134 are maintained in the locked state due to the risk of condensation. In some examples, the notification(s) generated by the alert generating circuitry 1212 inform the user of an estimated time after which conditions in the tank 1102 and/or the ambient environment may be adequate to enable the lock(s) 1110, 1134 to be unlocked based on estimates generated by the access determining circuitry 1210.

At block 1322, the display interface circuitry 1200 and/or the lock interface circuitry 1202 determines if a user request to override the decision to maintain the lock(s) 1110, 1134 in the locked state has been received. If a user override request has been received, then control proceeds to block 1314, where the access determining circuitry 1210 generates instructions to cause the lock(s) 1110, 1134 to unlock.

If the user override request has not been received, then at block 1324, the access determining circuitry 1210 generates instructions to cause the temperature of the cooling fluid to be adjusted (e.g., increased) or the moisture in the air of the ambient environment to be adjusted. In some examples, the access determining circuitry 1210 generates instructions for the pump(s) 1105 to be temporarily disabled to prevent the removal of heated cooling fluid 1104 from the tank 1102 and/or instructs the heater(s) 1107 in the tank 1102 to activate to increase a temperature of the cooling fluid. In some examples, the access determining circuitry 1210 generates instructions to adjust operational state(s) and/or behaviors of temperature control device(s) 1131 in the ambient environment, such as fan(s) or an air conditioner, to affect the moisture in the air. The instructions can be output via the immersion cooling system component interface circuitry 1214 and/or the environmental device interface circuitry 1216.

At block 1326, one or more of the dew point calculating circuitry 1206, the monitoring circuitry 1208, or the timing circuitry 1218 monitors the temperature of the cooling fluid 1104 and/or the conditions of the ambient air (e.g., humidity) over time in view of the instruction(s) output to the environmental temperature control device(s) 1131 and/or the immersion cooling system component(s) 1234. For example, the timing circuitry 1218 can monitor a duration of time for which the pump(s) 1105 are deactivated to prevent overheating of the cooling fluid 1104.

At block 1328, the monitoring circuitry 1208 determines (e.g., re-evaluates) if the temperature of the cooling fluid is higher than the dew point as a result of the instruction(s) to adjust the conditions in the tank 1102 and/or the ambient environment. If the temperature of the cooling fluid is higher than the dew point, the access determining circuitry 1210 determines that the lock(s) 1110, 1134 can be unlocked. In some examples, at block 1330, the alert generating circuitry 1212 output notification(s) to re-confirm that the user would like to unlock the lock(s) 1110, 1134 before the access determining circuitry 1210 causes the lock(s) 1110, 1134 to move to the unlocked state. If the lock(s) 1110, 1134 are to be unlocked, control proceeds to block 1314, where the access determining circuitry 1210 causes the lock(s) 1110, 1134 to move to the unlocked state.

At block 1332, one or more of the dew point calculating circuitry 1206, the monitoring circuitry 1208, the access determining circuitry 1210, or the timing circuitry 1218 monitors the temperature of the cooling fluid 1104 and/or the conditions of the ambient air (e.g., humidity) over time when the lock(s) 1110, 1134 are unlocked. At block 1334, the access determining circuitry 1210 determines whether alert(s) should be generated in view of, for instance, an increased risk of condensation when the lock(s) 110, 1134 are unlocked based on the monitoring. At block 1336, the alert generating circuitry 1212 outputs the alert(s) (e.g., audio alert(s), visual alert(s)) via the display screen(s) 1126, 1136 and/or the user device 1122.

The example instructions 1300 of FIG. 13 end at block 1338, 1340 when the lock(s) 1110, 1134 return to the locked state.

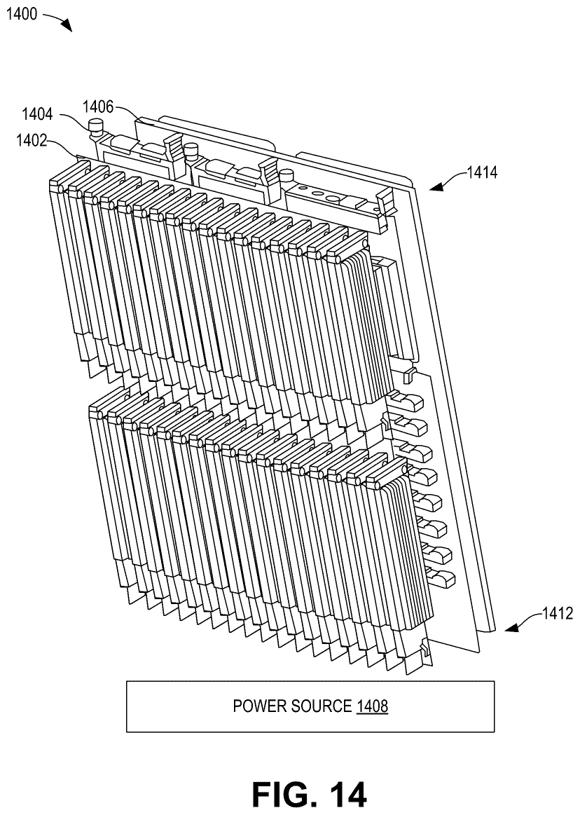

FIG. 14 illustrates an example server 1400 in accordance with teaching of this disclosure. The example server 1400 can be disposed in, for instance, the example immersion cooling tanks 104, 108, 201, 400, 500, 700, 900, 1102 of FIGS. 1, 2A, 2B, and/or 4-11, for cooling of the server 1400 via single-phase immersion cooling or two-phase immersion cooling. The example server 1400 of FIG. 14 is defined by a set of individual sleds that support various components of the server 1400. In the example of FIG. 14, a first sled 1402 of the server 1400 supports electronic components for storage and memory processes, a second sled 1404 of the server 1400 supports electronic components for compute processes, and a third sled 1406 of the server 1400 supports electronic components for accelerator processes. The example server 1400 can include additional sleds, such as a power supply sled, and/or sleds supporting other types of electronic components. As disclosed herein, the electronic components supported by each sled 1402, 1404, 1406 can be communicatively coupled to components on other sleds 1402, 1404, 1406 via, for example, cables.

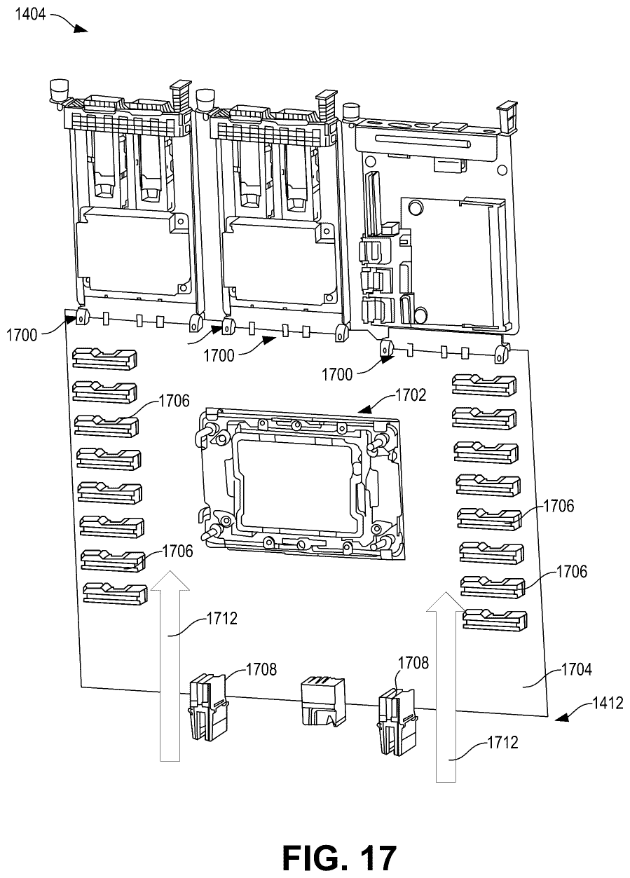

In the example of FIG. 14, each of the sleds 1402, 1404, 1406 is communicatively coupled to a power source 1408 (e.g., a power distribution board) that provides power to each of the sleds. As disclosed herein, when the server 1400 of FIG. 14 is disposed in an immersion tank, connectors carried by the respective sleds 1402, 1404, 1406 to enable coupling with the power source 1408 are disposed at a first end 1412 of the respective sleds 1402, 1404, 1406 (as shown in more detail in the example of FIG. 17).

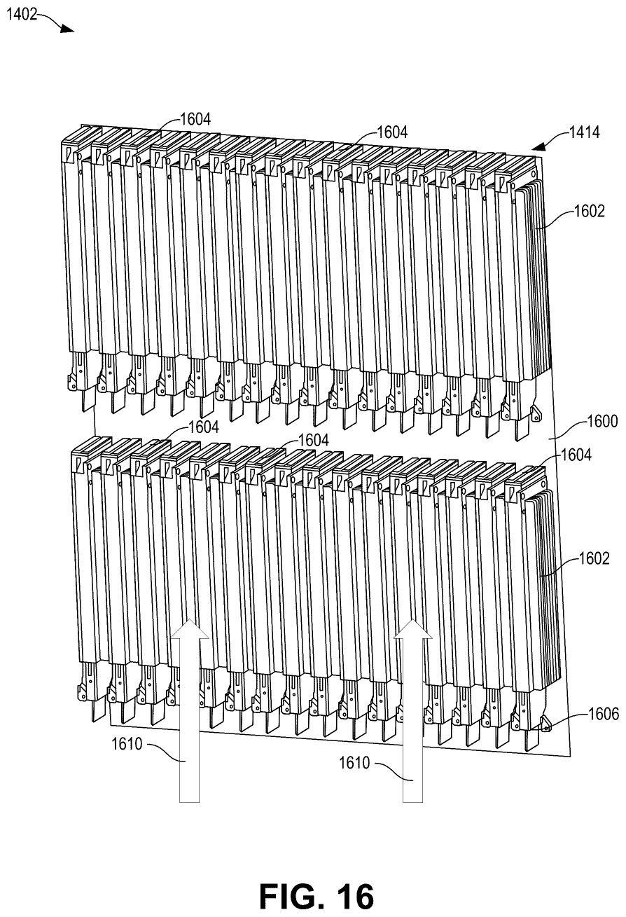

Also, one or more of the sled(s) 1402, 1404, 1404 includes input/output (I/O) connectors (FIG. 16). The I/O connectors can be disposed at the first end 1412 of respective sled(s) 1402, 1404, 1406 or at an opposing second end 1414 of the respective sled(s) 1402, 1404, 1404. As disclosed herein, the input/output (I/O) connectors can include connectors to receive network cards, cables, connections for fiber optic networking cards or cables (e.g., small form-factor pluggable (SFP), dual small form factor pluggable (DSFP), quad small form-factor pluggable (QSFP)), etc. In some examples, the I/O connections can include memory or storage attachment I/O connections (e.g., Compute Express Link (CXL), NVM express (NVMe), Peripheral Component Interconnect express (PCIe), etc.), connections for other peripherals (e.g., universal serial bus (USB)), and/or connections for a DataCenter Security Control Module (DC-SCM) (e.g., to communicatively couple the server 1400 to a control system of a data center in a secured fashion).

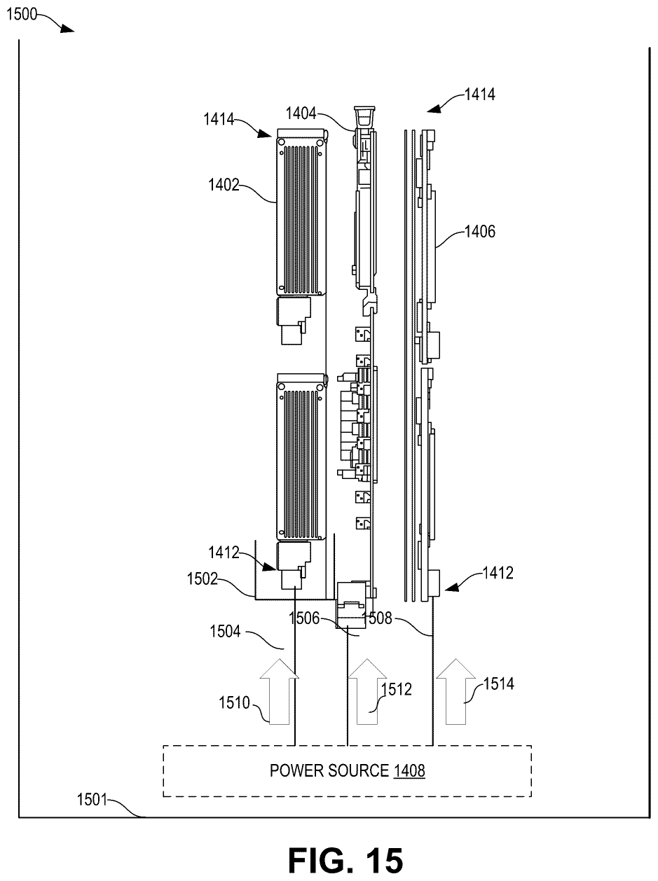

FIG. 15 is a side view of the example server 1400 of FIG. 14 illustrating the first storage/memory sled 1402, the second compute sled 1404, and the third accelerator sled 1406. In operation, the sleds 1402, 1404, 1406 generate heat. For illustrative purposes, an immersion tank 1500 is represented in FIG. 15, where the sleds 1402, 1404, 1406 are received in the immersion tank to cool the sleds 1402, 1404, 1406 during operation of the sleds 1402, 1404, 1406.

The example server 1400 including the sleds 1402, 1404, 1406 has a form factor designed to facilitate immersion of the server 1400 in an immersion cooling tank. For example, the sleds 1402, 1404, 1406 are oriented in the immersion tank 1500 in a vertical orientation as shown in FIG. 15. The first end 1412 of each sled 1402, 1404, 1406 is proximate to a surface 1501 (e.g., a bottom surface) of the tank 1500 opposite a lid of the tank 1500 (e.g., the lid 1108 of FIG. 11) and the second end 1414 of each sled 1402, 1404, 1406 is proximate to the lid. In some examples, the first end 1412 of the respective sleds 1402, 1404, 1406 includes mechanical supports or fasteners 1502 to removably secure (e.g., clamp) a respective sled 1402, 1404, 1406 to supporting structures in the immersion tank 1500 (e.g., to support the vertical orientation of the sleds 1402, 1404, 1406 shown in FIG. 15). As represented by the lines 1504, 1506, 1508, each of the sleds 1402, 1404, 1406 is communicatively coupled to the power source 1408 via the first end 1412 of each sled 1402, 1404, 1406. The sleds 1402, 1404, 1406 can be oriented in the immersion tank 1500 other orientations (e.g., at an angle).

As represented by arrows 1510, 1512, 1514 in FIG. 15, cooling fluid flows along and/or between the sleds 1402, 1404, 1406 when the server 1400 is disposed in the immersion tank 1500. The disaggregated or modular nature of the sleds 1402, 1404, 1406 of the server 1400 can result in more efficient cooling of the server components 1400 as compared to known servers that include components housed in a single chassis.

The vertical orientation of the sleds 1402, 1404, 1406 shown in FIG. 15 when the sleds 1402, 1404, 1406 are disposed in the immersion tank 1500 can facilitate case of insertion and removal of the respective sleds 1402, 1404, 1406 from the tank. For example, the sleds 1402, 1404, 1406 can be individually removed from the immersion tank 1500 for maintenance purposes without removing all of the sleds 1402, 1404, 1406. Because the sleds 1402, 1404, 1406 of the server 1400 are disaggregated, the weight of each sled 1402, 1404, 1406 is less than a weight of a server including a chassis that encloses the CPU, memory devices, accelerators, etc. The reduced weight of the sleds 1402, 1404, 1406 further facilities case of access and can eliminate the need for a mechanical hoisting device (e.g., a ceiling crane) to lift the sleds 1402, 1404, 1406 from the immersion tank 1500.

Also, the example server 1400 of FIGS. 14 and 15 can have reduced size as compared to known server chassis that are designed for air cooling. Some known server chassis have a length between 19-36 inches and width of approximately 19 inches. Conversely, a length of each sled 1402, 1404, 1406 of the example server 1400 can be approximately 13 inches. Also, a width each sled 1402, 1404, 1406 of the example server 1400 can be approximately 11 inches. In some examples, the respective sleds 1402, 1404, 1406 have a depth of 14″ or less, a width of 14″ or less, and a thickness dimension of 3.5″ or less. The reduced size of the sleds 1402, 1404, 1406 enables the sleds 1402, 1404, 1406 to be disposed in immersion tanks that have smaller form factors (e.g., smaller volumes). Thus, the example server 1400 can be used with immersion tanks disposed in data centers or at locations in an edge network where space for IT equipment may be limited. For instance, the smaller size of the sleds 1402, 1404, 1406 and, thus, in some instance, the tanks in which the sleds 1402, 1404, 1406 are disposed can enable two or more tanks to be stacked to conserve space in an environment.

Further, the reduced size of the sleds 1402, 1404, 1406 facilitates case of insertion and removal of the respective sleds 1402, 1404, 1406 from the tank 1500 by a user. For instance, unlike larger server chassis, the user may not have to bend over and pull the respective sleds 1402, 1404, 1406 out of the tank and over the user's head to extract the sled(s) 1402, 1404, 1406 from the tank because of the smaller size of the sleds 1402, 1404, 1406.

To dispose the respective sleds 1402, 1404, 1406 in an immersion tank, a user can for instance, couple first end(s) or wire(s) or cable(s) to component(s) on the respective sleds prior to inserting the sleds 1402, 1404, 1406 in the tank 1500. The user can dispose the sleds 1402, 1404, 1406 in the tank 1500 and couple the opposite (non-connected) ends of the wire(s) or cable(s) to corresponding component(s) on the respective sleds 1402, 1404, 1406. To remove one or more sleds from the immersion tank 1500, the user can disconnect the corresponding wires or cables from the sled 1402, 1404, 1406 that is to be removed.

FIG. 16 illustrates the example storage/memory sled 1402 of the server 1400 of FIG. 14. The storage/memory sled 1402 supports electronic components that provide memory and/or storage processes for the compute sled 1404 of FIG. 14. The example storage/memory sled 1402 of FIG. 14 includes a metal tray 1600 to support one or more bays 1602. The example sled 1402 can include additional or fewer bays 1602 than shown in FIG. 16. Each of the bays 1602 receives a storage/memory device 1604. For example, the memory devices 1604 can be slid into the respective bays 1602. Cooling fluid can flow in the immersion tank relative to the storage/memory sled 1402 as represented by the arrows 1610 of FIG. 16. In some examples, the storage/memory sled 1402 includes heat sinks to further promote cooling.

The example storage/memory devices 1604 of FIG. 16 can have an EDSFF (Enterprise and Data Center Standard Form Factor) form factor (e.g., EDSFF E.1 S form factor). The storage/memory devices 1604 can include volatile memory (e.g., DRAM), non-volatile byte addressable memory, non-volatile storage class memory, and/or non-volatile storage memory. The storage/memory devices 1604 can include, for example, CXL.mem DDR5 system memory devices, CXL DataCenter Persistent Memory Module (DCPMM) memory devices, and/or NAND memory devices for storage. In some examples, storage class memory or non-volatile storage devices can be integrated into a solid state drive (SSD) form factor.

The storage/memory devices 1604 supported by the storage/memory sled 1402 of FIG. 16 can be operatively coupled to corresponding component(s) supported by the compute sled 1404 via cable(s) (e.g., electrical, optical wires or cables, such as CXL wires or cables for memory EDSFF devices, NVMe or PCIe wires or cables for storage EDSFF devices, etc.). The storage/memory sled 1402 of FIG. 16 includes cable connector(s) 1606 to provide for communicative couplings with the compute sled 1404, the power source 1408 of FIG. 14, etc.

In some examples, the storage/memory devices 1604 are coupled to connectors disposed in an electronic circuit board, where the electronic circuit board can serve as a substrate for the storage/memory sled 1402. In such examples, wiring from within the board extends to connectors accessible via a face of the board (e.g., at the end 1414 of the sled 1402). Corresponding cables or wires can be coupled to the connectors located at the face of the board to facilitate communication with, for instance, the compute sled 1404.

FIG. 17 illustrates the example compute sled 1404 of the server 1400 of FIG. 14 to support computing components such as a central processing unit (CPU). The example compute sled 1404 of FIG. 17 includes slots 1700 to receive, for example, network interface cards for network communications and/or a DataCenter Security Control Module (DC-SCM). The example compute sled 1404 includes a CPU socket 1702. In some examples, the CPU socket 1702 includes a liquid metal socket (LMS) that forms I/O connections using a pin and a malleable well of metal for each I/O connection. As illustrated in FIG. 17, the socket 1702 is accessible via a face 1704 of the compute sled 1404 for ease of access during, for instance, maintenance. Other socket technologies such as Land Grid Array (LGA) sockets can also be used. The face 1704 of the compute sled 1404 can support other connectors 1706 such as SFF-TA-1020 high speed I/O connectors.

The example compute sled 1404 of FIG. 17 includes power connectors 1708. When the compute sled 1404 is oriented in an immersion tank as shown in FIG. 17, the power connectors 1708 are disposed at the end 1412 (e.g., a bottom end) of the compute sled 1404. Cooling fluid can flow in the immersion tank relative to the compute sled 1404 as represented by the arrows 1712 of FIG. 17.

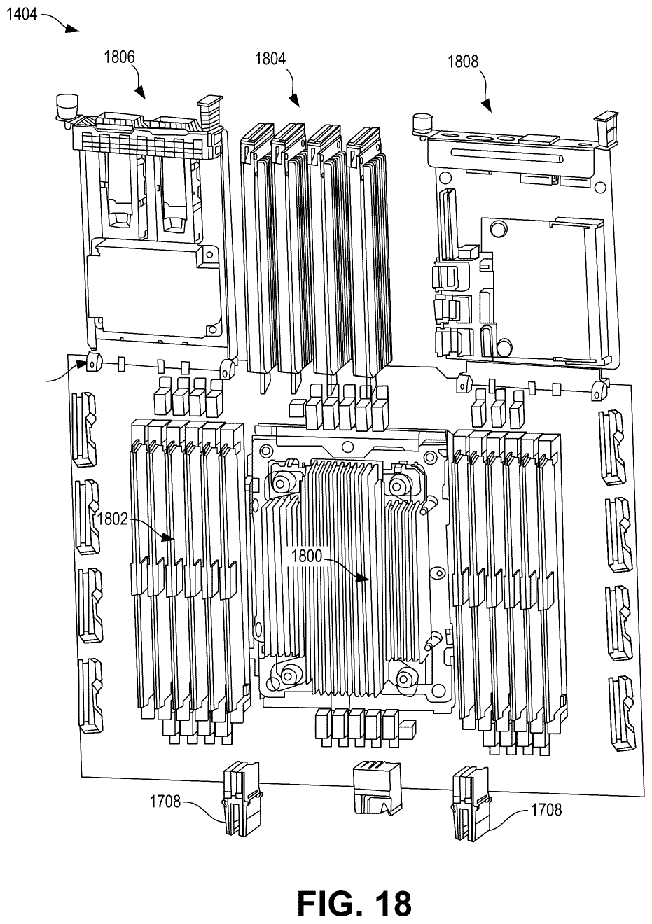

FIG. 18 illustrates another example of the compute sled 1404 of FIG. 14 including DIMM (Dual In-line Memory Module) devices. In the example of FIG. 18, the compute sled 1404 includes DRAM devices. The DRAM devices can include capacity to boot, for example, a system BIOS. In this example, a remainder of the memory devices (e.g., EDSFF E1.S devices) of the server 1400 can be supported by the storage/memory sled 1402 of FIG. 16.

The example compute sled 1404 includes a socket 1800, DIMM devices 1802 (e.g., 12 DIMM devices), memory devices 1804 (e.g., four E1.S CXL memory devices), a network interface card 1806, and a DC-SCM 1808. The example compute sled 1404 includes the power connectors 1708 (e.g., OCR-type busbar connectors) to couple to, for example, the power source 1408 of FIG. 14 that provides power to each sled 1402, 1404, 1406 of the server 1404.

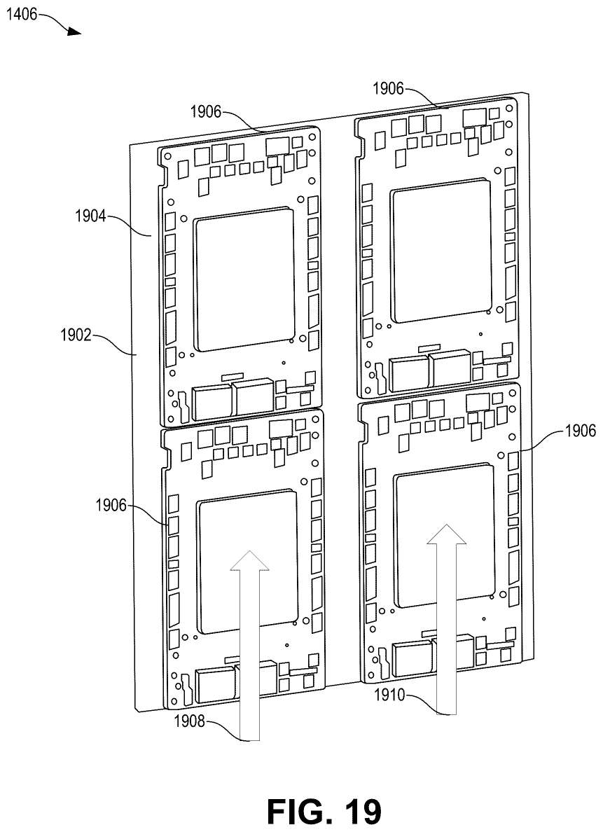

FIG. 19 illustrates the example accelerator sled 1406 of the server 1400 of FIG. 14. In some examples, the accelerator sled 1406 includes Open Compute Project Accelerator Modules (OAM). The example accelerator sled 1406 of FIG. 19 includes a carrier tray 1902. A carrier board 1904 is coupled to the carrier tray 1902. The carrier board 1904 supports accelerator devices 1906 (e.g., OCP accelerator modules). The accelerator devices 1906 can be coupled to corresponding compute devices on the compute sled 1404 of FIG. 14 (e.g., via CXL PCIe cables). Fluid flow in the immersion tank in which the example accelerator sled 1406 is disposed is represented by arrows 1908, 1910 in FIG. 19.

As explained above, a two-phase immersion cooling system involves a cooling fluid that is a dielectric (e.g., electrically insulative) and has a relatively low boiling point (e.g., less than 60° C. at atmospheric pressure) so that the fluid will vaporize and draw away heat generated by electrical system(s) (e.g., semiconductor chips) immersed therein. The gaseous vapor of the cooling fluid may be subsequently cooled to condense back into a liquid (e.g., with a heat exchanger and/or condenser) to continue being used to cool the electrical system(s). Such systems provide more efficient cooling than is possible using many other techniques (e.g., a fan heat sink), thereby enabling improved performance of the electrical system(s).

Cooling fluids that are electrically insulative and also have relatively low boiling points (e.g., FC-3284 Fluroinert™, which boils at approximately 50° C. at atmospheric pressure and FC-87 boils at approximately 30° C. at atmospheric pressure) are relatively expensive. As a result, efforts are employed to reduce any loss of such fluids over time to lower operating costs. This can be challenging in two-phase cooling systems where the fluid vaporizes because the fluid, while in a gaseous state, can escape the cooling tank, bath, or other chamber holding the fluid. Loss of the fluid vapor can be reduced by attempting to provide an airtight or hermetical sealing of the tank, but this can be expensive and difficult to accomplish inasmuch as there are likely to be various holes in the tank system to provide for electrical lines, a heat exchanger and/or condenser tubes, and/or other connectors. Furthermore, when the tank system lid needs to be opened (e.g., for intermittent system maintenance), the loss of the cooling fluid can be significant.

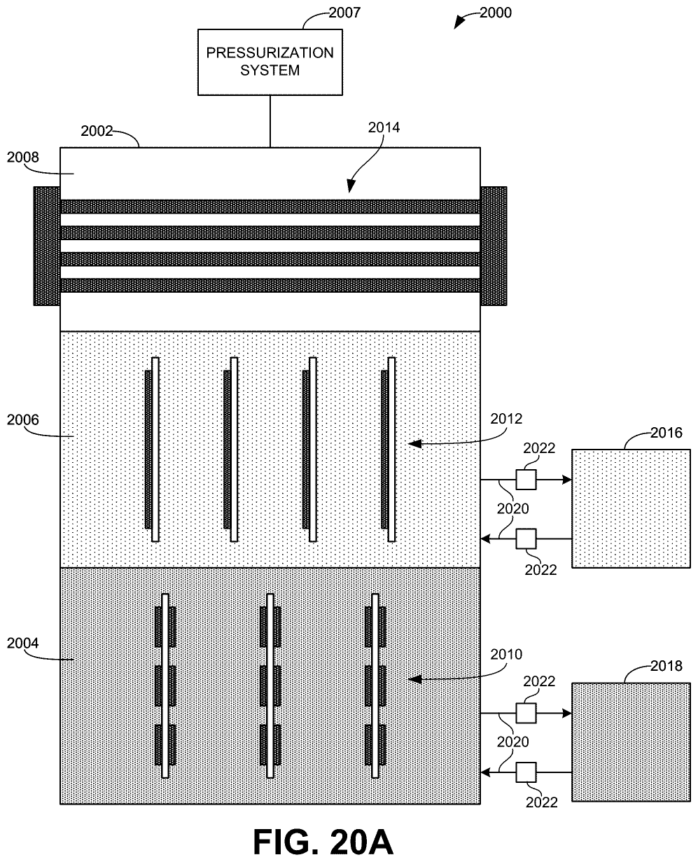

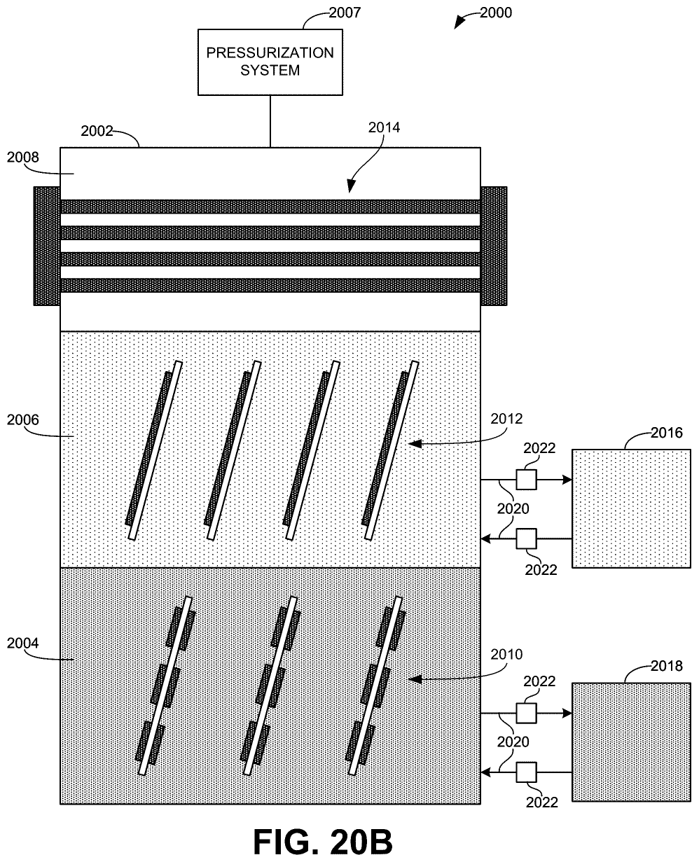

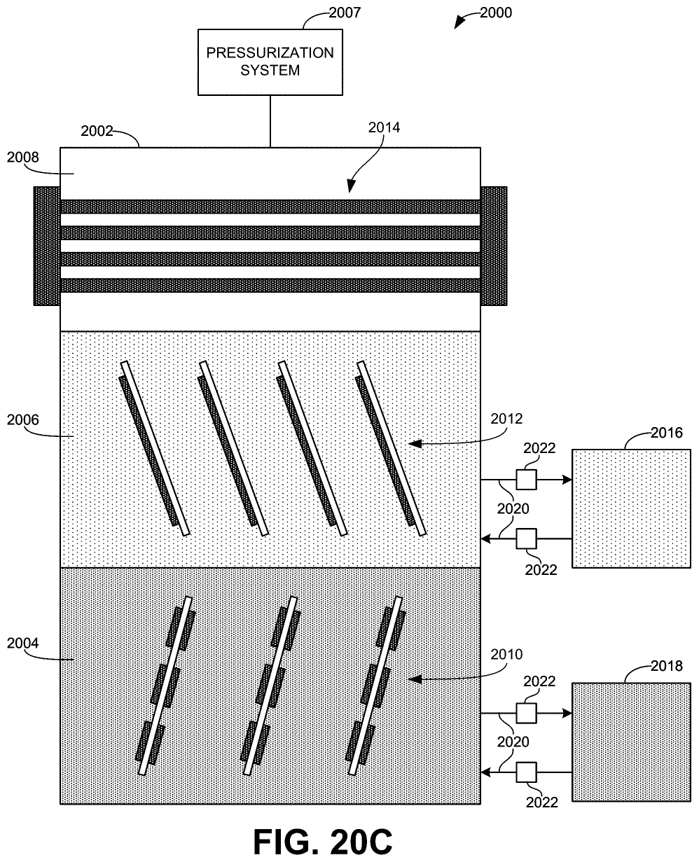

FIG. 20A illustrates an example two-phase immersion cooling system 2000 that reduces (and/or prevents) vapor of a two-phase cooling liquid from escaping the system 2000. More particularly, as shown in the illustrated example, the example system 2000 includes an immersion tank 2002 that includes multiple levels or stratifications of different cooling fluids. In some examples, the immersion tank 2002 corresponds to any one of the immersion tanks 104, 108, 201, 400, 500, 700, 900, 1102, 1500 of FIG. 1, 2, 4-11, 15. In the illustrated example, a first cooling fluid 2004 is located at the bottom of the immersion tank 2002 and has a relatively low boiling temperature (e.g., less than or equal to 60° C.) so as to operate as a two-phase cooling fluid (e.g., changes between the liquid phase and the vapor phase when in use). That is, the boiling temperature of the first cooling fluid 2004 is less than an operating temperature of electronic components immersed therein so that heat produced by such electronic components will cause the first cooling fluid 2004 to boil. Thus, the first cooling fluid 2004 is alternatively referred to herein as the two-phase cooling fluid 2004. In this example, the tank 2002 also includes a second cooling fluid 2006 layered on top of the first cooling fluid 2004 (when the two-phase cooling fluid 2004 is in the liquid phase) and has a relatively high boiling temperature (e.g., between approximately 300° C. and approximately 500° C.) to operate as a single-phase cooling fluid (e.g., remains a liquid when in use). Thus, the second cooling fluid 2006 is alternatively referred to herein as the single-phase cooling fluid 2006. The boiling temperatures for the cooling fluids 2004, 2006 provided above assume the tank is at atmospheric pressure. However, in some examples, the system 2000 includes a pressurization system 2007 to either increase or decrease the pressure within the tank 2002, which will correspondingly affect the temperatures at which the fluids 2004, 2006 boil.

In the illustrated example, the first cooling fluid 2004 has a specific gravity (e.g., density) that is greater than the specific gravity of the second cooling fluid 2006 such that the second cooling fluid 2004 floats on top of the first cooling fluid 2004 (at least when the first cooling fluid 2004 is a liquid). As a result, the second cooling fluid 2006 separates the first cooling fluid 2004 from an open space 2008 (also referred to herein as a vapor space) at a top of the tank 2002. In other words, the second cooling fluid 2006 serves as a barrier to reduce (e.g., prevent) loss of the first cooling fluid 2004. While there may be some loss of the second cooling fluid 2006 over time, this is less of a concern because the second cooling fluid 2006 may be significantly (e.g., an order of magnitude) less expensive than the first cooling fluid 2004. In some examples, the density of the first cooling fluid 2004 is greater than 1000 kg/m³ while the density of the second cooling fluid 2006 is less than 1000 kg/m³. In some examples, the specific gravity or density of the first cooling fluid is at least 20% greater than the specific gravity or density of the second cooling fluid. However, in some examples, the difference in densities can be less than or greater than this amount (e.g., 5%, 10%, 25%, 30%, etc.).

In addition to the first and second cooling fluids 2004, 2006 having properties associated with temperature and density as outlined above, the cooling fluids 2004, 2006 are immiscible with respect to one another so that the two fluids do not mix when in the liquid phase. Furthermore, inasmuch as the fluids are used in an immersion cooling system and may come in direct contact with electronic components, the cooling fluids 2004, 2006 also have electrically insulative properties (e.g., are dielectric fluids) and are compatible with the materials used in the electronic components. Any fluids having the above characteristics can be used in the example system of FIG. 20A. Specific example fluids for the first (two-phase) cooling fluid 2004 include Perfluorocarbons (PFCs), Fluoroketones (FKs), Hyrdofluoroethers (HFEs), Hydrofluorocarbons (HFCs), Hydrofluoroclefins (HFOs), etc. Specific example fluids for the second (single-phase) cooling fluid 2006 include Polyalphaolefin (PAO), Paraffinic, Alkenes, Ketones, Aromatics, Polyesters, Silicone, etc. As noted above, candidate fluids for the single-phase cooling fluid 2006 are typically significantly less expensive than the two-phase cooling fluid 2004.

In the illustrated example of FIG. 20A, first electronic components 2010 are disposed within the two-phase cooling fluid 2004 and second electronic components 2012 are disposed within the single-phase cooling fluid 2006. In this example, the first electronic components 2010 have a higher thermal design power (TDP) than the second electronic components 2012. That is, the first electronic components 2010 are higher performance components that produce more heat than the second electronic components 2012. As a specific example, the first electronic components 2010 include high performance processor and/or memory chips, whereas the second electronic components 2010 lower thermal output components (e.g., Peripheral Component Interconnect Express (PCIe) adapter cards, solid state drives (SSDs), etc.). While the first and second electronic components 2010, 2012 are represented in FIG. 20A as being separated and distinct from one another (e.g., associated with separate circuit boards), in some examples, a single circuit board may extend across the interface of the two layers of liquid with some components on the board in the two-phase cooling fluid 2004 and other components on the board in the single-phase cooling fluid 2006. Further, in some examples, all electronic components may be disposed in the two-phase cooling fluid 2004 to take advantage of the more efficient two-phase cooling provided by the two-phase cooling fluid 2004. That is, in some examples, the second electronic components 2012 are disposed in the two-phase cooling fluid 2004 along with the first electronic components 2010. In some examples, this is achieved by positioning the second electronic components 2012 alongside the first electronic components 2010. In other examples, this is achieved by increasing the depth of the two-phase cooling fluid 2004 within the tank 2002.

As the electronic components 2010 in the first cooling fluid 2004 heat up during operation, heat is transferred to the first cooling fluid 2004. When the operation of electronic components 2010 reaches a critical threshold, the heat produced by the components will cause the first cooling fluid 2004 to boil and produce vapor bubbles in the fluid. In some examples, the surfaces of individual heat sources on the electronic components 2001 (e.g., individual IC chips and/or boiler plates mounted to IC chips) are structured to promote nucleate boiling because nucleate boiling provides more efficient heat transfer than film boiling. However, in some examples, film boiling may also occur. The vapor bubbles formed by the boiling of the first cooling fluid 2004 will sweep away from the first electronic components 2010 and rise in the tank 2002 up through the liquid portion of the first fluid and into the second cooling fluid 2006 (which remains in the liquid state as a single-phase cooling fluid). In some examples, the vapor of the first cooling fluid 2004 rises all the way through second cooling fluid 2006 and into the open space 2008 of the tank 2002. In some examples, the sweep of the vapor bubbles through the liquids can facilitate circulation throughout the fluids and also draw in cooler coolant as the bubbles move away from the first electronic components 2010. In some examples, natural convection or natural circulation and the sweep of the bubbles are the motive forces relied on to facilitate circulation of the cooling fluids 2004, 2006 within the tank 2002. In other examples, a pump, agitator, and/or other mechanical device is used to facilitate forced circulation of the fluids 2004, 2006 (which may also reduce film boiling events). In some examples, such forced circulation may be implemented in combination with the external reservoirs 2016, 2018 and the associated flow control elements 2022. In other examples, forced circulation is implemented independent of and/or without the external reservoirs 2016, 2018 and the associated flow control elements 2022.

As shown in the illustrated example of FIG. 20A, the open space 2008 of the tank includes a cooling element 2014. In this example, the cooling element 2014 corresponds to an array of condenser tubes but any other type of cooling element (e.g., heat exchanger, cooling coil, etc.) may alternatively be implemented. Further, in some examples, more than one cooling element 2014 (of the same or different type) may be positioned within the open space 2008 above the second cooling fluid 2006. In this example, the cooling element 2014 is maintained at a relatively low temperature to draw heat away from the vapor of the first cooling fluid 2004, thereby causing the vapor to condense back into the liquid phase. The first cooling fluid 2004 that condenses back into a liquid on the cooling element 2014 will then fall (e.g., as condensate droplets) back into the second cooling fluid 2006 and continue to sink (due it its higher density) down to the bulk of the first cooling fluid 2004 at the bottom of the tank 2002.

In some examples, one or both of the cooling fluids 2004, 2006 are in fluid communication with corresponding external reservoirs 2016, 2018. In some examples, the reservoirs 2016, 2018 are coupled to the tank 2002 via tubing 2020. In some examples, the flow of fluid is controlled through the tubing 2020 using flow control elements 2022 (e.g., pumps, valves, etc.) to facilitate the removal and/or addition (refilling or replenishment) of the cooling fluids 2004, 2006 within the tank 2002. In some examples, the flow control elements include and/or are associated with electromechanical actuators that are controlled by a controller such as the control system circuitry of FIG. 2C. In some examples, the fluid within the reservoirs is cooled (e.g., with a heat exchanger) to facilitate the cooling of the fluids 2004, 2006 within the tank 2002. In some examples, condensate of the two-phase cooling fluid 2004 that condenses on the cooling element 2014 is directed towards the corresponding external reservoir 2018 to be reintroduces into the liquid phase portion of the fluid 2004 without sinking through the single-phase cooling fluid 2006. In some examples, the condensate bypasses the single-phase cooling fluid 2006 in this manner through tubing without the use of an external reservoir. While an example external reservoir and associated tubing and flow control elements are shown and described with respect to FIG. 20A, the same or similar reservoir(s) and associated components may be implemented in connection with any of the cooling systems shown and described in connection with FIGS. 1-19. In other examples, the reservoirs and associated components in FIG. 20A can be omitted.

In some examples, the heat transfer dynamics within the tank 2002 can be altered (e.g., improved) by modifying the position and/or orientation of the electronic components 2010, 2012 within the cooling fluids 2004, 2006. For instance, in the illustrated example of FIG. 20A, the electronic components are oriented substantially vertically. That is, the circuit boards (e.g., sleds) carrying particular heat sources (e.g., semiconductor chips) extend vertically. As used herein, substantially vertical means exactly vertical or within 5 degrees of exactly vertical. Other orientations for the electronic components 2010, 2012 are possible. For instance, as shown in the illustrated example of FIG. 20B, the electronic components 2010, 2012 are angled relative to the vertical (e.g., at oriented at a non-vertical angle). The electronic components 2010, 2012 can be angled at any angle relative to the vertical from 0 degrees (vertical) to 90 degrees (horizontal). In some examples, different ones of the electronic components 2010, 2012 are at different angles relative to one another. In some examples, the angle depends upon the placement (e.g., whether on one side or both sides), type (e.g., thermal design power), and/or size of the heat sources on the circuit boards of the electronic components 2010, 2012. In some examples, only the electronic components 2010 in the two-phase cooling fluid 2004 are angled relative to the vertical while the electronic components 2012 in the single-phase cooling fluid 2006 are substantially vertically. Conversely, in some examples, only the electronic components 2012 in the single-phase cooling fluid 2006 are angled relative to the vertical while the electronic components 2010 in the two-phase cooling fluid 2004 are substantially vertically.

As shown in FIG. 20B, the electronic components 2012 in the single-phase fluid 2006 are angled so that the heat sources face upwards and away from the electronic components 2010 in the two-phase fluid 2004. As a result, as the heat sources on the electronic components 2010 heat the surrounding cooling fluid 2006, rising convection flow will move away from the heat sources rather than across their surface. Further, the orientation of the lower TDP components 2012 (with the heat sources facing upwards) result in heat rising from the higher TDP components 2010 (due to natural convection and/or the sweep of the vapor bubbles rising through the fluids 2004, 2006) being in less direct contact with the upward facing heat sources. Instead, the heat rising from below is more likely to come into contact with the backside of the circuit boards carrying the heat sources of the lower TDP components 2010. This arrangement may help facilitate the ability of the single-phase cooling fluid 2006 to cool the lower TDP electronic components 2010. In other examples, as shown in the illustrated example of FIG. 20C, the electronic components 2012 in the single-phase fluid 2006 are angled so that the heat sources face downwards and towards the electronic components 2010 in the two-phase fluid 2004. As a result, heat rising from the higher TDP components 2010 (due to natural convection and/or the sweep of the vapor bubbles rising through the fluids 2004, 2006) will more likely be in direct contact with the downward facing heat sources. This arrangement may help facilitate the rising vapor bubbles of the two-phase cooling fluid 2004 to draw heat away from the heat sources on the lower TDP electronic components 2010.

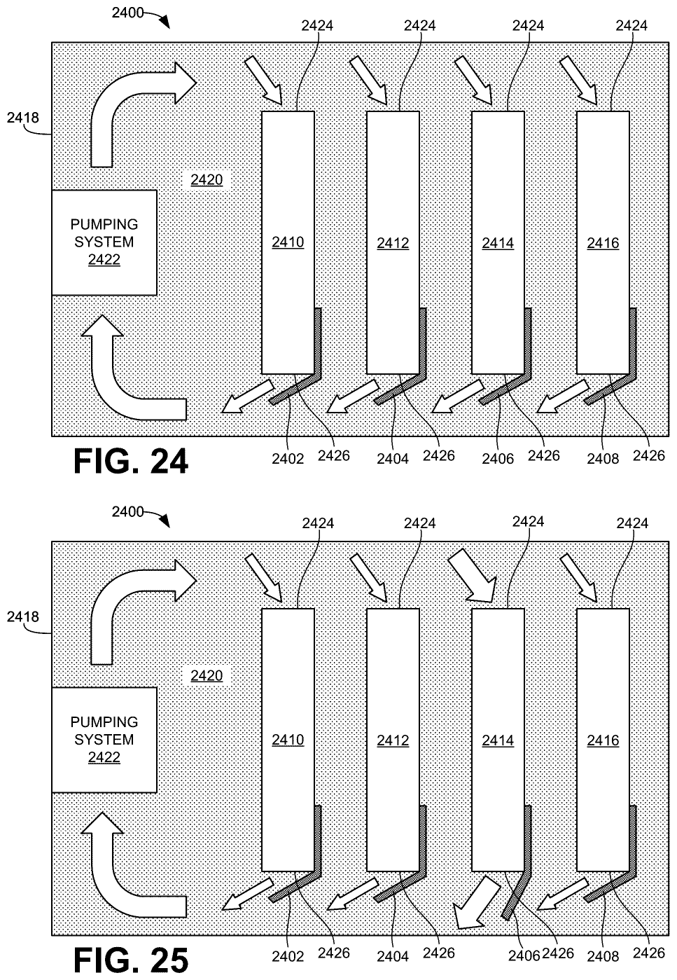

Although particular arrangements and/or orientations of the electronic components 2010, 2012 have been shown and described with reference to FIGS. 20A-C, other arrangements are possible. Furthermore, different orientations for electronic components are not limited to examples in which there are different electronic components in different levels of different cooling fluids. Rather, electronic components cooled in a single cooling fluid (whether a single-phase cooling fluid or a two-phase cooling fluid) may be suitable angled to achieve any particular heat transfer dynamics. Further, in some examples, the angle of electronic components may depend on whether the cooling fluid is circulated based solely on natural convection resulting from heat produced by the components being cooled or if the fluid is forced to flow across the components using one or more pumps and/or other fluid circulation mechanism. Further, in some examples, the orientation of electronic components can depend on the presence and/or orientation of other structures (e.g., baffles, including the baffles discussed below in connection with FIGS. 24-32) positioned to direct the flow of the cooling fluid (either based on convection currents or mechanically forced flow).

Different heat transfer dynamics between the two fluids 2004, 2006 can occur as the two-phase fluid 2004 vaporizes and rises through the single-phase fluid 2006 and then subsequently condenses and sinks back down based on the operating dynamics in the system. Specifically, in some examples, the operating or bulk temperature of the single-phase fluid 2006 is above the saturation or condensing temperature of the two-phase cooling fluid 2004. In some such examples, the bulk temperature of the single-phase fluid 2006 is above the condensing temperature of the two-phase cooling fluid 2004 because the single-phase fluid 2006 receives heat produced by the second electronic components 2012 within the single-phase fluid 2006, thereby enabling the cooling of the second electronic components 2012. In some examples, the bulk temperature of the single-phase fluid 2006 is at least 5° C. above the condensing temperature of the first cooling fluid 2004. In other examples, the temperature difference between the bulk temperature of the single-phase fluid 2006 and the condensing temperature of the first cooling fluid 2004 is less than 5° C. In some examples, the bulk temperature of the single-phase fluid 2006 is significantly higher than the condensing temperature of the first cooling fluid 2004 (e.g., by at least 15° C., 20° C., 25° C., 35° C. etc.).

In examples where the bulk temperature of the single-phase fluid 2006 is elevated above the two-phase cooling fluid condensing temperature, heat from the higher temperature single-phase fluid 2006 will transfer to or be absorbed by the vapor of the first fluid 2004 rising through the second fluid 2006. That is, the vapor (of the two-phase fluid 2004) will increase in temperature while drawing heat from the single-phase fluid 2006. In this manner, the bubbles of vapor rising through the single-phase fluid 2006 can help to cool the single-phase fluid 2006 (and the associated second electronic components 2012 contained therein) without the need for a separate cooling system in the single-phase fluid 2006. The heat contained in the vapor of the first cooling fluid 2004 (generated from first electronic components 2010 and drawn from the second cooling fluid 2006) is transferred to the cooling element 2014 as the vapor condenses on the tubes after reaching the open space 2008 above the second fluid 2006. In some examples, the additional heat added to the vapor as it passes through the second cooling fluid 2006 can improve the condensation of the vapor once it reaches the open space 2008. Once condensed back into the liquid phase, the first cooling fluid 2004 will return to the bottom of the tank 2002 due to its density being greater than that of the second cooling fluid 2006. As the condensed droplets (e.g., condensate) of the first cooling fluid 2004 sink through the second cooling fluid 2006, the droplets may heat up due to the higher temperature of the second cooling fluid 2006. Thus, as with the vapor bubbles rising through the second cooling fluid 2006, the sinking droplets can also assist in cooling the second cooling fluid 2006. In addition to the rising vapor bubbles and sinking droplets of the two-phase cooling fluid 2004 cooling the single-phase fluid 2006 due to heat transfer therebetween, the motion of the vapor bubbles and/or droplets passing through the single-phase fluid 2006 can induce mixing and/or convection flow throughout the single-phase fluid 2006, thereby further improving the cooling capability of the single-phase fluid 2006.

In some examples, the operating or bulk temperature of the single-phase fluid 2006 is less than the saturation or condensing temperature of the first cooling fluid 2004. In such examples, heat from the vapor rising through the single-phase fluid 2006 will transfer to the single-phase cooling fluid 2006 because of the cooler temperature of the single-phase fluid. As a result of this heat transfer, sufficient heat may be withdrawn from the vapor as it rises through the single-phase fluid 2006 such that the vapor condenses back into the liquid phase before reaching the upper surface of the single-phase fluid 2006 and the open space 2008. More particularly, in some examples, the depth of the single-phase fluid 2006 and/or its bulk operating temperature are designed so that all or substantially all (e.g., 90%, 95%, 98%, 99%, etc.) or at least a substantial majority of vapor from the boiling of the two-phase cooling fluid 2004 condenses within the single-phase fluid 2006 before reaching the open space 2008. Once the vapor condenses, it will sink back down to the bottom of the tank 2002 because of the greater density of the first cooling fluid 2004 when in liquid form. Inasmuch as the first cooling fluid 2004 is prevented from reaching the open space 2008 of the tank 2002, in this example, the amount of the first cooling fluid 2004 that is able to escape the tank 2002 (whether through small holes in the tank 2002 or when a lid of the tank 2002 is opened) is significantly reduced if not entirely prevented.

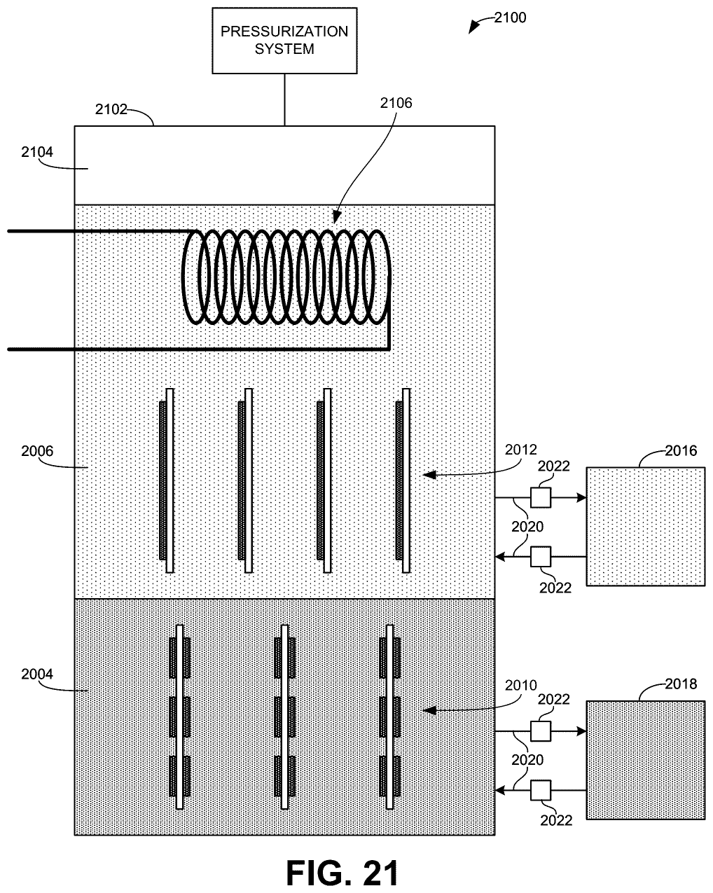

In some examples, to facilitate the cooling of the single-phase cooling fluid 2006 (to cool the second electronic components 2012 and/or to promote heat transfer from the vapor bubbles of the first cooling fluid 2004 within the single-phase cooling fluid 2006) a cooling element is included within the single-phase cooling fluid 2006 as shown in FIG. 21. In particular, FIG. 21 illustrates another example two-phase immersion cooling system 2100 that includes an immersion tank 2102 containing the first cooling fluid 2004 at the bottom and the second cooling fluid 2006 floating on the first cooling fluid 2004 as described above in connection with FIG. 20A. Further, in this example, the first and second electronic components 2010, 2012 are positioned within the two layers or levels of fluid 2004, 2006 as described above. As with the example system 2000 of FIG. 20A, the electronic components 2010, 2012 shown in FIG. 21 can be arranged in any other suitable matter than that which is shown in the illustrated example.

Unlike the example system 2000 of FIG. 20A, the example system 2100 of FIG. 21 does not include a cooling element within an open space 2104 of the tank 2102 above the second cooling fluid 2006. Instead, in the illustrated example of FIG. 21, a cooling element 2106 is positioned within the second cooling fluid 2006. In this example, the cooling element 2106 corresponds to a cooling coil but any other type of cooling element (e.g., heat exchanger, condenser tubes, etc.) may alternatively be implemented. Further, although the cooling element 2106 is shown in FIG. 21 as being above the second electronic components 20126, the cooling element 2106 can be in any suitable position relative to the second electronic components 2012 (e.g., above, below, to the side, between, etc.). Further, in some examples, more than one cooling element 2106 may be positioned within the second cooling fluid 2006.

Positioning the cooling element 2106 within the single-phase cooling fluid 2006 helps to cool the single-phase cooling fluid 2006, which in turn helps draw out heat from the vapor bubbles of the two-phase cooling fluid 2004 rising through the single-phase cooling fluid 2006. As a result, the cooler single-phase cooling fluid 2006 helps to cause the vapor bubbles to collapse and/or condense back into liquid before reaching the open space 2104. For this reason, in some examples, there is no need for a cooling element in the open space 2104 to cause the vapor of the first cooling fluid to condense. However, in some examples, the cooling element 2106 in FIG. 21 is used in combination with a separate cooling element (such as the cooling element 2014 shown in FIGS. 20A-C) within the open space 2104 of the tank 2102.

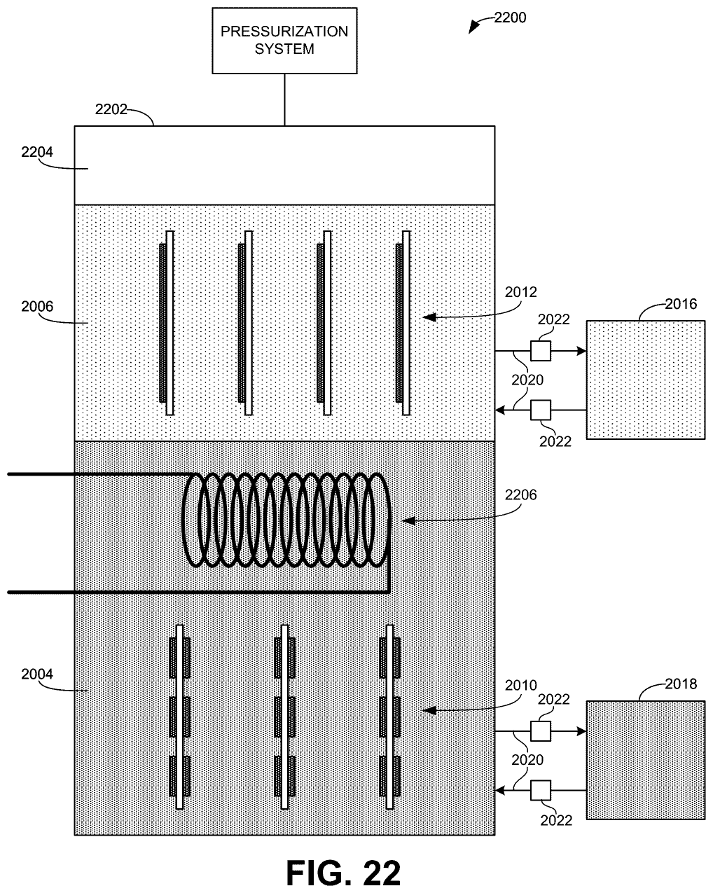

FIG. 22 illustrates another example two-phase immersion cooling system 2200 that includes an immersion tank 2202 containing the first cooling fluid 2004 at the bottom and the second cooling fluid 2006 floating on the first cooling fluid 2004 as described above in connection with FIG. 20A. Further, in this example, the first and second electronic components 2010, 2012 are positioned within the two layers of fluid 2004, 2006 as described above. As with the example system 2000 of FIGS. 20A-C, the electronic components 2010, 2012 shown in FIG. 22 can be arranged in any other suitable matter than that which is shown in the illustrated example.

Unlike the example system 2000, 2100 of FIGS. 20A-C and 21, the example system 2200 of FIG. 22 includes a cooling element 2206 positioned within the first cooling fluid 2004. In this example, the cooling element 2206 corresponds to a cooling coil but any other type of cooling element (e.g., heat exchanger, condenser tubes, etc.) may alternatively be implemented. In some examples, more than one cooling element 2206 may be positioned within the second cooling fluid 2006. Further, although the cooling element 2206 is shown in FIG. 22 as being above the second electronic components 2012, the cooling element 2206 can be in any suitable position relative to the second electronic components 2012 (e.g., above, below, to the side, between, etc.). In some examples, the cooling element 2206 is positioned to be above the first electronic components 2010 so as to be in the path of vapor bubbles rising from the first electronic components 2010. In this manner, the cooling element 2206 is able to draw heat from the vapor bubbles to cause the vapor to condense back to liquid before reaching the second cooling fluid 2006 and/or lower the temperature of the vapor so that the second cooling fluid 2006 needs to draw out less heat from the vapor before it condenses. In some examples, the cooling element 2206 in the first cooling fluid 2004 (as shown in FIG. 22) is used in combination with a cooling element in the second cooling fluid 2006 (e.g., as shown in FIG. 21) and/or in combination with a cooling element in the open space 2204 above the second cooling fluid 2006 (e.g., as shown in FIG. 20A)

The example two-phase immersion cooling systems 2000, 2100, 2200 of FIGS. 20A-22 take advantage of the enhanced cooling capabilities of two-phase cooling systems while defraying the costs of such systems by reducing (e.g., minimizing) the loss of the expensive two-phase cooling fluid used in such systems. The more efficient cooling systems 2000, 2100, 2200 of FIGS. 20A-22 enable more dense server system designs than is otherwise possible using other known approaches. Furthermore, the single-phase cooling fluid 2006 can also be employed as part of a single phase cooling system for lower heat dissipating heat sources disposed therein in an efficient manner (e.g., without the need for the complexity and/or cost of components to remove heat from the single phase fluid) because such cooling of the single phase fluid can be achieved by the thermal and fluid dynamics involved with vapor bubbles and droplets of the two-phase cooling fluid passing therethrough. Furthermore, having two separate fluids in two separate layers within a cooling chamber enables the operating temperatures of different fluid zones within the chamber to be distinguished, monitored, and/or designed with greater control than is possible in traditional cooling systems that employ a single cooling fluid.

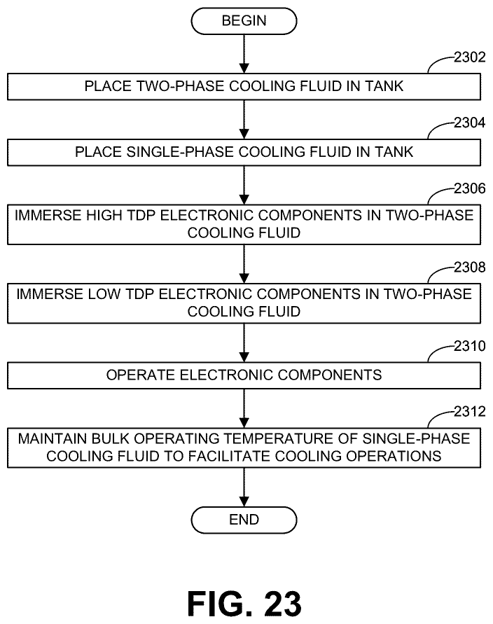

FIG. 23 is a flowchart illustrating an example method of implementing the example immersion cooling systems 2000, 2100, 2200 of FIGS. 20A-22. For purposes of explanation, the flowchart of FIG. 23 will be described with reference to the immersion cooling system 2000 of FIG. 20A with the understanding that the method of FIG. 23 could additionally or alternatively be used in connection with the example immersion cooling systems 2100, 2200. Although the example method is described with reference to the flowchart illustrated in FIG. 23, many other methods may alternatively be used. For example, the order of execution of the blocks may be changed, and/or some of the blocks described may be combined, divided, re-arranged, omitted, eliminated, and/or implemented in any other way.

The example process begins at block 2302 by placing the two-phase cooling fluid 2004 in the tank 2002. In some examples, the amount of the two-phase cooling fluid 2004 added to the tank 2002 is determined so as to provide a depth sufficient to completely immerse the first electronic components 2010. In some examples, the depth of the cooling fluid 2004 is limited to the amount needed to completely immerse the first electronic components 2010 so as to reduce the amount of the two-phase fluid 2004 used (which is typically much more expensive than the single-phase fluid 2006). In some examples, an additional amount of the two-phase fluid 2004 is included to enable a cooling element (such as the cooling element 2206 of FIG. 22) to be included in the fluid.

At block 2304, the process involves placing a single-phase cooling fluid 2006 in the tank 2002. In this example, the single-phase cooling fluid 2006 is less dense (e.g., has a lower density) than and immiscible with the two-phase cooling fluid 2004 such that the single-phase fluid 2006 will float on top of the two-phase cooling fluid 2004 without mixing therewith. In some examples, the amount of the single-phase cooling fluid 2006 added to the tank 2002 depends on the nature in which the single-phase cooling fluid 2006 is to interact with vapor from the boiling two-phase cooling fluid 2004. For instance, if the single-phase cooling fluid 2006 is to have a bulk operating temperature that is lower than the condensing temperature of the two-phase cooling fluid 2004 so as to cool down and cause the two-phase fluid 2004 to condense before reaching the top of the single-phase fluid 2006, then a relatively large amount (large depth) of the single-phase cooling fluid 2006 may be employed to allow adequate time for the vapor bubbles to collapse and condense. However, if it is expected that vapor from the two-phase fluid 2004 will pass all the way through the single-phase fluid 2006, then the amount (or depth) may be less. In some such examples, the depth of the single-phase cooling fluid 2006 is at least sufficient to enable the complete submersion of the second electronic components 2012 and/or to enable a cooling element (such as the cooling element 2106 of FIG. 21) to be included in the fluid.

At block 2306, the example process involves immersing high thermal design power (TDP) electronic components (e.g., the first electronic components 2010) in the two-phase cooling fluid 2004. At block 2308, the example process involves immersing low thermal design power (TDP) electronic components (e.g., the second electronic components 2012) in the single-phase cooling fluid 2006. At block 2310, the process involves operating the electronic components 2010, 2012. This will cause two-phase cooling in the two-phase cooling fluid 2004 and single-phase cooling in the single-phase cooling fluid 2006. At block 2312, the process involves maintaining the bulk operating temperature of the single-phase cooling fluid 2006 to facilitate cooling operations. As described above, in some examples, the bulk operating temperature of the single-phase cooling fluid 2006 is maintained above the condensing temperature of the two-phase cooling fluid 2004. In other examples, the bulk operating temperature of the single-phase cooling fluid 2006 is maintained below the condensing temperature of the two-phase cooling fluid 2004. Depending on the particular operation mode, different cooling elements (e.g., one or more of the cooling elements 2014, 2106, 2206) may be included in the tank to facilitate the cooling process. Thereafter, the example process of FIG. 23 ends.

Convection cooling is the cooling of an electronic component or device through natural circulation or recirculation movement of a fluid over and/or through the device. In single-phase immersion cooling systems particularly (but also in a two-phase immersion cooling systems), convection cooling within the immersion tank can be enhanced by directing fluid flows over/through the immersed electronics within the tank. In many existing cooling systems, it is not possible to dynamically adjust the flow rate and/or flow direction of a cooling fluid in response to ongoing changes in power dissipation and temperature of the components to be cooled. As such, overcooling can result for low thermal output devices while insufficient cooling can result for high thermal output components. Examples disclosed herein enable the automatic adjustment of the flow of a cooling fluid with respect to individual components at the board level within an immersed electronic system (e.g., a particular IC chip within a server chassis) as well at the server level with respect to different server chassis immersed in the same cooling tank. Enabling the automatic adjustment of flow of cooling fluid across different electronic components responsive to changes in the amount of heat dissipated by such components provides for more efficient cooling and also reduces (e.g., eliminates) the need to over design pumps and/or associated flow supply systems.

In some disclosed examples, the automatic adjustment of the flow of a cooling fluid is made by baffles constructed with memory metals (also referred to as shape memory alloys (SMAs) that respond directly to the temperature of the fluid by changing shape without the need for any external and/or active actuator (e.g., a motor, electrical circuit, moving mechanical parts, etc.). Memory metals are made of alloys of two or more metals that can have multiple different crystal structures associated with different shapes. In some instances, the different crystal structures (and the associated shape) of a memory metal are dominant at different temperatures. That is, a memory metal will assume a first shape at a first temperature and transition to a second shape at a second higher temperature in response to a change in temperature. Memory metals can be constructed to revert to the first shape when the metal is cooled back down to the first temperature. In some instances, the transition can happen relatively quickly (e.g., the metal can snap from the first shape to the second shape) when a critical threshold temperature is reached.

Additionally or alternatively, the automatic adjustment of the flow of cooling fluid in disclosed examples is made by baffles constructed with multiple strips of different metals having different coefficients of thermal expansion (CTEs) that are bonded together. Often two strips of metal are employed (commonly known as a bimetallic strip). However, in other examples, more than two strips and/or more that two types of metal are employed. For purposes of explanation, any number of at least two different metals bonded together into a strip is referred to herein as a multi-metallic strip. As the temperature of a multi-metallic strip changes, the different metals in the strip will expand or contract at different rates, thereby causing the shape of the strip to change. In this manner, it is possible to fabricate baffles that automatically change in response to a change in temperature without the need for any external actuator.

FIG. 24 illustrates an example cooling system 2400 that includes a series of baffles 2402, 2404, 2406, 2408 to adjust fluid flows relative to a series of server chassis 2410, 2412, 2414, 2416 within an immersion tank 2418. In this examples, the server chassis 2410, 2412, 2414, 2416 include servers that are to be cooled by a cooling fluid 2420 within the tank 2418. While four server chassis 2410, 2412, 2414, 2416 are shown in FIG. 24, any suitable number of chassis may be included. Furthermore, any other type of electronic equipment to be immersion cooled (e.g., servers without associated chassis, server blades, sleds, electronic circuit boards, etc.) can be included in the tank 2418 in addition to or instead of the server chassis 2410, 2412, 2414, 2416.

As shown in the illustrated example, the cooling fluid 2420 is circulated within the tank 2418 by a pumping system 2422 including any suitable equipment (e.g., one or more pumps, jets, props, etc.). In this examples, the pumping system 2422 is shown as being inside the tank 2418. However, in other examples, some or all of the pumping system 2422 is external to the tank 2418. As represented by the arrows in the illustrated example, the pumping system 2422 causes the cooling fluid 2420 to enter inlet ends 2424 of the server chassis 2410, 2412, 2414, 2416 to pass through the server chassis to cool heat producing electronic components contained therein before exiting at outlet ends 2426 of the chassis. In some examples, the server chassis 2410, 2412, 2414, 2416, the tank 2418, and pumping system 2422 are arranged to provide a balanced flow (e.g., approximately the same amount of flow) of the cooling fluid 290 to each of the chassis 2410, 2412, 2414, 2416 (as represented by the arrows having the same size at the inlet and outlet ends 2424, 2426 of each chassis). Thus, in some examples, the server chassis 2410, 2412, 2414, 2416 are arranged differently than shown in the illustrated example and/or the cooling system 2400 includes additional tubing, channels, and/or or other structures to facilitate the flow of the cooling fluid between the pumping system 2422 and the chassis 2410, 2412, 2414, 2416.

During operation, the electronic components within one or more of the chassis 2410, 2412, 2414, 2416 may produce more heat than the electronic components in other ones of the chassis 2410, 2412, 2414, 2416. In such situations, an even or balanced flow can be problematic because the flow across the higher thermal output electronic components may be insufficient to adequately cool such components. Additionally or alternatively, the flow across the lower thermal output electronic components may be overcooled. Accordingly, as disclosed herein, the baffles 2402, 2404, 2406, 2408 are provided to automatically adjust the fluid flow in response to differences in temperatures between electronic components associated with different ones of the server chassis 2410, 2412, 2414, 2416.

The operation of the baffles 2402, 2404, 2406, 2408 is demonstrated with reference to FIG. 25 in comparison with FIG. 24. In particular, FIG. 25 is identical to FIG. 24 except that the third baffle 2406 has changed shape to be more open at the outlet end 2426 of the third server chassis 2414 in response to an increase in the thermal output of electronic components in the third server chassis 2414. As a result of the changed shape of the third baffle 2406, the flow of the cooling fluid 2420 through the third server chassis 2414 is increased (as represented by the larger arrows relative to the corresponding arrows shown in FIG. 24) to facilitate cooling of the higher temperature electronic components. In this example, the change in shape of the third baffle 2406 is the direct and automatic result of an increase in the temperature of the cooling fluid exiting the outlet end 2426 of the third server chassis 2414. That is, as the temperature of the cooling fluid 2420 increases, as it draws heat away from the electronic components, some of this additional heat will transfer to the baffle 2406 when the fluid 2420 comes into contact with the baffle, thereby causing the baffle 2406 to increase in temperature. Due to the material properties of the baffle 2406 being made from one or more memory metals and/or one or more multi-metallic strips, the change in temperature of the baffle 2406 will result in a change in shape to the baffle 2406. Similarly, once the electronic components in the third server chassis cool down (e.g., no longer produce high amounts of heat), the cooling fluid 2420 will also cool down. This reduction in the temperature of the cooling fluid 2420 will, in turn, cause the baffle 2406 to cool down. As a result, in some examples, the baffle 2406 will again change shape by returning to the shape or position represented in FIG. 24.

As noted above, in some examples, such as when the baffle 2406 is fabricated from a memory metal, the change in shape occurs relatively suddenly once a critical threshold temperature is reached. In such examples, the baffle 2406 changes from a first shape (represented in FIG. 24) associated with a first crystal structure of the metal alloy of the baffle to a second shape (represented in FIG. 25) associated with a second crystal structure of the metal allow. Having two discrete shapes in this manner enables the baffle 2406 to be switched between two modes such as “open” and “close” or “standard flow” and “high temperature flow.” In other examples, such as when the baffle 2406 is fabricated from a multi-metallic strip, the change in shape occurs gradually and commensurate with changes in the temperature of the fluid 2420.

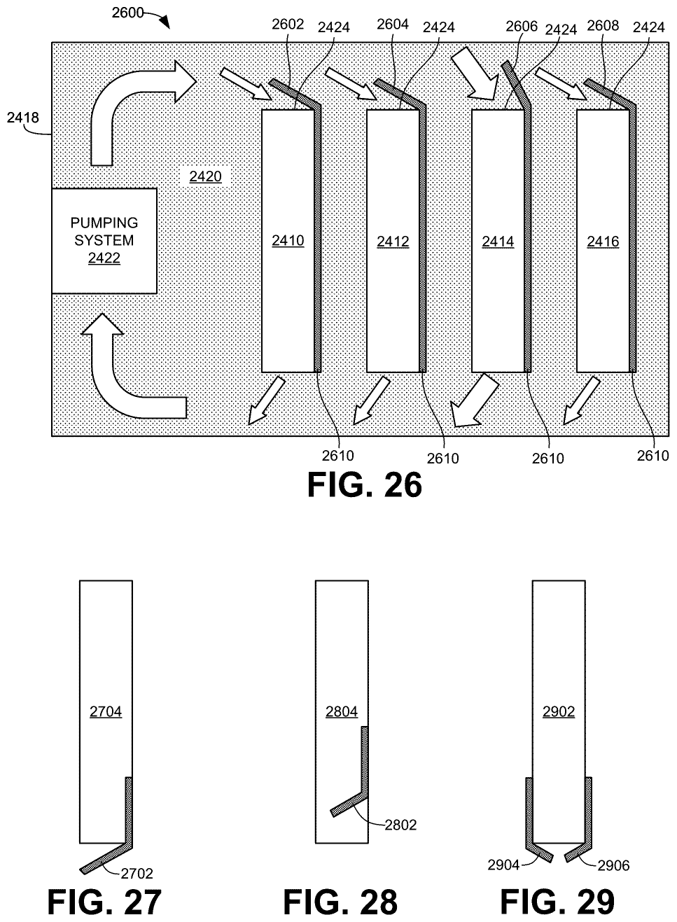

In order for the baffles 2402, 2404, 2406, 2408 to directly respond to changes in temperature in the cooling fluid 2420 caused by changes in thermal outputs of electronic components, the baffles 2402, 2404, 2406, 2408 must necessarily be positioned downstream from the electronic components so that the cooling fluid 2420 passes over the electronic components before reaching the baffles. However, FIG. 26 illustrates another example cooling system 2600 in which metal baffles 2602, 2604, 2606, 2608 are positioned at the upstream side of the electronic components. More particularly, the example cooling system 2600 of FIG. 26 includes similar components identified with similar reference numbers as the cooling system 2400 of FIGS. 24 and 25 except that the baffles 2602, 2604, 2606, 2608 in FIG. 26 are located adjacent the inlet ends 2424 of the server chassis 2410, 2412, 2414, 2416. Further, in this example, the metal baffles 2602, 2604, 2606, 2608 are thermally coupled to the electronic components within the chassis 2410, 2412, 2414, 2416 and/or thermally coupled to the cooling fluid 2420 flowing through the chassis 2410, 2412, 2414, 2416 by a conductive arm 2610 that extends along the length of the chassis 2410, 2412, 2414, 2416. In this example, although the metal baffles 2602, 2604, 2606, 2608 are upstream from the electronic components in the server chassis 2410, 2412, 2414, 2416, the baffles 2602, 2604, 2606, 2608 can still respond to temperatures changes in the electronic components and/or the cooling fluid 2420 drawing heat from the same due to thermal conduction through the associated arm 2610. In particular, as the electronic components increase in thermal output, some of the additional heat will transfer to the arm 2610 (either via direct conduction from the electronic components to the arm 2610 (e.g., through thermally conductive material, a heat pipe, etc.) and/or or through the cooling fluid 2420). As the arm 2610 increases in temperature, the heat is conducted along the arm 2610 in the upstream direction towards the associated baffle 2602, 2604, 2606, 2608, thereby causing the baffle to increase in temperature. As described above, due to the material properties of the baffles, the change in temperature results in a change in shape to the baffles to affect the flow impedance of the cooling fluid 2420 into the server chassis 2410, 2412, 2414, 2416.

In some examples, the arm 2610 shown and described in FIG. 26 is implemented in connection with the baffles 2402, 2404, 2406, 2408 at the outlet ends 2426 of the server chassis 2410, 2412, 2414, 2416 as shown and described in connection with FIGS. 24 and 25. Further, in some examples, metal baffles that change shape in response to changes in temperature are positioned at both the inlet and outlet ends 2424, 2446 of the server chassis 2410, 2412, 2414, 2416. Other arrangements and/or configurations of baffles disclosed herein are also possible. For instance, in the illustrated examples of FIGS. 24-26, the baffles 2402, 2404, 2406, 2408, 2602, 2604, 2606, 2608 and/or the associated arms 2610 are attached to an exterior of the server chassis 2410, 2412, 2414, 2416. In other examples, the baffle can be attached to the interior of the server chassis as shown by the example baffle 2702 in the server chassis 2704 of FIG. 27. Further, in the foregoing examples, the baffles extend beyond the inlet and outlet ends 2424, 2426 of the server chassis. However, FIG. 28 illustrates an example metal baffle 2802 positioned at an internal location with an associated server chassis 2804. Further, FIG. 29 illustrates an example server chassis 2902 that includes multiple baffles 2904, 2906 that operate in combination to adjust the flow impedance of cooling fluid through the chassis. In other examples, multiple baffles at different locations along the flow path of the cooling fluid within the server chassis can be employed.

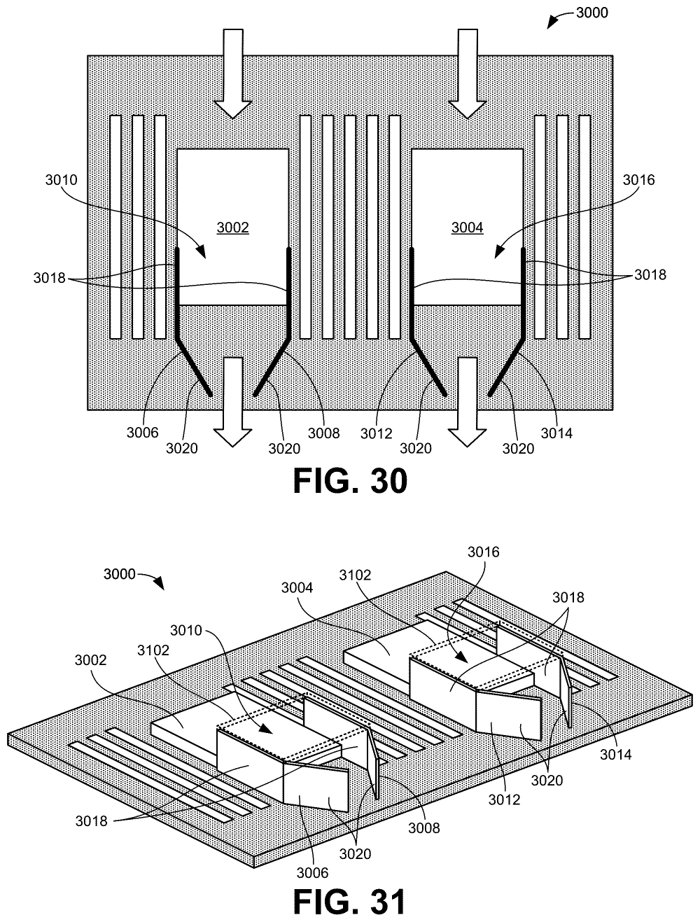

The example baffles 2402, 2404, 2406, 2408, 2602, 2604, 2606, 2608, 2702, 2802, 2904, 2906 of FIG. 24-26 automatically adjust the flow impedance of cooling fluid 2420 relative to individual ones of the server chassis. In other examples, similar baffles can be implemented at the circuit board level and/or individual component level as shown and described with reference to FIGS. 30-32. In particular, FIG. 30 illustrates an example circuit board 3000 that includes a plurality of heat generating electronic components including two IC chips 3002, 3004. However, the IC chips 3002, 3004 could be any other type of heat producing electronic component. In this example, the IC chips 3002, 3004 are relatively high TDP devices (e.g., CPU chips, memory chips, etc.). FIG. 31 is an isometric view of the example circuit board 3000 of FIG. 30. As shown in the illustrated examples, two baffles 3006, 3008 are positioned on either side of the first IC chip 3002 to define a first channel 3010 therebetween. Likewise, two baffles 3012, 3014 are positioned on either side of the second IC chip 3004 to define a second channel 3016 therebetween.

In this example, each of the baffles 3006, 3008, 3012, 3014 includes a support wall 3018 and an end flap 3020. In some examples, the support walls 3018 are mechanically coupled to the circuit board 3000 and/or the IC chips 3002, 3004 to secure the baffles 3006, 3008, 3012, 3014 in place adjacent the IC chips 3002, 3004. As shown in the illustrated examples, the support walls 3018 extend away from the circuit board 3000 (e.g., perpendicular and/or transverse to the circuit board 3000) beyond an exposed exterior surface of the IC chips 3002, 3004. In some examples, the support walls 3018 extend beyond the exposed exterior surface of the IC chips 3002, 3004 a distance that is equal to or greater than the thickness of the IC chips 3002, 3004. In some examples, the distance away from the circuit board 3000 beyond the exposed surface of the IC chips 3002, 3004 that the support walls 3018 extends is multiple (e.g., 2, 3, 4, 5, etc.) times the thickness of the IC chips 3002, 3004. Having the support walls 3018 extend beyond the IC chips 3002, 3004 in this manner provides depth to the associated channel 3011, 3016 to guide cooling fluid across the exposed exterior surface of the IC chips 3002, 3004.

The arrows in FIG. 30 are provided for purposes of explanation to represent the flow of the cooling fluid across the IC chips 3002, 3004. Thus, as shown in the illustrated examples, the support walls 3018 are oriented to extend along the flow direction of the cooling fluid. Further, as shown in the illustrated example, the support walls 348 extend along opposite edges of the IC chips 3002, 3004. In this examples, the support walls 3018 extend along approximately half the length of the edges of the IC chips 3002, 3004. In other examples, the support walls may extend along a larger proportion (e.g., all) of the length of the edges of the IC chips 3002, 3004. In some examples, the support walls 3018 extend more than a full length of the edges of the IC chips 3002, 3004 (e.g., the support walls 3018 extend beyond ends of the IC chips 3002, 3004 in a direction opposite the fluid flow represented by the arrows in FIG. 30). In other examples, the support walls 3018 extend less than half the length of the edges of the IC chips 3002, 3004.

In this example, the support walls 3018 support the end flaps 3020 at the end of the baffles. That is, whereas the support walls 3018 are directly coupled to the circuit board 3000 and/or the IC chips 3002, 3004 to be held in place, the end flaps 3020 are not directly attached to the circuit board 3000 or the IC chips 3002, 3004 so as to be able to move relative thereto. More particularly, in some examples, the baffles 3006, 3008, 3012, 3014 are fabricated with a memory metal and/or a multi-metallic strip (at least in the region of the joint between the support walls 3018 and the end flaps 3020) so as to change shape in response to a change in temperature of the IC chips 3002, 3004 and/or the cooling fluid. Thus, in some examples, the end flaps 3020 are spaced apart from the circuit board 3000 and other components attached thereto (except for the support walls 3018) to be free to move relative thereto.

In some examples, a cross beam 3102 (shown in dashed lines in FIG. 31 to provide visibility of underlying components) can extend between the outward protruding edges of the support walls 3018 to enclose the channels 3010, 3016 on all sides between upstream and downstream ends of the channels 3010, 3016. In the illustrated example, the cross beam 3102 is the same length as the support walls 3018. However, in other examples, the cross-beam 3102 can be longer or shorter (in the direction of fluid flow represented by the arrows shown in FIG. 30) than the support walls 3018. More particularly, in some examples, the cross beam 3102 extends downstream of the support walls 3018 so as to extend over the end flaps 3020. That is, the end flaps 3020 are positioned directly between the circuit board 3000 and the cross beam 3102. In this way, mixing of the cooling fluid that passes outside of the channels 3010, 3016 with fluid passing through the channels 3010, 3016 is reduced before the fluid passing through the channels 3010, 3016 (which will be heated by the IC chips 3002, 3004) contacts the end flaps 3020. In some such examples, the end flaps 3020 are spaced apart from and/or otherwise able to move relative to the cross beam 3102 in response to changes in temperature of the cooling fluid.

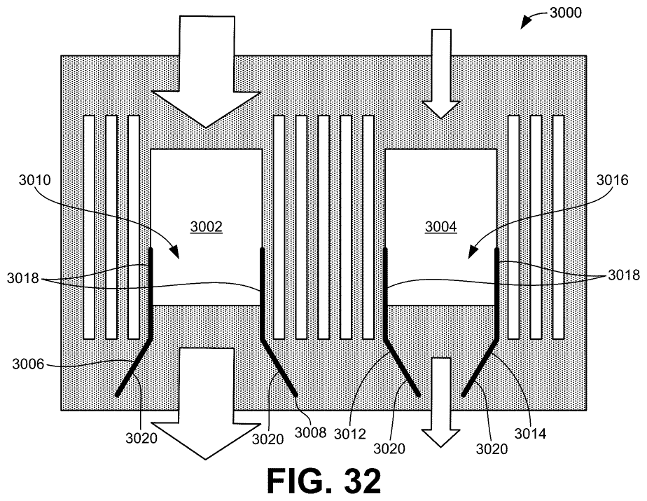

As shown in this example, the end flaps 3020 on the pairs of the baffles 3006, 3008, 3012, 3014 on either side of the same IC chip 3002, 3004 are angled toward one another relative to the corresponding support walls 3018. As a result, the end flaps 3020 restrict the flow of fluid at a downstream end of the channels 3010, 3016 defined by the baffles 3006, 3008, 3012, 3014. However, if the corresponding IC chip 3002, 3004 begins heating up, the cooling fluid passing over the IC chip will also heat up. As the cooling fluid comes into contact with the baffles 3006, 3008, 3012, 3014, the increased temperature of the cooling fluid will cause the baffles 3006, 3008, 3012, 3014 to also increase in temperature. This change in temperature in the baffles 3006, 3008, 3012, 3014 and, more particularly, change in temperature of the memory metal and/or multi-metallic strip in the baffles, will cause the baffles to change shape (e.g., cause the end flaps 3020 to move relative to the support walls 3018). An example change in the shape of the baffles 3006, 3008 associated with the first IC chip 3002 is represented in FIG. 32. As shown in FIG. 32, the end flaps 3020 of the baffles 3006, 3008 are angled outward relative to the associated support walls 3018. As a result, the first channel 3010 is no longer obstructed or restricted by the end flaps 3020 such that the flow of cooling fluid through the channel 3010 can increase (as represented by the larger arrows shown in FIG. 32 relative to those shown in FIG. 30).

The position of the end flaps 3020 at a relatively low temperature (FIG. 30) and at a relatively high temperature (FIG. 32) can be designed to any suitable position based on the construction of the memory metal and/or multi-metallic strip within the associated the baffles 3006, 3008, 3012, 3014. For instance, in some examples, rather than angling outward, the end flaps 3020 extend straight in alignment with the support walls 3018 in response to an increase in temperature. In some examples, the end flaps 3020 remain angled inwards but at less of an angle than in FIG. 30.

More generally, the size, shape, position, and orientation of the baffles 3006, 3008, 3012, 3014 relative to the IC chips 3002, 3004 and/or the circuit board 3000 can be modified in any suitable manner depending on the particular application in which the baffles are to be employed. Further, any of the variations described in connection with FIGS. 24-29 associated with baffles at the server level can be suitable adapted to baffles at the board level shown in FIGS. 30-32. For instance, end flaps 3020 can additionally or alternatively be positioned at the upstream end of the IC chips 3002, 3004 to increase or decrease the flow impedance of the cooling fluid upstream of the IC chips. In such examples, the movement of such end flaps 3020, based on a change in shape of an associated memory metal and/or multi-metallic strip, cannot rely on changes in temperature of the cooling fluid because the end flaps are upstream of the heat dissipating IC chip. However, in some such examples, the end flaps can move in response to heat conducted through the support walls 3018 that are thermally coupled to the IC chips 3002, 3004 and/or extend sufficiently downstream to be heated by an increased temperature of the cooling fluid after having passed over some or all of an associated IC chip 3002, 3004.

In some examples, baffles can be spaced apart from particular electronic components and/or associated server chassis and attached to the walls of an immersion tank and/or some other structure disposed in the immersion tank. Thus, baffles constructed in accordance with any of the example baffles 2402, 2404, 2406, 2408, 2602, 2604, 2606, 2608, 2702, 2802, 2904, 2906, 3006, 3008, 3012, 3014 of FIGS. 24-30 can be implemented in any of the example cooling assemblies, immersion tanks, and/or electronic components described in any of FIGS. 1-23.

A challenge in implementing immersion cooling systems is selecting suitable cooling fluids. Not only must the cooling fluid be electrically insulative, but the fluid must also be chemically compatible with the electronic components and/or the circuit boards carrying such components that are to be immersed within the fluid so as to avoid the components reacting with and/or corroding as a result of contact with the fluid. Such incompatibility and resulting contaminants in the cooling fluid can negatively impact the operation of the associated cooling system and/or the operation of the electronic components themselves. To avoid such concerns, engineers of immersion cooling systems must select from a relatively narrow set of relatively expensive cooling fluids. However, examples disclosed herein enable the use of a much broader array (and less expensive) cooling fluids by covering and/or encapsulating electronic components that are incompatible with such fluids with a thermal interface material (TIM) made from a curable thermal gel (e.g., an epoxy-like TIM). As used herein, an epoxy-like TIM is a material with relatively high thermal conductivity (e.g., equal to or above 2.0 W/mK) that begins as a dispensable liquid or thermal gel that can then be cured to a solid. In some examples, the thermal gel is a two-part material that remains in the liquid or gel state until the two parts are combined and allowed to cure. In other examples, the TIM is a one-part thermal gel. In some examples, the cured (solidified) TIM is resiliently compliant (like rubber).

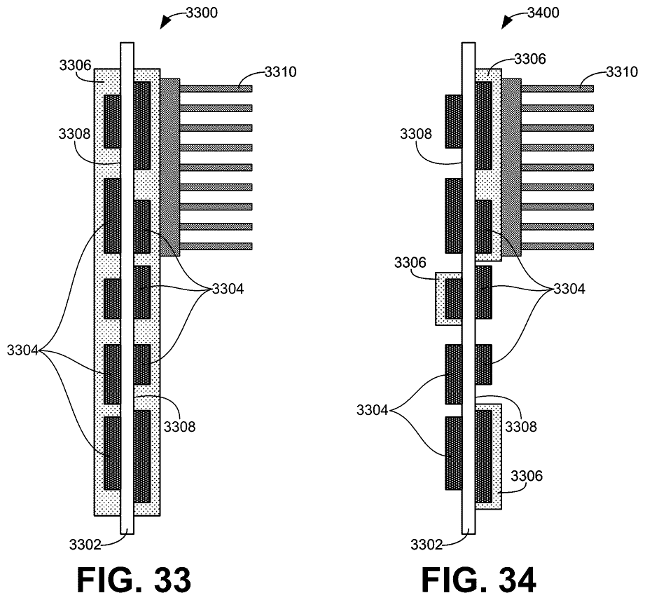

FIG. 33 illustrates an example circuit board assembly 3300 to be immersion cooled. The example assembly 3300 includes a circuit board 3302 with electronic components 3304 covered by and/or encapsulated in a cured thermal gel TIM 3306 in accordance with teachings disclosed herein. The circuit board 3302 can be a motherboard, an adaptor card (e.g., PCIe, NIC, Ethernet, etc.), a circuit board for a peripheral device such as an solid state drive (SSD), or other kind of circuit board. The electronic components 3304 can correspond to any type of electronic component including semiconductor dies (e.g. IC chips), resistors, capacitors, etc. In this example, the electronic components 3304 are positioned on both sides of the circuit board 3302. However, in other examples, the electronic components are positioned on only one side of the circuit board 3302. As shown in the illustrated example, the electronic components 3304 are surrounded or enclosed by the TIM 3306. More particularly, the TIM 3306 covers the outward facing surfaces of the electronic components 3304 (e.g., the surfaces facing away from the circuit board 3302) as well as the lateral sides of the electronic components 3304. That is, as shown in FIG. 33, the TIM 3306 fills in the gaps or spaces between adjacent electronic components 3304. Further, in some examples, the TIM 3306 extends to and is in contact with the exposed surfaces 3308 of the circuit board 3302 between the electronic components. In some examples, the TIM 3306 extends underneath the electronic components 3304 in gaps or spaces between the electronic components 3304 and the outward facing surfaces 3308 of the circuit board 3302 (e.g., around solder joints and the like). The TIM 3306 is able to reach and/or fill in these regions and spaces because the TIM 3306 is a curable thermal gel material that is initially in a liquid or gel form that is applied (e.g., through spraying, dipping, printing, etc.) to the circuit board 3302 and electronic components 3304. As a result, the liquid or gel is able to flow or seep into relatively small spaces and around various contours and/or shapes of the electronic components 3304 to entirely enclose or surround the components 3304. Once the thermal gel is applied, the gel is allowed to set or cure into the solid TIM 3306 represented in the illustrated example.

By completely encapsulating the electronic components 3304 within the TIM 3306, the TIM 3306 can protect the components 3304 from contact with external materials including immersion cooling fluids into which the circuit board assembly 3300 is immersed. More particularly, inasmuch as the TIM 3306 is a solid (once cured), the TIM 3306 acts as a physical barrier that prevents direct contact between the electronic components 3304 and a surrounding cooling fluid. As such, the likelihood of the electronic components 3304 reacting with the cooling fluid, thereby causing corrosion, contamination, and/or other concerns is greatly, if not entirely, diminished. Significantly, the TIM 3306 is composed of materials that are compatible with the cooling fluid so that the above issues are not a concern.

In examples disclosed herein, the TIM 3306 is thermally conductive. As such, while the TIM 3306 keeps the electronic components 3304 physically separated from a cooling fluid, heat generated by the components 3304 is still transferred through the TIM 3306 to the cooling fluid, thereby enabling the cooling fluid to cool the circuit board assembly 3300. In some examples, to further facilitate heat transfer away from the electronic components 3304, a heat sink 3310 is attached to the outer surface of the TIM 3306. As shown in the illustrated example, the solid nature of the TIM 3306 across the circuit board 3302 can provide a solid surface to which the heat sink 3310 may attach that can extend across multiple individual electronic components 3304. In other examples, the heat sink 3310 is sized and dimensioned to be adjacent a single electronic component 3304 on the circuit board 3302.

While the solid nature of the TIM 3306 can provide a structural base for the heat sink 3310, in some examples, the TIM 3306 is at least somewhat elastic or compliant (like rubber). In this manner, the TIM 3306 can flex or move in response to expansion, contraction, warping, and/or other physical changes to the circuit board 3302 and/or the electronic components 3304 as they change temperature.

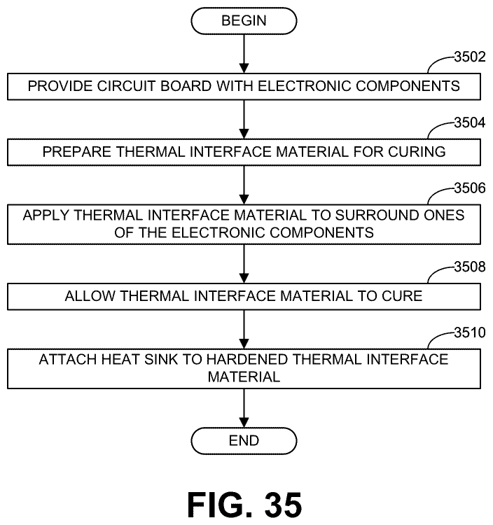

In some examples, not all of the electronic components 3304 pose concerns for corrosion or other issues due to incompatibility with a cooling fluid to be used to cool the assembly 3300. That is, in some examples, at least some of the electronic components 3304 are compatible with the cooling fluid such that there is no need to seal them off from the cooling fluid with the TIM 3306. Accordingly, only some of electronic components 3304 are covered by the TIM 3306. That is, in some examples, the TIM 3306 is selectively applied to regions on the circuit board 3302 for which the TIM 3306 is needed (e.g., to protect components with incompatible materials and/or to provide a base or surface to which a heat sink 3310 can be mounted). This is represented by the example circuit board assembly 3400 of FIG. 34, in which similar components as in FIG. 33 are identified with similar reference numbers. As shown in FIG. 34, the TIM 3306 encapsulates and/or encloses some of the electronic components 3304 while other ones of the components 3304 are left exposed to be directly cooled by a cooling fluid when placed in an immersion tank. The application of the TIM 3306 as shown and described in the illustrated examples of FIGS. 34 and 35 can be used on any electronic components and/or associated circuit boards immersed in cooling fluids used in any one of the example cooling systems shown and described above in connection with FIGS. 1-33.

FIG. 35 is a flowchart illustrating an example method of manufacturing any one of the example circuit board assemblies 3300, 3400 of FIGS. 33 and 34. Although the example method is described with reference to the flowchart illustrated in FIG. 35, many other methods may alternatively be used. For example, the order of execution of the blocks may be changed, and/or some of the blocks described may be combined, divided, re-arranged, omitted, eliminated, and/or implemented in any other way.

The example process begins at block 3502 by providing a circuit board (e.g., the circuit board 3302) with electronic components (e.g., the electronic components 3304). At block 3504, the process involves prepare thermal interface material (e.g., the TIM 3306) for curing. In some examples, if the TIM is a two-part thermal gel, the TIM is prepared by mixing the two parts. If an external catalyst (e.g., the application of heat) initiated the curing process, block 3504 can be omitted. At block 3506, the process involves applying the TIM, while still in the liquid or gel form, to surround (e.g., enclose and/or encapsulate) ones of the electronic components 3304. In some examples, all or substantially all of the electronic components 3304 are covered by the TIM 3306 (as represented in FIG. 33). In other examples, individual ones and/or isolating groupings of the electronic components 3304 are covered by the TIM 3306 (as represented in FIG. 35). on the circuit board are covered fluid 2004 in the tank 2002. Thereafter, at block 3508, the process involves allowing the thermal interface material to cure (e.g., harden). In some examples, an external catalyst (e.g., the application of heat) is used to facilitate and/or complete the curing process. In some examples, the blocks 3504, 3506, and/or 3508 involve the use of a fixture, mold, or other assembly to control the thickness, flatness, and/or spread of the TIM until it has cured/hardened. In some example, a post cure planarization process may be implemented to facilitate a flatness of the hardened TIM 3306. At block 3510, the example process involves attaching a heat sink (or other cooling device) to the hardened TIM 3306. If a heat sink is not needed, block 3510 may be omitted. Thereafter, the example process of FIG. 35 ends.

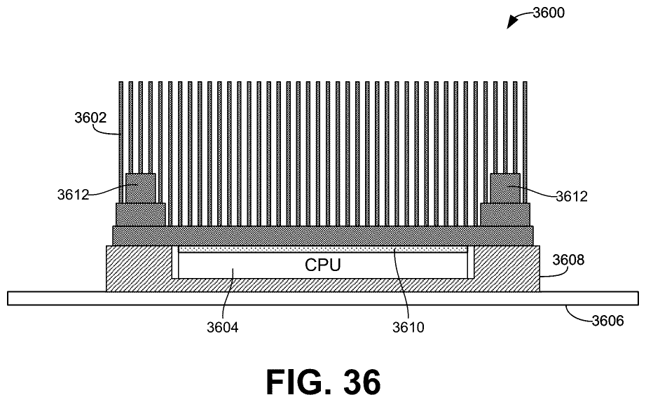

The material properties of the curable thermal gel TIM outlined above can be advantageously used in other liquid cooling situations other than to encapsulate or protect electronic components that are not compatible with immersion cooling fluids (as well as applications that do not involve immersion cooling). For instance, in some examples, a curable thermal gel TIM is used as the thermal interface between a CPU and an associated heat sink. In particular, FIG. 36 illustrates an example CPU assembly 3600 that includes a heat sink 3602 thermally coupled to a CPU die 3604 mounted to a circuit board 3606 (e.g., a motherboard). In this example, the CPU die 3604 is mounted to the circuit board 3606 via a CPU socket 3608. In other examples, the CPU die 3604 can be mounted directly to the circuit board 3606 (e.g., with solder).

As shown in the illustrated example, the heat sink 3602 is thermally coupled to the CPU die 3604 with a curable thermal gel TIM 3610. In some examples, the TIM 3610 is initially applied to the underside of the heat sink (in the thermal gel form) and allowed to cure or harden. In some examples, a fixture is used when applying the liquid components of the TIM 3610 to control the thickness and flatness of the TIM 3610. Once the TIM 3610 has cured it becomes a solid that will retain its shape. However, as noted above, in some examples the solid TIM 3610 is elastic or resilient (like rubber) to be able to flex under pressure. As a result, when the heat sink 3602 is pressed against the CPU die 3604 using the clamping mechanisms 3612 (e.g., springs, screws, etc.), the resilient nature of the TIM 3610 will compress and provide good contact with the CPU die 3604 for improved heat transfer. Furthermore, due to the compatibility of the TIM 3610 with immersion cooling fluids, the CPU assembly 3600 of FIG. 36 can be expected to provide stable performance for a longer period of time than traditional TIMs that degrade over time when immersed in a cooling fluid.

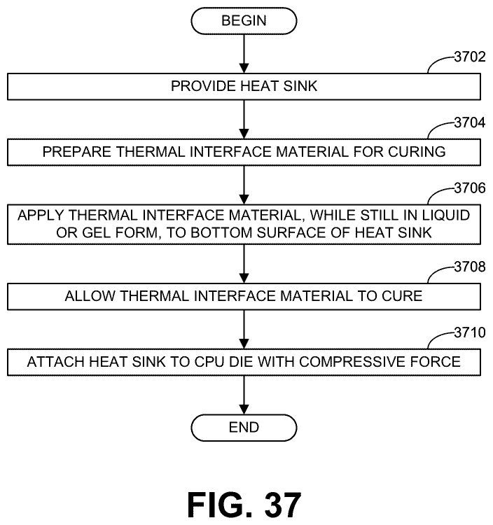

FIG. 37 is a flowchart illustrating an example method of manufacturing the example CPU assembly 3600 of FIG. 36. Although the example method is described with reference to the flowchart illustrated in FIG. 37, many other methods may alternatively be used. For example, the order of execution of the blocks may be changed, and/or some of the blocks described may be combined, divided, re-arranged, omitted, eliminated, and/or implemented in any other way.

The example process begins at block 3702 by providing a heat sink (e.g., the heat sink 3602). At block 3704, the process involves preparing thermal interface material (e.g., the TIM 3610) for curing. In some examples, if the TIM is a two-part thermal gel, the TIM is prepared by mixing the two parts. If an external catalyst (e.g., the application of heat) initiated the curing process, block 3504 can be omitted. At block 3706, the process involves applying the TIM, while still in liquid or gel form, to a bottom surface of the heat sink 3602 (e.g., the surface to face toward the CPU die 3604). Thereafter, at block 3708, the process involves allowing the thermal interface material to cure (e.g., harden). In some examples, an external catalyst (e.g., the application of heat) is used to facilitate and/or complete the curing process. In some examples, the blocks 3704, 3706, and/or 3708 involve the use of a fixture, mold, or other assembly to control the thickness, flatness, and/or spread of the TIM 3610 until it has cured/hardened. In some example, a post cure planarization process may be implemented to facilitate a flatness of the hardened TIM 3610. At block 3710, the example process involves attaching the heat sink 3602 to a CPU die 3604 with a compressive force. The resilient (clastic) nature of the TIM 3610 will result in the TIM 3610 being compressed against the CPU die 3604, thereby providing good contact for reliable heat transfer from the CPU die 3604 to the heat sink 3602. Thereafter, the example process of FIG. 37 ends.

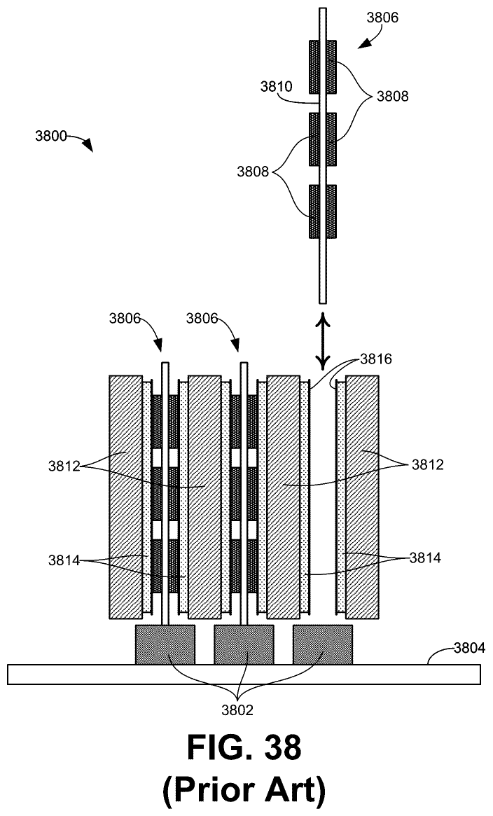

Another example use for curable thermal gel TIMs disclosed herein is in connection with liquid cooled memory systems. FIG. 38 illustrates a known liquid cooling system 3800 commonly used to cool dual in-line memory modules (DIMMs). In FIG. 38, the liquid cooling system 3800 includes three DIMM sockets 3802 on a circuit board 3804. Each of the DIMM sockets 3802 is configured to receive a corresponding DIMM 3806. As shown in FIG. 38, two DIMMs 3806 are plugged into their respective DIMM sockets 3802 while the third DIMM 3806 is removed to represent that it is possible to repeatedly insert and remove the DIMMs 3806 from a corresponding socket 3802 as needed. As shown in FIG. 38, the DIMMs 3806 include a plurality of heat producing electronic components 3808 (e.g., memory chips) on a memory circuit board 3810. When positioned within a socket 3802, a DIMM 3806 is sandwiched between two cold plates 3812 that draw heat from the DIMM 3806. The cold plates 3812 can include vapor chambers and/or liquid tubes to enable the cooling. To enable heat transfer between the DIMMs 3806 and the cold plates 3812, a thermal pad (traditional TIM) 3814 is attached to the cold plates 3812 and dimensioned to contact the DIMMs 3806 when plugged into the sockets 3802.

As noted above, the DIMMs 3806 used in the known liquid cooling system of FIG. 38 can be repeatedly plugged in and unplugged from the sockets 3802, which can cause wear on the thermal pads 3814. To reduce such wear, the thermal pads 3814 are covered with an anti-scratch film 3816. The anti-scratch film 3816 is the material in direct contact with the electronic components 3808 on the DIMMs 3806. While the anti-scratch film 3816 reduces wear so that DIMMs 3806 can be inserted and removed from the sockets 3802 more times than would otherwise be possible, the anti-scratch film 3816 has a relatively high thermal resistance, thereby reducing the performance and/or efficiency of the cold plates 3812. Furthermore, the anti-scratch film 3816 will itself wear away over time and can become damaged or peel off the thermal pads 3814, which can result in a further reduction in thermal performance of the system and/or damage to the electronic components 3808.

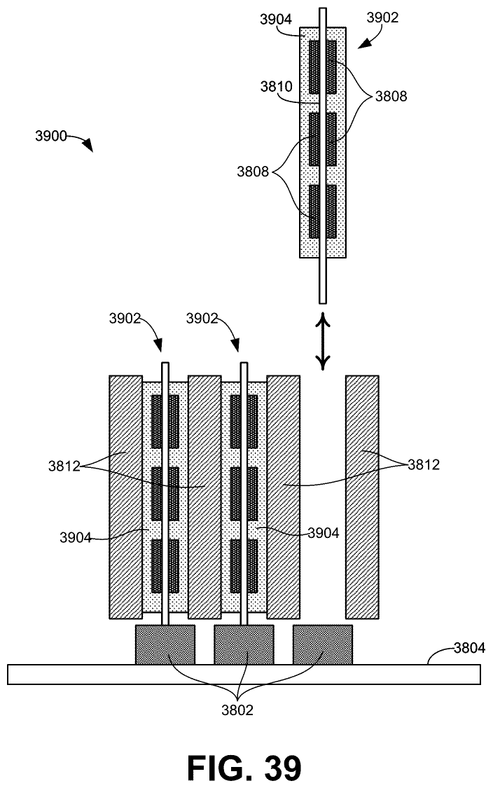

FIG. 39 illustrates an example liquid cooling system 3900 constructed in accordance with teachings disclosed herein to overcome some of the limitations of the known cooling system 3800 shown in FIG. 38. For purposes of explanation, similar components in FIGS. 38 and 39 are identified with similar reference numbers. Thus, as shown in the illustrated example of FIG. 39, three DIMM sockets 3802 are located on a circuit board 3804 and configured to receive example DIMMs 3902 inserted therein. When inserted in a socket 3802, the example DIMMs 3902 are sandwiched between two of the cold plates 3812. However, unlike what is shown in FIG. 38, the cold plates 3812 in the example system 3900 of FIG. 39 do not have thermal pads 3814 attached thereto. Instead, in FIG. 39, a curable thermal gel TIM 3904 is applied directly to the electronic components 3808 and the memory circuit board 3810 of the example DIMMs 3902. More particularly, as shown in the illustrated example, the TIM 3904 surrounds and/or encapsulates the electronic components 3808 on all sides and is also in contact with the memory circuit board 3810 similar to the example circuit board assembly 3400 of FIG. 34.

In some examples, the thickness and/or flatness of the TIM 3904 when it is applied as a liquid is controlled so that once it cures into a solid, the outer surfaces of the TIM 3904 will be substantially parallel to one another so as to evenly interface with the substantially parallel cold plates 3812. As used herein, substantially parallel means exactly parallel or within 5 degrees of exactly parallel. Further, in some examples, the thickness of the TIM 3904 is controlled so that the overall thickness of the DIMM 3902 (from opposing outer surfaces of the TIM 3904 on either side of the circuit board 3810) is slightly larger than the space between adjacent ones of the cold plates 3812 to provide an interference fit when the DIMMs 3902 are inserted into corresponding sockets 3802. Due to the elasticity and/or resilient compliance of the TIM 3904, the TIM 3904 will compress when inserted and clamped between the cold plates 3812 to provide good contact for improved heat transfer. Furthermore, the TIM 3904 extends between the electronic components 3808 and the cold plates 3812 without an anti-scratch film (such as the anti-scratch film 3816 of FIG. 38) that would otherwise reduce heat transfer between the electronic components 3808 and the cold plates 3812. Further still, as shown in FIG. 39, the TIM 3904 contacts the sides of the electronic components 3808 and the surface of the memory circuit board 3810. As a result, the TIM 3904 is able to facilitate heat transfer from all regions of the DIMMs 3902 (including the circuit board 3810) for improved performance. By contrast, heat transfer through the thermal pads 3814 in the known system 3800 of FIG. 38 is limited to the points of contact with the electronic components 3808, which are limited to the outward facing surfaces of the electronic components 3808.

The example TIMs 3406, 3610, 3904 described in connection with FIGS. 34-39 can be implemented with any suitable epoxy-like (curable thermal gel) TIM that has the material properties outlined above including being a thermal gel that can be applied as a liquid and then cures to a solid that is resiliently compliant (e.g., elastic), having relatively high thermal conductivity, and being compatible immersion cooling fluids. Although resilient, in some examples, the TIM 3406, 3610, 3904 is relatively hard to withstand multiple plug-in/plug-out actions (e.g., in the case of the memory cooling system 3900 of FIG. 39). Further, in some examples, the TIM 3406, 3610, 3904 has a relatively low viscosity after the curing process to reduce the risk of the TIM 3406, 3610, 3904 and/or the electronic components being torn down when being handled (plugged or unplugged into a socket).

Candidate materials for the TIMs 3406, 3610, 3904 include thermally conductive gels the provide good thixotropic characteristics and relatively low viscosity, prior to curing, to facilitate the dispensing of the material in a relatively easy and controlled manner. Further, in some examples, gels that cure in a relatively short amount of time (e.g., less than 20 minutes) of time are used to shorten the fabrication process. Further, as outlined above, materials for the TIMs 3406, 3610, 3904 are selected to provide relatively high compressibility, once cured, to reduce (e.g., minimize) thermal resistance at interfaces where the TIM is to be used. A particular example candidate for the TIMs 3406, 3610, 3904 is HLT3500 gap filler provided by Honeywell Corporation headquartered in Charlotte, North Carolina. Being a “gap filler” the HLT3500 is akin to a rubber epoxy and therefore is elastic. According to HLT3500 product specifications, the HLT3500 material has a thermal conductivity of 3.5 W/mK, a thermal impedance of 0.44° C. in²/W, and a Shore00 hardness of 40. Another possible candidate for the TIM 3406 is HLT2000 gap filler provided by Honeywell Corporation which has a thermal conductivity of 2.0 W/mK, a thermal impedance 0.66° C. in²/W, and Shore00 hardness of 50. Simulations using HLT2000 and HLT3500 as the TIM 3904 in FIG. 39 reveal significant improvements relative to a traditional thermal pad shown in FIG. 38 (e.g., a Laird-320 thermal pad). The above-identified materials provide adequate thermal conductivity and are compatible with most cooling fluids and have the advantage of being less expensive than indium TIM that is commonly used in components cooled in immersion cooling systems. Thus, in some examples, the TIM 3406, 3610, 3904 does not include indium. Further, while indium TIM is relatively compatible with some cooling fluids, indium TIM corrodes over time more quickly than the thermal gel TIMs disclosed herein. As such, the curable thermal gel TIMs disclosed herein can maintain reliability for a longer period of time than indium TIM.

As noted above, two-phase immersion cooling involves a cooling liquid is caused to boil and turn into vapor as it draws heat away from electronic components after which it is condensed back into a liquid. To facilitate the onset of boiling of such a two-phase cooling liquid (and the associated heat transfer from electronic components to the cooling liquid) in a two-phase immersion cooling system, many high thermal output components (e.g., CPUs, GPUs, XPUs, etc.) are thermally coupled to a boiler plate. As used herein, a boiler plate refers to a block or piece of thermally conductive material that has a first surface that is thermally coupled to an electronic component and a second surface directly exposed to the cooling fluid such that as the electronic component generates heat, the heat can pass from the electronic component through the boiler plate and into the surrounding cooling liquid. Frequently, the second surface of boiler plates that directly interfaces with the two-phase cooling liquid includes surface features (e.g., irregularities) that promote boiling of the cooling liquid to enhance heat transfer. These surface features are typically created by adding material to the surface of a solid mass block or plate of metal (e.g., copper) that serves as the base or main body of the boiler plate. The added material that provides irregularities to the surface of the base metal plate to promote boiling is referred to herein as the boiling enhancement layer (BEL). In some instances, the BEL is created by the application or bonding of a coating or film (e.g., approximately 100 to 500 um thick) that includes granulated powder onto the exposed surface of the base metal plate. Such a coating is sometimes referred to as a bonding enhancement coating (BEC). Additionally or alternatively, in some instances, the BEL is created by the application or bonding of one or more metal meshes to the solid base metal plate.

Whether the BEL of a boiler plate is a powdered coating (e.g., a BEC) or corresponding to a stack of metal meshes, the materials used to create the BEL are distinct from the underlying base metal plate used for the boiler plate. As a result, the manufacturing of boiler plates typically involves multiple (e.g., two or more) fabrication processes including, for example, the fabrication of the base solid plate, fabrication of the BEL material, and the bonding of the BEL to the base plate (e.g., with a cold spray, using a high temperature fusing process for a BEC, a low temperature soldering process for a metal mesh, etc.). Manufacturing of boiler plates through multiple processes in this manner results in increased costs and complexity to the fabrication process. Further, these processes can result in greater variation in output products, which can negatively impact thermal performance of the boiler plates (e.g., due to incomplete solder coverage and/or delamination of the BEL from the underlying metal plate). Furthermore, some materials used to bond the BEL to the base metal plate are not compatible with certain immersion cooling fluids. For instance, bismuth is a material commonly used in low temperature solder that is known to be incompatible with various two-phase cooling fluids. As such, boiler plates that use bismuth cannot be used in certain cooling systems without risking performance degradation of the boiler plate, contamination of the cooling system, and/or the potential for material transfer to electronic components being cooled (e.g., the bottom side pads of an IC chip), thereby affecting device performance. One solution is to cover such components with a curable thermal gel TIM as disclosed above in connection with FIGS. 34-39. Another solution is to fabricate boiler plates without solder or other bonding agent between the base of the boiler plate and the boiling enhancement features as disclosed in further detail below.

Some S example boiler plates disclosed herein can be manufactured in a single fabrication process with boiling enhancement features (e.g., irregularities) integrated into the main body of the boiler plate to serve the purpose of the separate BEL material added to typical boiler plates. As a result, example boiler plates disclosed herein can be manufactured at lower cost and with less manufacturing variations, thereby providing greater performance reliability. Further, example boiler plates disclosed herein can be manufactured without a bonding material or agent (such as solder) to attach, combine, or secure the BEL to the main body of the boiler plate, thereby avoiding concerns for contamination and/or issues of incompatibility with certain cooling fluids.

More particularly, some example boiler plates disclosed herein are manufactured using a single metal injection molding (MIM) process. MIM involves mixing a fine powder of metal (e.g., copper) with a binder material that can then be shaped and solidified using injection molding techniques. Once solidified, the binder is removed and the remaining metal particles are diffusion bonded to increase the density and strength of the final product. Components produced through MIM can exhibit micro-pores between different particles of the metal. Such pores on the surface of a boiler plate constitute irregularities that can fulfill the function of the BEL in typical boiler plates by promoting or enhancing boiling as bubble nucleation sites. Significantly, the MIM process can be adjusted to tune (e.g., increase or decrease) the size and/or amount of the micro-pores with a relatively high level of control such that the boiling enhancement features (e.g., irregularities) in example boiler plates disclosed herein can be specifically designed to enhance (e.g., optimize) boiling and the associated heat transfer. The size and/or amount of the micro-pores can be expressed with respect to the porosity of the component. As used herein, porosity is the ratio of the volume of cavities or voids in a material (e.g., the volume of the micro-pores) to the total volume of the material. Porosity is typically expressed as a percentage. In addition to being able to control the porosity (e.g., size and/or amount of micro-pores) of a metal component fabricated using MIM techniques, it is also possible to vary the porosity across different portions or regions of a single component fabricated using MIM techniques. Thus, in some examples, the porosity of the MIM metal used in example boiler plates disclosed herein is characterized by a gradient and/or otherwise has different regions with different porosities.

Another advantage of MIM is the ability to fabricate metal components with complex shapes. Accordingly, some example boiler plates disclosed herein include non-planar exterior surfaces. More particularly, in some examples, boiler plates includes three-dimensional (3D) features or protrusions (e.g., a pin fin array) that extend from but are integrally formed with the main body of the boiler plate. In some examples, the non-planar surface is defined based on a mold used to fabricate the boiler plate using a MIM process. Such protrusions and/or other 3D features can increase the surface area of the boiler plate exposed to an immersion cooling liquid to improve thermal heat transfer by improving the critical heat flux (CHF) of the boiler plate. Additionally or alternatively, protrusions and/or other 3D features can create macro-irregularities (as opposed to the micro-irregularities of the micro-pores) that can further enhance boiling.

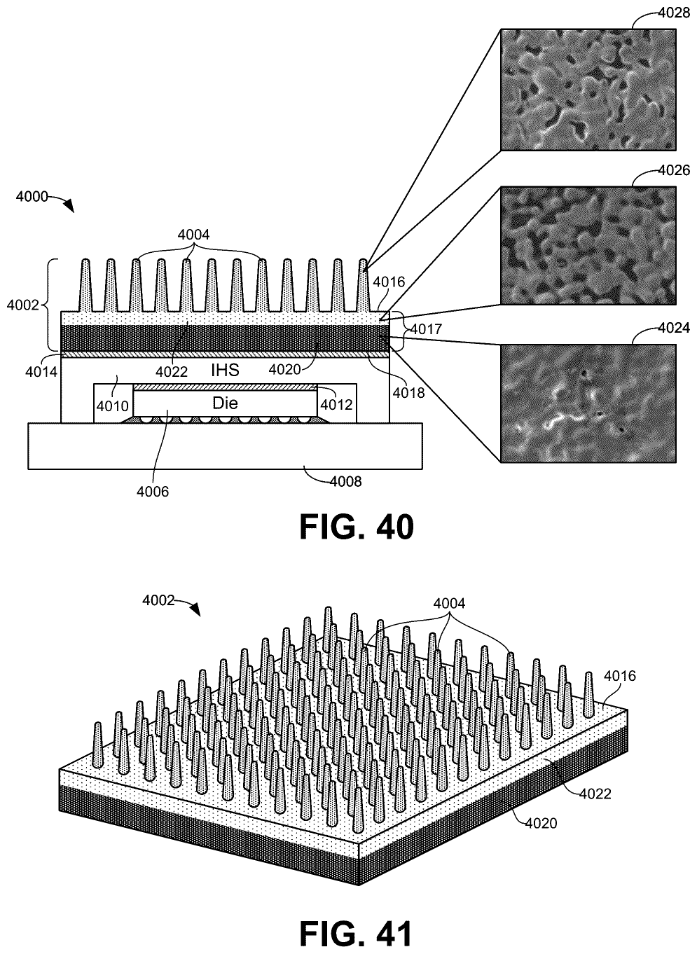

FIG. 40 illustrates a cross-sectional view of an example cooling system assembly 4000 that includes an example boiler plate 4002 with integrated 3D features or protrusion 4004 coupled to a semiconductor die or integrated circuit (IC) chip 4006. The semiconductor die 4006 can correspond to any heat producing electronic component (e.g., a CPU, a GPU, an XPU, a memory chip, etc.). In this example, the semiconductor die 4006 is electrically and mechanically coupled to an organic substrate 4008 (e.g., a printed circuit board (PCB)). Further, the semiconductor die 4006 is surrounded by an integrated heat spreader (IHS) 4010 that is thermally coupled to an upper surface of the die 4006 via a first thermal interface material (TIM) 4012. In this example, the boiler plate 4002 is positioned adjacent the upper surface of the IHS 4010 with a second TIM 4014 disposed therebetween to facilitate heat transfer from the IHS 4010 to the boiler plate 4002. In some examples, the first TIM 4012 and/or the second TIM 4014 is a curable thermal gel TIM as disclosed above in connection with FIGS. 34-39.

FIG. 41 illustrates an isometric view of the example boiler plate 4002 of FIG. 40. As shown in FIGS. 40 and 41, the 3D features or protrusions 4004 correspond to a grid or two-dimensional array of pins (commonly referred to as a pin fin array) protruding away from a baseline outer surface 4016 of the boiler plate 4002. As used herein, the baseline outer surface of a boiler plate is a surface facing away from a heat source to be cooled (e.g., the semiconductor die 4006) that defines a bulk region, main body, or base 4017 of the boiler plate. Thus, the baseline outer surface 4016 of the example boiler plate 4002 of FIGS. 40 and 41 may be distinguished from the protrusions 4004, which protrude outward from the baseline outer surface. Inasmuch as the protrusions 4004 are integrally formed with the base of the boiler plate 4002, the baseline outer surface 4016 and the protrusions 4004 are collectively referred to herein as the exposed outer surface of the boiler plate 4002. Thus, in some examples, the exposed outer surface of the boiler plate 4002 is non-planar (e.g., due to the 3D shape of the protrusions 4004). In this example, the baseline outer surface 4016 is planar and parallel to the inner surface 4018 of the boiler plate 4002 (e.g., the surface facing toward the semiconductor die 4006). However, in other examples, the baseline outer surface 4016 can define a 3D or non-planar surface independent of the protrusions 4004 (e.g., a concave surface, a gable-shaped surface, etc.) and/or be oriented at an angle relative to the inner surface 4018.

Although the individual protrusions 4004 (e.g., the pins of the pin fin array) protrude perpendicularly to the baseline outer surface 4016 in the illustrated example, in other examples, the protrusions 4004 extend from the baseline outer surface 4016 at non-perpendicular angles. Further, in some examples, different ones of the protrusions extend in different directions relative to one another. In this example, the protrusions are tapered such that the thickness (e.g., diameter) of the protrusions 4004 at their base is greater than the thickness of the protrusions 4004 adjacent their free ends. In other examples, the protrusions have a consistent thickness along their length. Further, the size and shape of the protrusions 4004 can be modified in any suitable manner in accordance with teachings disclosed herein. For example, the height to width aspect ratio can be less than or greater than what is shown in the illustrated example. Further, the cross-section of the protrusions 4004 can be any suitable shape (e.g., square, oval, rectangular, hexagonal, star shaped, etc.). In some examples, the protrusions 4004 are fins instead of pins. Additionally, the protrusions 4004 can be arranged on the baseline outer surface 4016 of the boiler plate 4002 in any suitable manner. For instance, in the illustrated example, the protrusions 4004 are arranged in a square grid or array. In other examples, the protrusions can be arranged in a hexagonal pattern, a triangular pattern, and/or in any other arrangement. Further, the spacing or pitch between adjacent protrusions 4004 can be less than or greater than what is shown in the illustrated example. In some examples, protrusions 4004 having different shapes and/or different arrangements are located on different regions of the boiler plate 4002.

As already noted above, the protrusions 4004 are integrated with (e.g., integrally formed with) the base 4017 or of the boiler plate 4002. This is made possible by fabricating the boiler plate 4002 (including the protrusions 4004) in a single MIM process. Although all portions of the boiler plate 4002 correspond to a single integrated body, in some examples, the MIM process is controlled so that different regions of the boiler plate 4002 are constructed to have different porosities. This is visually represented in FIGS. 40 and 41 by the different shading or stippling used in different regions of the boiler plate 4002, with darker shading or stippling representative of less porous (e.g., more solid) regions of the boiler plate 4002. Thus, in this example, a first portion 4020 of the base 4017 of the boiler plate 4002 adjacent the inner surface 4018 has the lowest porosity (e.g., the fewest and/or smallest micro-pores) of any portion or region of the example boiler plate 4002. A second portion of 4022 of the base 4017 of the boiler plate 4002 adjacent the outer surface 4016 has the highest porosity (e.g., the most and/or largest micro-pores) of any portion or region of the example boiler plate 4002. Further, in this example, the protrusions 4004 have an intermediate porosity that is higher than in the first portion 4020 and lower than in the second portion 4022. Example SEM images 4024, 4026, 4028 representative of the different porosities of the three different regions of the boiler plate 4002 are provided as insets in FIG. 40 for purposes of explanation.

In the illustrated example of FIGS. 40 and 41, the porosity of the first portion 4020 is the lowest to reduce (e.g., minimize) the size and/or amount of cavities (e.g., micro-holes) so as to increase (e.g., maximize) heat transfer from the IHS 4010, through the boiler plate 4002, and towards the outer surface 4016. However, the porosity at the baseline outer surface 4016 (e.g., in the second portion 4022) is much higher because the presence of larger and/or a greater number of micro-holes function as boiling enhancement features that promote boiling, thereby improving heat transfer from the boiler plate 4002 to the surrounding cooling liquid in which the boiler plate 4002 is immersed. More particularly, micro-pores that are exposed on the outer surface 4016 of the boiler plate 4002 serve as nucleation sites for boiling of a two-phase cooling liquid. As such, increasing porosity at the outer surface 4016 increases nucleation site density for enhanced boiling heat transfer. Notably, micro-pores that are internal to boiler plate 4002 (e.g., not exposed at the outer surface 4016) have less impact on boiling. As such, in some examples, the relatively highly porous region at the outer surface 4016 is relatively thin. Thus, in some examples, as shown in FIGS. 40 and 41, the second portion 4022 is thinner than the first portion 4020.

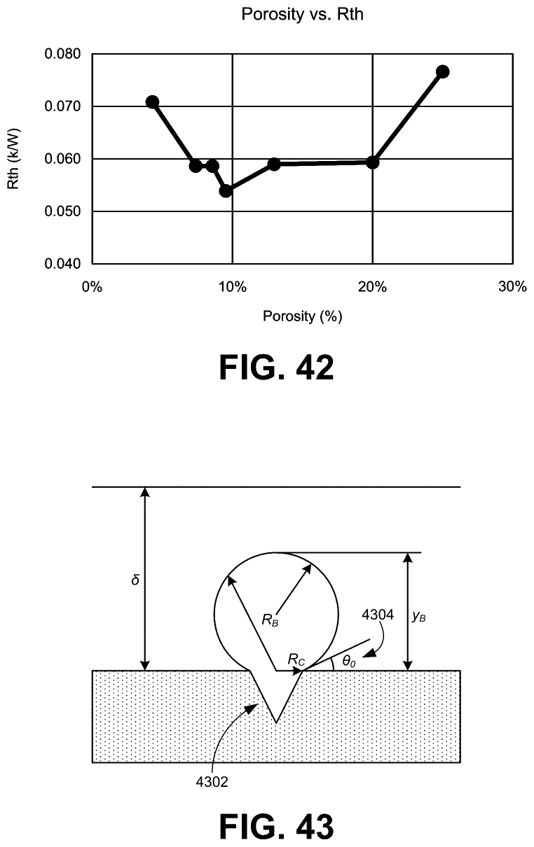

While increasing porosity can enhance boiling, the thermal performance advantages of the micro-pores are lost if the porosity is increased too high. In particular, FIG. 42 is a graph illustrating experimental results for the thermal resistance (Rth) (also known as Psi_cf) of boiler plates fabricated with different porosities. As shown in FIG. 42, the thermal resistance is lowest for porosities ranging between approximately 7% and 20%. Accordingly, in some examples, the porosity of the second portion 4022 designed to be between 7% and 20%. In some examples, the porosity is between 9% and 11% (e.g., 10%) because testing (as shown in FIG. 42) indicates this porosity achieves the lowest thermal resistance. Different porosities may be selected for different applications based on differences in the geometry of the boiler plate 4002, the two-phase cooling liquid used (e.g., FC-3284 was used in the testing to generate the graph of FIG. 42), and/or any other relevant considerations. More generally, the appropriate size for bubble nucleation sites (e.g., the micro-pores on the surface of the boiler plate 4002) can be approximated with Hsu's criterion, which is mathematically expressed as follows:

$$\{ {R}_{c , min} , {R}_{c , max} \} = \frac{{δ}_{t} {C}_{2}}{2 {C}_{1}} \frac{( {T}_{w} - {T}_{s a t} )}{( {T}_{w} - {T}_{b u l k} )} [ 1 ∓ \sqrt{1 - \frac{8 {C}_{1} σ {T}_{s a t} ( {T}_{w} - {T}_{b u l k} )}{{ρ}_{v} {h}_{lv} {{δ}_{t} ( {T}_{w} - {T}_{s a t} )}^{2}}} ] \qquad ( 1 )$$

where R_{c,min} and R_{c,max} represent the range of radii at the mouth of a conical crevice (e.g., the crevice 4302 shown in FIG. 43 which is representative of the micro-pores in the surface of the boiler plate 4002 of FIGS. 40 and 41) suitable for bubble nucleation, δₜ represents the thickness or depth of the superheated liquid film immediately above the boiling surface, T_{w} is the wall temperature, Tₛₐₜ is the saturation temperature of the fluid, T_{bulk} is the remote fluid temperature, ρᵥ is the density of the gaseous phase of the fluid, hₗᵥ is the latent heat of vaporization, and σ is the surface tension of the fluid. C₁ and C₂ in Equation (1) are functions of the contact angle 4304 (θ₀) shown in FIG. 43, as given in Equations (2) and (3) below.

$${C}_{1} = ( 1 + cos {θ}_{0} ) / sin {θ}_{0} \qquad ( 2 )$$

$${C}_{2} = 1 / sin {θ}_{0} \qquad ( 3 )$$

Based on experimental testing using typical two-phase coolant 3M™ FC-72, the values used in Equations (1)-(3) for sizing the nucleation sites are given in Table I. Based on these values, the range, as given by R_{c,min} and R_{c,max} was 0.5 μm to 75 μm, respectively.

TABLE I
Input Values for Sizing Nucleation Sites in FC-72

| | |
|---|---|
| Wall Temperature T_{w} (K) | 338 |
| Remote fluid temperature T_{bulk} (K) | 324 |
| Saturation temperature of fluid Tₛₐₜ (K) | 329 |
| Contact angle θ (Rad) | 0.87 |
| Latent heat of vaporization hₗᵥ (J/Kg) | 8.80E+04 |
| Surface tension of fluid σ (N/m) | 100E−02 |
| Film thickness δₜ (m) | 2.53E−04 |

Inasmuch as the protrusions 4004 will be exposed to the cooling liquid of an immersion cooling system and can, therefore, cause the liquid to boil, in some examples, the protrusions 4004 have a porosity that is relatively high for the same reasons discussed above with respect to the second portion 4022. More particularly, in some examples, the protrusions 4004 have a porosity that is similar to, the same as, or even higher than that of the second portion 4022. In other examples, the protrusions 4004 have a porosity similar to, the same as, or even lower than that of the first portion 4020.

While the example boiler plate 4002 illustrated in FIGS. 40 and 41 shows one example arrangement of different regions of different porosities, the boiler plate 4002 can be divided into any number of different regions with different corresponding porosities and/or the porosity of any particular region can be less than or greater than any other region. For instance, in some examples, the protrusion 4004 have a higher porosity than the second portion 4022. In some examples, different ones of the protrusions 4004 have different porosities. In some examples, different portions of the protrusions 4004 have different porosities. For instance, in some examples, the internal cores of the protrusions 4004 have a lower porosity than the exterior surfaces of the protrusions 4004. Additionally or alternatively, in some examples, different regions along an elongate length of the protrusions have different porosities (e.g., the base of the protrusions 4004 is associated with a higher porosity than the tip of the protrusions 4004 or vice versa). In some examples, rather than the porosity changing at discrete interfaces between different regions (as represented in the figures for purposes of illustration), the porosity can gradually change between two different locations on the boiler plate. That is, the porosity across the boiler plate 4002 (or any portion thereof) can be defined by a gradient in some examples.

Analytical modeling and experimental testing indicate that fabricating boiler plates with micro-pores using MIM technology, as disclosed herein, can reduce the thermal resistance (Psi_cf) from a heat generating electronic component to an ambient fluid by approximately 25% relative to a traditional copper boiler plate with a BEC bonded thereto and by approximately 10% relative to a heat-pipe based boiler plate with a BEC. More particularly, testing at a thermal design power (TDP) of 270 W has shown that a standard copper boiler plate with a BEC exhibits a Psi_cf of approximately 0.056° C./W, whereas a MIM boiler plate with integrated protrusions (as shown in FIGS. 40 and 41) exhibits a Psi_cf of approximately 0.050° C./W. Further, at a TDP of 350 W, testing has shown that a standard copper boiler plate with a BEC exhibits a Psi_cf of approximately 0.055° C./W, whereas MIM boiler plate with integrated protrusions (as shown in FIGS. 40 and 41) exhibits a Psi_cf of approximately 0.049° C./W. This reduction in thermal resistance results in a reduction in junction temperature (Tⱼ) for a 350 W SKU of approximately 5° C. and enables a boost in performance of approximately 0.125 to 0.25 GHZ.

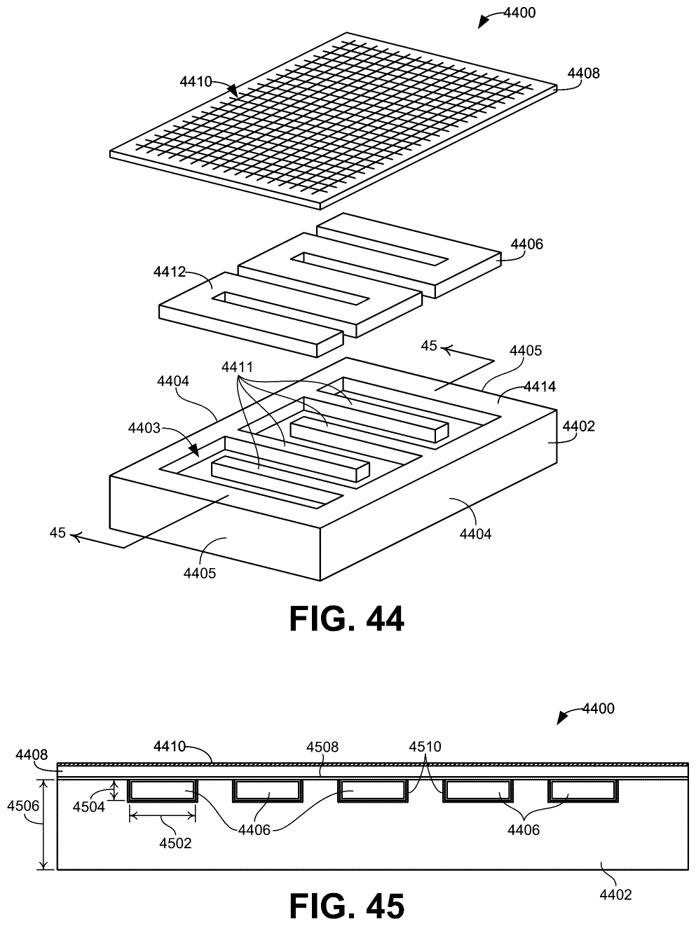

While traditional boiler plates composed of a solid piece of metal (e.g., copper) are thermally conductive, such boiler plates nevertheless have some appreciable thermal resistance. This thermal resistance is attributable to, at least in part, the relatively large mass of the solid boiler plate (e.g., more time is needed to fully heat the block). Unlike other known boiler plates that are implemented with a solid block or plate of metal, some example boiler plates disclosed herein include one or more heat pipes (e.g., a sealed tube containing a liquid) embedded inside. Specifically, FIG. 44 is an exploded view of an example boiler plate 4400 constructed in accordance with teachings disclosed herein to facilitate the cooling of a semiconductor chip (e.g., a silicon die) using two-phase immersion cooling. FIG. 45 is a cross-sectional view of the example boiler plate 4400 of FIG. 44 in an assembled form taken along the line 45-45 of FIG. 44. As shown in the illustrated example, the boiler plate 4400 includes a main body or base 4402 that includes an opening, track, groove, heat pipe bed, or recess 4403 into which an example heat pipe 4406 is disposed. In some examples, the base 4402 is made from a solid block or plate of thermally conductive material (e.g., copper and/or any other suitable metal) that has been cut, machined, or etched to provide the opening 4403. In other examples, the opening 4403 is integrally formed in the base 4402 during a single fabrication process (e.g., via metal injection molding, casting, etc.).

The example boiler plate 4400 further includes a lid 4408 to cover and/or enclose the heat pipe 4406 within the base 4402. In some examples, the lid 4408 is made of the same material (e.g., copper) as the base 4402 of the boiler plate 4400. In other examples, the lid 4408 and the base 4402 are made from different materials. In this example, the lid 4408 includes a boiler enhancing layer (BEL) 4410 on its exposed outer surface. In this examples, the BEL 4410 is made from a stacked array of metal (e.g., copper) meshes to provide irregularities that promote nucleate boiling on the outer surface of the boiler plate 4400. In other examples, the BEL 4410 is a boiling enhancement coating that includes granulated powder that provide irregularities to promote boiling. In other examples, the lid 4408 is fabricated using MIM technology (as discussed above in connection with FIGS. 40-43) to integrally include irregularities (e.g., micro-pores) that provide boiling enhancement without attachment of a separate material (e.g., a separate BEL) to base material of the lid 4408.

As shown in the illustrated examples, the opening 4403 in the base 4402 of the boiler plate 4400 is a groove that defines a path generally corresponding to the overall shape of the heat pipe 4406. In this example, the overall shape of the heat pipe 4406 defines a generally serpentine path. However, the heat pipe 4406 may follow any other suitable shape (e.g., straight, zig-zagged, circular, spiraled, etc.). In some examples, the particular shape of the path or track followed by the heat pipe 4406 depends on an expected orientation of the boiler plate 4400 relative to the direction of gravity when in use. For instance, in the illustrated example of FIG. 44, the corners or turns in the serpentine path of the heat pipe 4406 (at which the heat pipe 4406 reverses direction on itself) are positioned along lateral edges 4404 of the base 4402 rather than along the ends 4405 of the base 4402. In such examples, the elongate segments of the heat pipe 4406 between the corners or turns extend general transverse to the lateral edges 4404. In some such examples, the lateral edges 4404 are expected to be oriented in a substantially vertical direction with the ends at the top and bottom when in use. In some examples, the corners or turns of the heat pipe 4406 are positioned along the ends 4405 of the base 4402 such that elongate segments of the heat pipe between such corners extend transverse to the ends 4405. In other examples, the corners and/or the elongate segments between the corners can be position in at any suitable location and be oriented in any suitable manner relative to the direction of gravity when in use. Further, although the corners or turns in the heat pipe are shown at right angles, in other examples, the corners or turns may be at any other angle and/or may be rounded. In some examples, the path and/or shape of the heat pipe 4406 is structured so that portions 4411 of the base 4402 are able to extend through different portions of the heat pipe 4406, thereby maintaining the stiffness and/or rigidity of the boiler plate 4400, which may not be possible if the entire base 4402 was hollowed out to provide space for a planar vapor chamber.

In some examples, there may be more than one heat pipe 4406. In some such examples, different ones of the heat pipes 4406 may have different shapes and/or be oriented in different directions. In some examples, the heat pipe 4406 is made of a thermally conductive material. In some examples, the same thermally conductive material (e.g., copper) is used for both the heat pipe 4406 and the base 4402 of the boiler plate 4400. In other examples, different materials are used for the heat pipe 4406 and the base 4402.

As shown in the illustrated example of FIG. 45, the example heat pipe 4406 has a width dimension 4502 (e.g., parallel the primary plane of the base 4402) being greater than a depth dimension 4504 (in a direction associated with a thickness 4506 of the base 4402). In other examples, the depth dimension 4504 is greater than the width dimension 4502. In other examples, the width dimension 4502 is approximately equal to the depth dimension 4504. In this example, the depth dimension 4504 of the heat pipe 4406 is less than half the thickness 4506 of the base 4402. In other examples, the depth dimension 4504 is less than what is shown in FIG. 45. In other examples, the depth dimension 4504 is greater than what is shown in FIG. 45 (e.g., approximately half the thickness 4506, more than half the thickness 4506, etc.). In some examples, the opening 4403 extends all the way through the base 4402 and the depth dimension 4504 of the heat pipe 4406 extends all or substantially all the way through the opening 4403. Thus, in some examples, the depth dimension 4504 of the heat pipe 4406 is approximately the same as the thickness 4506 of the base 4402.

In some examples, the depth of the opening 4403 is approximately the same as the depth dimension 4504 of the heat pipe 4406 so that an upper (e.g., outer) surface 4412 of the heat pipe 4406 is positioned substantially flush with an upper (e.g., outer) surface 4414 of the base 4402 when the heat pipe 4406 is disposed within the opening 4403. As used herein, substantially flush means within 0.5 mm of exactly flush. Positioning the upper surfaces of the 4412, 4414 of the heat pipe 4406 and the base 4402 facilitates the thermal coupling of both the heat pipe 4406 and the base 4402 to the lid 4408 for improved heat transfer to the exterior surface of the boiler plate 4400 where the BEL 4410 is located. In other examples, the heat pipe 4406 is embedded within openings in the lower surface of the base 4402 (facing away from the lid 4408 in the illustrated example) such that the upper surface 4414 of the base 4402 is a single continuous surface without the opening 4403. In some such examples, the lid 4408 is omitted with the BEL 4410 attached directly to the upper surface of the base 4402. In some examples, multiple heat pipes are positioned within the boiler plate 4400 at different depths (e.g., so that the different heat pipes overlap one another). In some such examples, the base 4402 shown in FIG. 44 is a first base layer of the boiler plate 4400 and a second intermediate layer covers the heat pipe 4406 in the first base layer and includes a second opening to receive a second heat pipe, which is covered by the lid 4408. In other examples, the openings 4403 in the base 4402 has a depth sufficiently large to fit two (or more) heat pipes 4406 stacked on top of one another.

As shown in the illustrated example of FIG. 45, the example heat pipe 4406 has a rectangular cross-section. In other examples, the heat pipe 4406 can have any other cross-sectional shape (e.g., round, oval, triangular, square, etc.). In some examples, the heat pipe 4406 includes a generally round cross-section with a flat (e.g., planar) surface facing away from the main body to provide a flat surface with which the lid 4408 can bond to the heat pipe 4406, as noted above. In some examples, the lid 4408 is bonded to both the upper surface 4412 of the heat pipe 4406 and the upper surface 4414 of the base 4402 with a solder 4508 to fill in any gaps due to irregularities or unevenness across the surfaces 4412, 4414 to improve heat transfer across the interface. Further, in some examples, the heat pipe 4406 is bonded to the walls of the opening 4403 in the base 4402 with a separate solder 4510 to fill in any gaps between the two components for improved heat transfer. Thus, in some examples, there may be no need for the cross-sectional shape of the opening 4403 to be exactly the same as the cross-sectional shape of the heat pipe 4406. However, in some examples, the cross-sectional shape of the opening 4403 generally mirrors and/or is fit-up to the cross-sectional shape of the heat pipe 4406 to reduce the amount of solder to be used to connect the components and to help maintain stiffness of the overall assembly. In some examples, the heat pipe 4406 is bonded to the base 4402 before the lid 4408 is bonded to both the heat pipe 4406 and the base 4402. Accordingly, in some examples, the solder 4510 used between the heat pipe 4406 and the base 4402 is a higher temperature solder (e.g., has a higher melting point) than the solder 4508 used between the lid 4408 and the heat pipe 4406. In this manner, when the lid 4408 is bonded to the rest of the assembly, the bonding process will not melt the previously applied solder 4510 between the heat pipe 4406 and the base 4402.

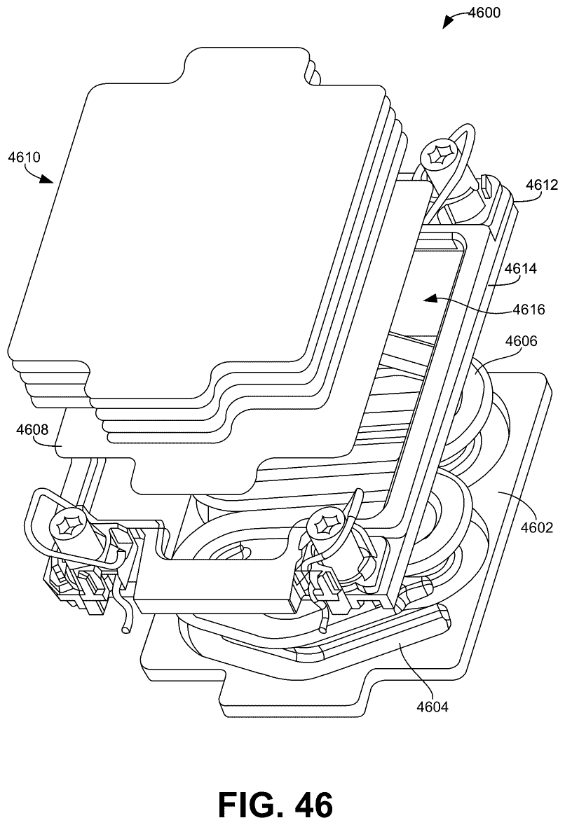

FIG. 46 is an exploded view of another example boiler plate constructed in accordance with teachings disclosed herein. As shown in the illustrated example, the boiler plate 4600 includes a main body or base 4602 that includes recesses or openings 4604 dimensioned to receive a heat pipe 4606. A lid 4608 is bonded to the base 4602 (and the heat pipe 4606) so as to seal off or enclose the heat pipe 4606 within the boiler plate 4600. Further, in this example, five layers of metal mesh 4610 are bonded to the exterior surface of the lid 4608 to serve as a boiling enhancement layer. In other examples, a different number of metal meshes can be used.

A loading frame 4612 is also shown in FIG. 46 relative to the components of the boiler plate. As shown in the illustrated example, the loading frame 4612 includes an outer rim 4614 surrounding a central opening 4616. When assembled, the outer rim 4614 of the loading frame 4612 interfaces with the outer perimeter of the upper surface of the base 4602 to apply a force on the boiler plate 4600 to urge the plate against an underlying electronic component (e.g., the outer surface of IHS 4010 enclosing the semiconductor die 4006 as shown in FIG. 40). The lid 4608 and the layers of metal mesh 4610 are dimensioned to fit within and extend through the central opening 4616 of the loading frame 4612.

Analytical modeling and experimental testing indicate that embedding a heat pipe within a boiler plate, as disclosed in the illustrated examples of FIGS. 44-46, can reduce the thermal resistance (Psi_cf) from a heat generating electronic component to an ambient fluid by approximately 14% relative to a traditional solid copper boiler plate. More particularly, testing shows a reduction from maximum and minimum thermal resistance (Psi_cf) for a standard solid copper boiler plate of approximately 0.057° C./W and 0.054° C./W across a TDP sweep from 200 W to 450 W down to maximum and minimum thermal resistance for a boiler plate with an embedded heat pipe (as shown in FIGS. 44-46) of approximately 0.050° C./W and 0.047° C./W. This reduction in thermal resistance results in a reduction in junction temperature (Tⱼ) for a 500 W SKU of approximately 4° C. and enables a boost in performance of approximately 0.125 to 0.25 GHz. The above advantages are achieved by utilizing two-phase cooling techniques enabled by the heat pipes 4406, 4606 embedded within the boiler plates 4400, 4600 of FIGS. 44-46. More particularly, the embedded heat pipes 4406, 4606 disclosed herein are partially filled with a cooling liquid and scaled off. As heat generated by an associated electronic component is transferred to the example boiler plates 4400, 4600, the heat causes the liquid within the embedded heat pipes 4406, 4606 to boil and change to the vapor phase. The resulting vapor subsequently condenses back to a liquid within the pipes (e.g., along an upper portion of the heat pipes 4406, 4606 in a direction opposite gravity where the cooling liquid pools when in liquid form) and transfers heat to associated portions of the base 4402, 4602, and/or lid 4408, 4608 of the boiler plates 4400, 4600. The condensate of the cooling fluid will then flow down (in the direction of gravity) to return and combine with the rest of the cooling fluid that is in the liquid phase within the heat pipe. This two-phase cooling process within the heat pipes 4406, 4606 (vaporization of the internal liquid followed by condensation of the vapor back into a liquid) transfers heat more efficiently than is possible by a solid boiler plate. Furthermore the replacement of solid metal within the example boiler plates 4400, 4600 with heat pipes 4406, 4606 also has the benefit of reducing the overall weight of the boiler plates 4400, 4600 and/or reducing the amount of raw materials needed to fabricate the boiler plates 4400, 4600.

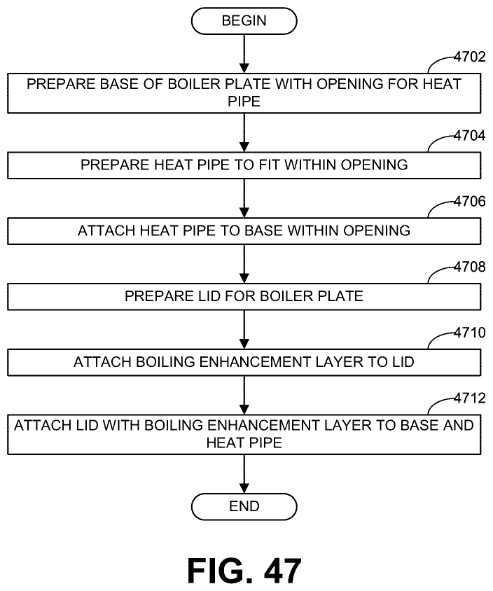

FIG. 47 is a flowchart illustrating an example method of manufacturing any one of the example boiler plates 4400, 4600 of FIGS. 44-46. For purposes of explanation, the flowchart of FIG. 4700 will be described with reference to the boiler plate 4400 of FIGS. 44 and 45. Although the example method of manufacture is described with reference to the flowchart illustrated in FIG. 47, many other methods may alternatively be used. For example, the order of execution of the blocks may be changed, and/or some of the blocks described may be combined, divided, re-arranged, omitted, eliminated, and/or implemented in any other way.

The example process begins at block 4702 by preparing the base 4402 of the boiler plate 4400 with an opening 4403 for the heat pipe 4406. In some examples, this is accomplished by cutting, machining, etching, or otherwise removing material from a metal plate to form the opening 4403. In other examples, MIM techniques and/or any other suitable method can be implemented to create the base 4402 with the opening 4403. At block 4704, the example process involves preparing the heat pipe 4406 to fit within the opening 4403. In some examples, block 4704 is implemented before and/or in parallel with block 4702. At block 4706, the example process involves attaching the heat pipe 4406 to the base 4402 within the opening 4403. In some examples, this is accomplished through the use of a solder 4510 (and an associated reflow process) positioned between the heat pipe 4406 and walls of the opening 4403.

At block 4708, the example process involves preparing the lid 4408 for the boiler plate 4400. In some examples the lid 4408 is a sheet of metal foil. At block 4710, the example process involves attaching the boiling enhancement layer (BEL) 4410 to the lid 4408. As described above, the BEL 4410 can be a boiling enhancing coating of powder or a stack of multiple layers of metal mesh. In some examples, when the stack of metal mesh layers are used, the layers are diffusion bonded with the lid 4408. In some examples, the lid 4408 is fabricated using MIM techniques with micro-pores that providing boiling nucleation sites such that a separate BEL does not need to be included. Thus, in some examples, block 4710 is omitted and/or incorporated into the processes associated with block 4708. Inasmuch as the lid 4408 and BEL 4410 are fabricated separately from the base 4402 and the heat pipe 4406, in some examples, blocks 4708, and 4710 can be performed prior to and/or in parallel with block 4702 and/or block 4704.

At block 4712, the example process involves attaching the lid 4408 with the BEL 4410 (or integrated micro-pores that serve the function of the BEL 4410) to the base 4402 and the heat pipe 4406. In some examples, this is accomplished through the use of a solder 4508 (and an associated reflow process) provided across the upper surfaces of the heat pipe 4406 and the base 4402. In some examples, the solder 4508 used at block 4712 is a lower temperature solder than the solder 4510 used at block 4706. In some examples, the attachment of the heat pipe 4406 to the base 4402 (block 4706) and the attachment of the lid 4408 to the base 4402 and the heat pipe 4406 (block 4712) are accomplished in a single process. In such examples, a single solder (e.g., cutectic Bi₅₈Sn₄₂) at all interfaces is used and the process is completed in a single reflow process. In some examples, the attachment of the BEL 4410 (block 4710) to the lid 4408 occurs after the attachment of the lid 4408 to the base 4402 and the heat pipe (block 4712). Once all components are assembled, the example process of FIG. 47 ends.

Any of the example boiler plates 4000, 4400, 4600 of FIGS. 40, 41, and 44-46 can be suitable adapted for use with any type of electronic component to be immersed in any one of the immersion cooling systems shown and described in FIGS. 1-39.

The flowchart of FIG. 3 is representative of example hardware logic circuitry, machine readable instructions, hardware implemented state machines, and/or any combination thereof for implementing the control system circuitry 224 of FIG. 2C. The flowchart of FIG. 13 is representative of example hardware logic circuitry, machine readable instructions, hardware implemented state machines, and/or any combination thereof for implementing the lock control circuitry 1130 of FIG. 12. The machine readable instructions may be one or more executable programs or portion(s) of an executable program for execution by processor circuitry, such as the processor circuitry 4812, 4912 shown in the example processor platforms 4800, 4900 discussed below in connection with FIGS. 48 and 49 and/or the example processor circuitry discussed below in connection with FIGS. 50 and/or 51. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowcharts illustrated in FIGS. 3 and 13, many other methods of implementing the example control system circuitry 224 and/or the example lock control circuitry 1130 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU), etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 3 and 13 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium and non-transitory computer readable storage medium are expressly defined to include any type of computer readable storage device and/or storage disk and to exclude propagating signals and to exclude transmission media.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 48 is a block diagram of an example processor platform 4800 structured to execute and/or instantiate the machine readable instructions and/or the operations of FIG. 3 to implement the control system circuitry 224 of FIG. 2C. The processor platform 4800 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing device.

The processor platform 4800 of the illustrated example includes processor circuitry 4812. The processor circuitry 4812 of the illustrated example is hardware. For example, the processor circuitry 4812 can be implemented by one or more integrated circuits, logic circuits, FPGAs, microprocessors, CPUs, GPUs, DSPs, and/or microcontrollers from any desired family or manufacturer. The processor circuitry 4812 may be implemented by one or more semiconductor based (e.g., silicon based) devices. In this example, the processor circuitry 4812 implements the example sensor data analysis circuitry 230 and the example device control circuitry 232.

The processor circuitry 4812 of the illustrated example includes a local memory 4813 (e.g., a cache, registers, etc.). The processor circuitry 4812 of the illustrated example is in communication with a main memory including a volatile memory 4814 and a non-volatile memory 4816 by a bus 4818. The volatile memory 4814 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 4816 may be implemented by flash memory and/or any other desired type of memory device. Access to the main memory 4814, 4816 of the illustrated example is controlled by a memory controller 4817.

The processor platform 4800 of the illustrated example also includes interface circuitry 4820. The interface circuitry 4820 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 4822 are connected to the interface circuitry 4820. The input device(s) 4822 permit(s) a user to enter data and/or commands into the processor circuitry 4812. The input device(s) 4822 can be implemented by, for example, an audio sensor, a microphone, a camera (still or video), a keyboard, a button, a mouse, a touchscreen, a track-pad, a trackball, an isopoint device, and/or a voice recognition system.

One or more output devices 4824 are also connected to the interface circuitry 4820 of the illustrated example. The output device(s) 4824 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 4820 of the illustrated example, thus, typically includes a graphics driver card, a graphics driver chip, and/or graphics processor circuitry such as a GPU.

The interface circuitry 4820 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 4826. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 4800 of the illustrated example also includes one or more mass storage devices 4828 to store software and/or data. Examples of such mass storage devices 4828 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine executable instructions 4832, which may be implemented by the machine readable instructions of FIG. 3, may be stored in the mass storage device 4828, in the volatile memory 4814, in the non-volatile memory 4816, and/or on a removable non-transitory computer readable storage medium such as a CD or DVD.

FIG. 49 is a block diagram of an example processor platform 4900 structured to execute and/or instantiate the machine readable instructions and/or the operations of FIG. 13 to implement the lock control circuitry 1130 of FIG. 12. The processor platform 4900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing device.

The processor platform 4900 of the illustrated example includes processor circuitry 4912. The processor circuitry 4812 of the illustrated example is hardware. For example, the processor circuitry 4912 can be implemented by one or more integrated circuits, logic circuits, FPGAs, microprocessors, CPUs, GPUs, DSPs, and/or microcontrollers from any desired family or manufacturer. The processor circuitry 4912 may be implemented by one or more semiconductor based (e.g., silicon based) devices. In this example, the processor circuitry 4912 implements the example display interface circuitry 1200, the example lock interface circuitry 1202, the example filtering circuitry 1204, the example dew point calculating circuitry 1206, the example monitoring circuitry 1208, the example access determining circuitry 1210, the example alert generating circuitry 1212, the example immersion cooling system component interface circuitry 1214, the example environmental device interface circuitry 1216, and the example timing circuitry 1218.

The processor circuitry 4912 of the illustrated example includes a local memory 4913 (e.g., a cache, registers, etc.). The processor circuitry 4912 of the illustrated example is in communication with a main memory including a volatile memory 4914 and a non-volatile memory 4916 by a bus 4918. The volatile memory 4914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 4916 may be implemented by flash memory and/or any other desired type of memory device. Access to the main memory 4914, 4916 of the illustrated example is controlled by a memory controller 4917.

The processor platform 4800 of the illustrated example also includes interface circuitry 4920. The interface circuitry 4920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 4922 are connected to the interface circuitry 4920. The input device(s) 4922 permit(s) a user to enter data and/or commands into the processor circuitry 4912. The input device(s) 4922 can be implemented by, for example, an audio sensor, a microphone, a camera (still or video), a keyboard, a button, a mouse, a touchscreen, a track-pad, a trackball, an isopoint device, and/or a voice recognition system.

One or more output devices 4924 are also connected to the interface circuitry 4920 of the illustrated example. The output device(s) 4924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 4920 of the illustrated example, thus, typically includes a graphics driver card, a graphics driver chip, and/or graphics processor circuitry such as a GPU.

The interface circuitry 4920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 4926. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 4900 of the illustrated example also includes one or more mass storage devices 4828 to store software and/or data. Examples of such mass storage devices 4828 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine executable instructions 4932, which may be implemented by the machine readable instructions of FIG. 13, may be stored in the mass storage device 4928, in the volatile memory 4914, in the non-volatile memory 4916, and/or on a removable non-transitory computer readable storage medium such as a CD or DVD.

FIG. 50 is a block diagram of an example implementation of the processor circuitry 4812 of FIG. 48 and/or the processor circuitry 4912 of FIG. 49. In this example, the processor circuitry 4812 of FIG. 48 and/or the processor circuitry 4912 of FIG. 49 is implemented by a general purpose microprocessor 5000. The general purpose microprocessor circuitry 5000 executes some or all of the machine readable instructions of the flowcharts of FIGS. 3 and/or 13 to effectively instantiate the circuitry of FIGS. 2C and/or 12 as logic circuits to perform the operations corresponding to those machine readable instructions. In some such examples, the circuitry of FIGS. 2C and/or 12 is instantiated by the hardware circuits of the microprocessor 5000 in combination with the instructions. For example, the microprocessor 5000 may implement multi-core hardware circuitry such as a CPU, a DSP, a GPU, an XPU, etc. Although it may include any number of example cores 5002 (e.g., 1 core), the microprocessor 5000 of this example is a multi-core semiconductor device including N cores. The cores 5002 of the microprocessor 5000 may operate independently or may cooperate to execute machine readable instructions. For example, machine code corresponding to a firmware program, an embedded software program, or a software program may be executed by one of the cores 5002 or may be executed by multiple ones of the cores 5002 at the same or different times. In some examples, the machine code corresponding to the firmware program, the embedded software program, or the software program is split into threads and executed in parallel by two or more of the cores 5002. The software program may correspond to a portion or all of the machine readable instructions and/or operations represented by the flowcharts of FIGS. 3 and/or 13.

The cores 5002 may communicate by a first example bus 5004. In some examples, the first bus 5004 may implement a communication bus to effectuate communication associated with one(s) of the cores 5002. For example, the first bus 5004 may implement at least one of an Inter-Integrated Circuit (I2C) bus, a Serial Peripheral Interface (SPI) bus, a PCI bus, or a PCIe bus. Additionally or alternatively, the first bus 5004 may implement any other type of computing or electrical bus. The cores 5002 may obtain data, instructions, and/or signals from one or more external devices by example interface circuitry 5006. The cores 5002 may output data, instructions, and/or signals to the one or more external devices by the interface circuitry 5006. Although the cores 5002 of this example include example local memory 5020 (e.g., Level 1 (L1) cache that may be split into an L1 data cache and an L1 instruction cache), the microprocessor 5000 also includes example shared memory 5010 that may be shared by the cores (e.g., Level 2 (L2_ cache)) for high-speed access to data and/or instructions. Data and/or instructions may be transferred (e.g., shared) by writing to and/or reading from the shared memory 5010. The local memory 5020 of each of the cores 5002 and the shared memory 5010 may be part of a hierarchy of storage devices including multiple levels of cache memory and the main memory (e.g., the main memory 4814, 4816 of FIG. 48; the main memory 4914, 4916 of FIG. 49). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 5002 may be referred to as a CPU, DSP, GPU, etc., or any other type of hardware circuitry. Each core 5002 includes control unit circuitry 5014, arithmetic and logic (AL) circuitry (sometimes referred to as an ALU) 5016, a plurality of registers 5018, the L1 cache 5020, and a second example bus 5022. Other structures may be present. For example, each core 5002 may include vector unit circuitry, single instruction multiple data (SIMD) unit circuitry, load/store unit (LSU) circuitry, branch/jump unit circuitry, floating-point unit (FPU) circuitry, etc. The control unit circuitry 5014 includes semiconductor-based circuits structured to control (e.g., coordinate) data movement within the corresponding core 5002. The AL circuitry 5016 includes semiconductor-based circuits structured to perform one or more mathematic and/or logic operations on the data within the corresponding core 5002. The AL circuitry 5016 of some examples performs integer based operations. In other examples, the AL circuitry 5016 also performs floating point operations. In yet other examples, the AL circuitry 5016 may include first AL circuitry that performs integer based operations and second AL circuitry that performs floating point operations. In some examples, the AL circuitry 5016 may be referred to as an Arithmetic Logic Unit (ALU). The registers 5018 are semiconductor-based structures to store data and/or instructions such as results of one or more of the operations performed by the AL circuitry 5016 of the corresponding core 5002. For example, the registers 5018 may include vector register(s), SIMD register(s), general purpose register(s), flag register(s), segment register(s), machine specific register(s), instruction pointer register(s), control register(s), debug register(s), memory management register(s), machine check register(s), etc. The registers 5018 may be arranged in a bank as shown in FIG. 50. Alternatively, the registers 5018 may be organized in any other arrangement, format, or structure including distributed throughout the core 5002 to shorten access time. The second bus 5022 may implement at least one of an 12C bus, a SPI bus, a PCI bus, or a PCIe bus

Each core 5002 and/or, more generally, the microprocessor 5000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 5000 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 51 is a block diagram of another example implementation of the processor circuitry 4812 of FIG. 48 and/or the processor circuitry 4912 of FIG. 49. In this example, the processor circuitry 4812 and/or the processor circuitry 4912 is implemented by FPGA circuitry 5100. The FPGA circuitry 5100 can be used, for example, to perform operations that could otherwise be performed by the example microprocessor 5000 of FIG. 50 executing corresponding machine readable instructions. However, once configured, the FPGA circuitry 5100 instantiates the machine readable instructions in hardware and, thus, can often execute the operations faster than they could be performed by a general purpose microprocessor executing the corresponding software.

More specifically, in contrast to the microprocessor 5000 of FIG. 50 described above (which is a general purpose device that may be programmed to execute some or all of the machine readable instructions represented by the flowcharts of FIGS. 3 and/or 13 but whose interconnections and logic circuitry are fixed once fabricated), the FPGA circuitry 5100 of the example of FIG. 51 includes interconnections and logic circuitry that may be configured and/or interconnected in different ways after fabrication to instantiate, for example, some or all of the machine readable instructions represented by the flowcharts of FIGS. 3 and/or 13. In particular, the FPGA 5100 may be thought of as an array of logic gates, interconnections, and switches. The switches can be programmed to change how the logic gates are interconnected by the interconnections, effectively forming one or more dedicated logic circuits (unless and until the FPGA circuitry 5100 is reprogrammed). The configured logic circuits enable the logic gates to cooperate in different ways to perform different operations on data received by input circuitry. Those operations may correspond to some or all of the software represented by the flowcharts of FIGS. 3 and/or 13. As such, the FPGA circuitry 5100 may be structured to effectively instantiate some or all of the machine readable instructions of the flowcharts of FIGS. 3 and/or 13 as dedicated logic circuits to perform the operations corresponding to those software instructions in a dedicated manner analogous to an ASIC. Therefore, the FPGA circuitry 5100 may perform the operations corresponding to the some or all of the machine readable instructions of FIGS. 3 and/or 13 faster than the general purpose microprocessor can execute the same.

In the example of FIG. 51, the FPGA circuitry 5100 is structured to be programmed (and/or reprogrammed one or more times) by an end user by a hardware description language (HDL) such as Verilog. The FPGA circuitry 5100 of FIG. 51, includes example input/output (I/O) circuitry 5102 to obtain and/or output data to/from example configuration circuitry 5104 and/or external hardware (e.g., external hardware circuitry) 5106. For example, the configuration circuitry 5104 may implement interface circuitry that may obtain machine readable instructions to configure the FPGA circuitry 5100, or portion(s) thereof. In some such examples, the configuration circuitry 5104 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 5106 may implement the microprocessor 5000 of FIG. 50. The FPGA circuitry 5100 also includes an array of example logic gate circuitry 5108, a plurality of example configurable interconnections 5110, and example storage circuitry 5112. The logic gate circuitry 5108 and interconnections 5110 are configurable to instantiate one or more operations that may correspond to at least some of the machine readable instructions of FIGS. 3 and/or 13 and/or other desired operations. The logic gate circuitry 5108 shown in FIG. 51 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 5108 to enable configuration of the electrical structures and/or the logic gates to form circuits to perform desired operations. The logic gate circuitry 5108 may include other electrical structures such as look-up tables (LUTs), registers (e.g., flip-flops or latches), multiplexers, etc.

The interconnections 5110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 5108 to program desired logic circuits.

The storage circuitry 5112 of the illustrated example is structured to store result(s) of the one or more of the operations performed by corresponding logic gates. The storage circuitry 5112 may be implemented by registers or the like. In the illustrated example, the storage circuitry 5112 is distributed amongst the logic gate circuitry 5108 to facilitate access and increase execution speed.

The example FPGA circuitry 5100 of FIG. 51 also includes example Dedicated Operations Circuitry 5114. In this example, the Dedicated Operations Circuitry 5114 includes special purpose circuitry 5116 that may be invoked to implement commonly used functions to avoid the need to program those functions in the field. Examples of such special purpose circuitry 5116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 5100 may also include example general purpose programmable circuitry 5118 such as an example CPU 5120 and/or an example DSP 5122. Other general purpose programmable circuitry 5118 may additionally or alternatively be present such as a GPU, an XPU, etc., that can be programmed to perform other operations.

Although FIGS. 50 and 51 illustrate two example implementations of the processor circuitry 4812 of FIG. 48 and/or the processor circuitry 4912 of FIG. 49, many other approaches are contemplated. For example, as mentioned above, modern FPGA circuitry may include an on-board CPU, such as one or more of the example CPU 5120 of FIG. 51. Therefore, the processor circuitry 4812 of FIG. 48 and/or the processor circuitry 4912 of FIG. 49 may additionally be implemented by combining the example microprocessor 5000 of FIG. 50 and the example FPGA circuitry 5100 of FIG. 51. In some such hybrid examples, a first portion of the machine readable instructions represented by the flowcharts of FIGS. 3 and/or 13 may be executed by one or more of the cores 5002 of FIG. 50, a second portion of the machine readable instructions represented by the flowcharts of FIGS. 3 and/or 13 may be executed by the FPGA circuitry 5100 of FIG. 51, and/or a third portion of the machine readable instructions represented by the flowcharts of FIGS. 3 and/or 13 may be executed by an ASIC. It should be understood that some or all of the circuitry of FIGS. 2C and 12 may, thus, be instantiated at the same or different times. Some or all of the circuitry may be instantiated, for example, in one or more threads executing concurrently and/or in series. Moreover, in some examples, some or all of the circuitry of FIGS. 2C and 12 may be implemented within one or more virtual machines and/or containers executing on the microprocessor.

In some examples, the processor circuitry 4812 of FIG. 48 and/or the processor circuitry 4912 of FIG. 49 may be in one or more packages. For example, the processor circuitry 5000 of FIG. 50 and/or the FPGA circuitry 5100 of FIG. 51 may be in one or more packages. In some examples, an XPU may be implemented by the processor circuitry 4812 of FIG. 48 and/or the processor circuitry 4912 of FIG. 49, which may be in one or more packages. For example, the XPU may include a CPU in one package, a DSP in another package, a GPU in yet another package, and an FPGA in still yet another package.

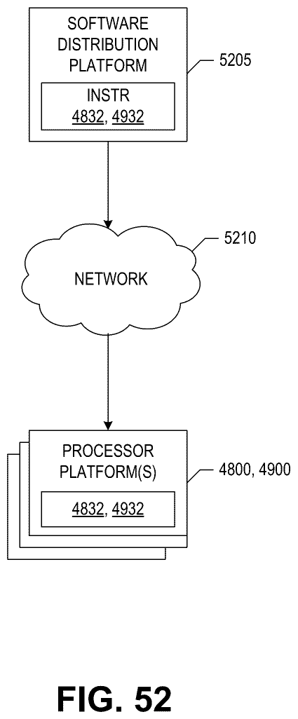

A block diagram illustrating an example software distribution platform 5205 to distribute software such as the example machine readable instructions 4832 of FIG. 48 and/or the example machine readable instructions 4932 of FIG. 49 to hardware devices owned and/or operated by third parties is illustrated in FIG. 52. The example software distribution platform 5205 may be implemented by any computer server, data facility, cloud service, etc., capable of storing and transmitting software to other computing devices. The third parties may be customers of the entity owning and/or operating the software distribution platform 5205. For example, the entity that owns and/or operates the software distribution platform 5205 may be a developer, a seller, and/or a licensor of software such as the example machine readable instructions 4832 of FIG. 48 and/or the example machine readable instructions 4932 of FIG. 49. The third parties may be consumers, users, retailers, OEMs, etc., who purchase and/or license the software for use and/or re-sale and/or sub-licensing. In the illustrated example, the software distribution platform 5205 includes one or more servers and one or more storage devices. The storage devices store the machine readable instructions 4832, which may correspond to the example machine readable instructions 300 of FIG. 3, as described above. The storage devices store the machine readable instructions 4932, which may correspond to the example machine readable instructions 1300 of FIG. 13, as described above. The one or more servers of the example software distribution platform 5205 are in communication with a network 5210, which may correspond to any one or more of the Internet and/or any of the example networks 4826, 4926 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 4832, 4932 from the software distribution platform 5205. For example, the software, which may correspond to the example machine readable instructions 4832 of FIG. 48, may be downloaded to the example processor platform 4800, which is to execute the machine readable instructions 4832 to implement the control system circuitry 224 of FIG. 2C. The software, which may correspond to the example machine readable instructions 4932 of FIG. 49, may be downloaded to the example processor platform 4900, which is to execute the machine readable instructions 4932 to implement the lock control circuitry 1130 of FIG. 12. In some example, one or more servers of the software distribution platform 5205 periodically offer, transmit, and/or force updates to the software (e.g., the example machine readable instructions 4832 of FIG. 48, the example machine readable instructions 4932 of FIG. 49) to ensure improvements, patches, updates, etc., are distributed and applied to the software at the end user devices.

While the concepts of the present disclosure are susceptible to various modifications and alternative forms, specific examples thereof have been shown by way of example in the drawings and described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one example,” “an example,” “an illustrative example,” etc., indicate that the example described may include a particular feature, structure, or characteristic, but every example may or may not necessarily include that particular feature, structure, or characteristic. Moreover, such phrases are not necessarily referring to the same example. Further, when a particular feature, structure, or characteristic is described in connection with an example, it is submitted that it is within the knowledge of one skilled in the art to effect such feature, structure, or characteristic in connection with other examples whether or not explicitly described.

In the drawings, some structural or method features may be shown in specific arrangements and/or orderings. However, it should be appreciated that such specific arrangements and/or orderings may not be required. Rather, in some examples, such features may be arranged in a different manner and/or order than shown in the illustrative figures. Additionally, the inclusion of a structural or method feature in a particular figure is not meant to imply that such feature is required in all examples and, in some examples, may not be included or may be combined with other features.

Referring now to FIG. 53, a data center 5300 in which disaggregated resources may cooperatively execute one or more workloads (e.g., applications on behalf of customers) includes multiple platforms 5310, 5320, 5330, 5340 (referred to herein as pods), each of which includes one or more rows of racks. Of course, although data center 5300 is shown with multiple pods, in some examples, the data center 5300 may be embodied as a single pod. As described in more detail herein, each rack houses multiple sleds, each of which may be primarily equipped with a particular type of resource (e.g., memory devices, data storage devices, accelerator devices, general purpose processors), i.e., resources that can be logically coupled to form a composed node, which can act as, for example, a server. In the illustrative example, the sleds in each pod 5310, 5320, 5330, 5340 are connected to multiple pod switches (e.g., switches that route data communications to and from sleds within the pod). The pod switches, in turn, connect with spine switches 5350 that switch communications among pods (e.g., the pods 5310, 5320, 5330, 5340) in the data center 5300. In some examples, the sleds may be connected with a fabric using Intel Omni-Path technology. In other examples, the sleds may be connected with other fabrics, such as InfiniBand or Ethernet. As described in more detail herein, resources within sleds in the data center 5300 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 5310, 5320, 5330, 5340. As such, some resources of a single sled may be allocated to one managed node while other resources of the same sled are allocated to a different managed node (e.g., one processor assigned to one managed node and another processor of the same sled assigned to a different managed node).

A data center comprising disaggregated resources, such as data center 5300, can be used in a wide variety of contexts, such as enterprise, government, cloud service provider, and communications service provider (e.g., Telco's), as well in a wide variety of sizes, from cloud service provider mega-data centers that consume over 5300,000 sq. ft. to single- or multi-rack installations for use in base stations.

The disaggregation of resources to sleds comprised predominantly of a single type of resource (e.g., compute sleds comprising primarily compute resources, memory sleds containing primarily memory resources), and the selective allocation and deallocation of the disaggregated resources to form a managed node assigned to execute a workload improves the operation and resource usage of the data center 5300 relative to typical data centers comprised of hyperconverged servers containing compute, memory, storage and perhaps additional resources in a single chassis. For example, because sleds predominantly contain resources of a particular type, resources of a given type can be upgraded independently of other resources. Additionally, because different resources types (processors, storage, accelerators, etc.) typically have different refresh rates, greater resource utilization and reduced total cost of ownership may be achieved. For example, a data center operator can upgrade the processors throughout their facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

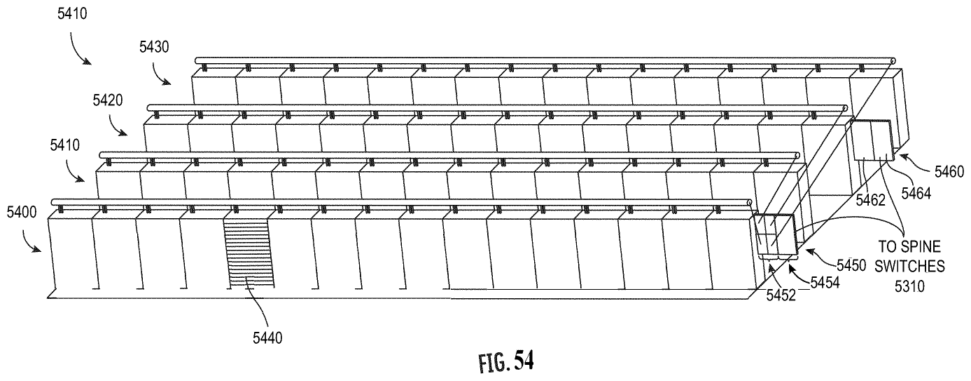

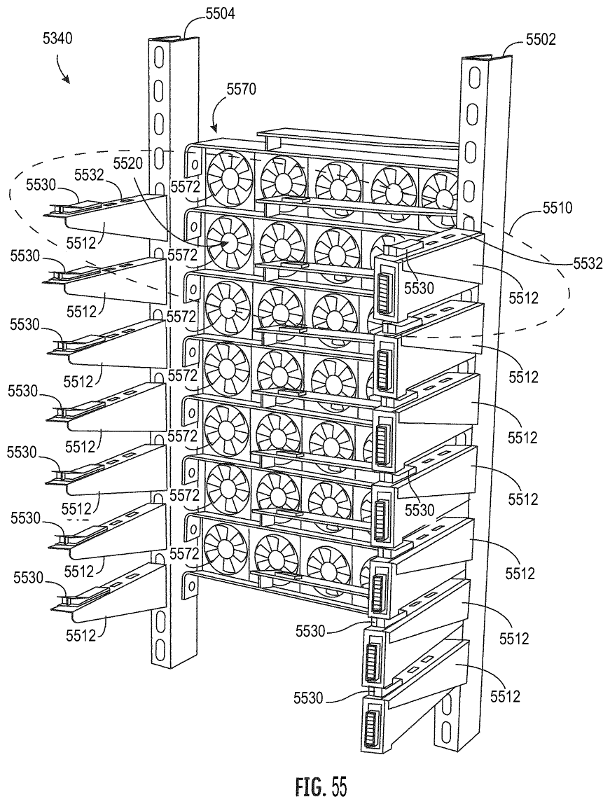

Referring now to FIG. 54, the pod 5310, in the illustrative example, includes a set of rows 5400, 5410, 5420, 5430 of racks 5440. Each rack 5440 may house multiple sleds (e.g., sixteen sleds) and provide power and data connections to the housed sleds, as described in more detail herein. In the illustrative example, the racks in each row 5400, 5410, 5420, 5430 are connected to multiple pod switches 5450, 5460. The pod switch 5450 includes a set of ports 5452 to which the sleds of the racks of the pod 5310 are connected and another set of ports 5454 that connect the pod 5310 to the spine switches 5350 to provide connectivity to other pods in the data center 5300. Similarly, the pod switch 5460 includes a set of ports 5462 to which the sleds of the racks of the pod 5310 are connected and a set of ports 5464 that connect the pod 5310 to the spine switches 5350. As such, the use of the pair of switches 5450, 5460 provides an amount of redundancy to the pod 5310. For example, if either of the switches 5450, 5460 fails, the sleds in the pod 5310 may still maintain data communication with the remainder of the data center 5300 (e.g., sleds of other pods) through the other switch 5450, 5460. Furthermore, in the illustrative example, the switches 5350, 5450, 5460 may be embodied as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that each of the other pods 5320, 5330, 5340 (as well as any additional pods of the data center 5300) may be similarly structured as, and have components similar to, the pod 5310 shown in and described in regard to FIG. 54 (e.g., each pod may have rows of racks housing multiple sleds as described above). Additionally, while two pod switches 5450, 5460 are shown, it should be understood that in other examples, each pod 5310, 5320, 5330, 5340 may be connected to a different number of pod switches, providing even more failover capacity. Of course, in other examples, pods may be arranged differently than the rows-of-racks configuration shown in FIGS. 53-54. For example, a pod may be embodied as multiple sets of racks in which each set of racks is arranged radially, i.e., the racks are equidistant from a center switch.

Referring now to FIGS. 55-57, each illustrative rack 5440 of the data center 5300 includes two elongated support posts 5502, 5504, which are arranged vertically. For example, the elongated support posts 5502, 5504 may extend upwardly from a floor of the data center 5300 when deployed. The rack 5440 also includes one or more horizontal pairs 5510 of elongated support arms 5512 (identified in FIG. 55 via a dashed ellipse) configured to support a sled of the data center 5300 as discussed below. One elongated support arm 5512 of the pair of elongated support arms 5512 extends outwardly from the elongated support post 5502 and the other elongated support arm 5512 extends outwardly from the elongated support post 5504.

In the illustrative examples, each sled of the data center 5300 is embodied as a chassis-less sled. That is, each sled has a chassis-less circuit board substrate on which physical resources (e.g., processors, memory, accelerators, storage, etc.) are mounted as discussed in more detail below. As such, the rack 5440 is configured to receive the chassis-less sleds. For example, each pair 5510 of elongated support arms 5512 defines a sled slot 5520 of the rack 5440, which is configured to receive a corresponding chassis-less sled. To do so, each illustrative elongated support arm 5512 includes a circuit board guide 5530 configured to receive the chassis-less circuit board substrate of the sled. Each circuit board guide 5530 is secured to, or otherwise mounted to, a top side 5532 of the corresponding elongated support arm 5512. For example, in the illustrative example, each circuit board guide 5530 is mounted at a distal end of the corresponding elongated support arm 5512 relative to the corresponding elongated support post 5502, 5504. For clarity of the Figures, not every circuit board guide 5530 may be referenced in each Figure.

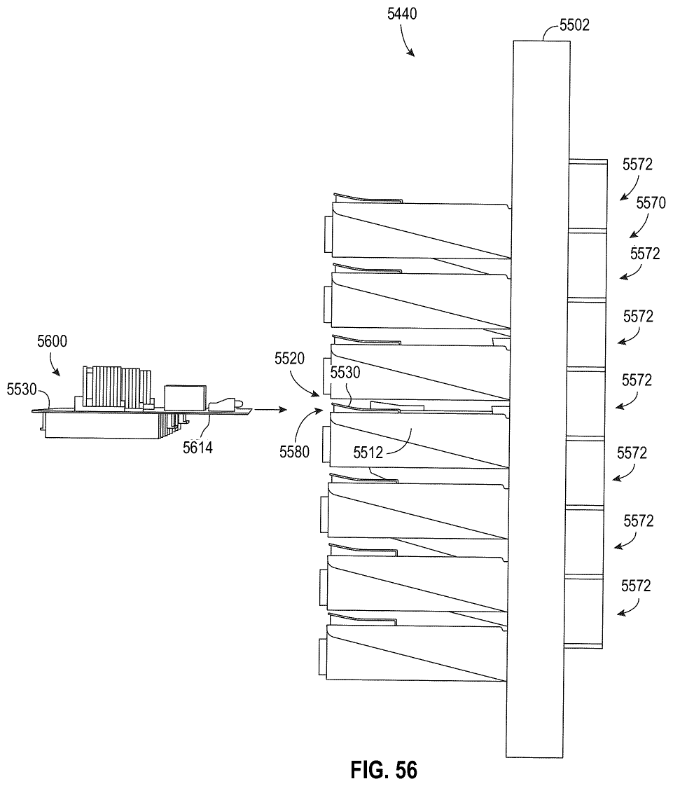

Each circuit board guide 5530 includes an inner wall that defines a circuit board slot 5580 configured to receive the chassis-less circuit board substrate of a sled 5600 when the sled 5600 is received in the corresponding sled slot 5520 of the rack 5440. To do so, as shown in FIG. 56, a user (or robot) aligns the chassis-less circuit board substrate of an illustrative chassis-less sled 5600 to a sled slot 5520. The user, or robot, may then slide the chassis-less circuit board substrate forward into the sled slot 5520 such that each side edge 5614 of the chassis-less circuit board substrate is received in a corresponding circuit board slot 5580 of the circuit board guides 5530 of the pair 5510 of elongated support arms 5512 that define the corresponding sled slot 5520 as shown in FIG. 56. By having robotically accessible and robotically manipulable sleds comprising disaggregated resources, each type of resource can be upgraded independently of each other and at their own optimized refresh rate. Furthermore, the sleds are configured to blindly mate with power and data communication cables in each rack 5440, enhancing their ability to be quickly removed, upgraded, reinstalled, and/or replaced. As such, in some examples, the data center 5300 may operate (e.g., execute workloads, undergo maintenance and/or upgrades, etc.) without human involvement on the data center floor. In other examples, a human may facilitate one or more maintenance or upgrade operations in the data center 5300.

It should be appreciated that each circuit board guide 5530 is dual sided. That is, each circuit board guide 5530 includes an inner wall that defines a circuit board slot 5580 on each side of the circuit board guide 5530. In this way, each circuit board guide 5530 can support a chassis-less circuit board substrate on either side. As such, a single additional elongated support post may be added to the rack 5440 to turn the rack 5440 into a two-rack solution that can hold twice as many sled slots 5520 as shown in FIG. 55. The illustrative rack 5440 includes seven pairs 5510 of elongated support arms 5512 that define a corresponding seven sled slots 5520, each configured to receive and support a corresponding sled 5600 as discussed above. Of course, in other examples, the rack 5440 may include additional or fewer pairs 5510 of elongated support arms 5512 (i.e., additional or fewer sled slots 5520). It should be appreciated that because the sled 5600 is chassis-less, the sled 5600 may have an overall height that is different than typical servers. As such, in some examples, the height of each sled slot 5520 may be shorter than the height of a typical server (e.g., shorter than a single rank unit, “1U”). That is, the vertical distance between each pair 5510 of elongated support arms 5512 may be less than a standard rack unit “1U.” Additionally, due to the relative decrease in height of the sled slots 5520, the overall height of the rack 5440 in some examples may be shorter than the height of traditional rack enclosures. For example, in some examples, each of the elongated support posts 5502, 5504 may have a length of six feet or less. Again, in other examples, the rack 5440 may have different dimensions. For example, in some examples, the vertical distance between each pair 5510 of elongated support arms 5512 may be greater than a standard rack until “1U”. In such examples, the increased vertical distance between the sleds allows for larger heat sinks to be attached to the physical resources and for larger fans to be used (e.g., in the fan array 5570 described below) for cooling each sled, which in turn can allow the physical resources to operate at increased power levels. Further, it should be appreciated that the rack 5440 does not include any walls, enclosures, or the like. Rather, the rack 5440 is an enclosure-less rack that is opened to the local environment. Of course, in some cases, an end plate may be attached to one of the elongated support posts 5502, 5504 in those situations in which the rack 5440 forms an end-of-row rack in the data center 5300.

In some examples, various interconnects may be routed upwardly or downwardly through the elongated support posts 5502, 5504. To facilitate such routing, each elongated support post 5502, 5504 includes an inner wall that defines an inner chamber in which interconnects may be located. The interconnects routed through the elongated support posts 5502, 5504 may be embodied as any type of interconnects including, but not limited to, data or communication interconnects to provide communication connections to each sled slot 5520, power interconnects to provide power to each sled slot 5520, and/or other types of interconnects.

The rack 5440, in the illustrative example, includes a support platform on which a corresponding optical data connector (not shown) is mounted. Each optical data connector is associated with a corresponding sled slot 5520 and is configured to mate with an optical data connector of a corresponding sled 5600 when the sled 5600 is received in the corresponding sled slot 5520. In some examples, optical connections between components (e.g., sleds, racks, and switches) in the data center 5300 are made with a blind mate optical connection. For example, a door on each cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 5440 also includes a fan array 5570 coupled to the cross-support arms of the rack 5440. The fan array 5570 includes one or more rows of cooling fans 5572, which are aligned in a horizontal line between the elongated support posts 5502, 5504. In the illustrative example, the fan array 5570 includes a row of cooling fans 5572 for each sled slot 5520 of the rack 5440. As discussed above, each sled 5600 does not include any on-board cooling system in the illustrative example and, as such, the fan array 5570 provides cooling for each sled 5600 received in the rack 5440. Each rack 5440, in the illustrative example, also includes a power supply associated with each sled slot 5520. Each power supply is secured to one of the elongated support arms 5512 of the pair 5510 of elongated support arms 5512 that define the corresponding sled slot 5520. For example, the rack 5440 may include a power supply coupled or secured to each elongated support arm 5512 extending from the elongated support post 5502. Each power supply includes a power connector configured to mate with a power connector of the sled 5600 when the sled 5600 is received in the corresponding sled slot 5520. In the illustrative example, the sled 5600 does not include any on-board power supply and, as such, the power supplies provided in the rack 5440 supply power to corresponding sleds 5600 when mounted to the rack 5440. Each power supply is configured to satisfy the power requirements for its associated sled, which can vary from sled to sled. Additionally, the power supplies provided in the rack 5440 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

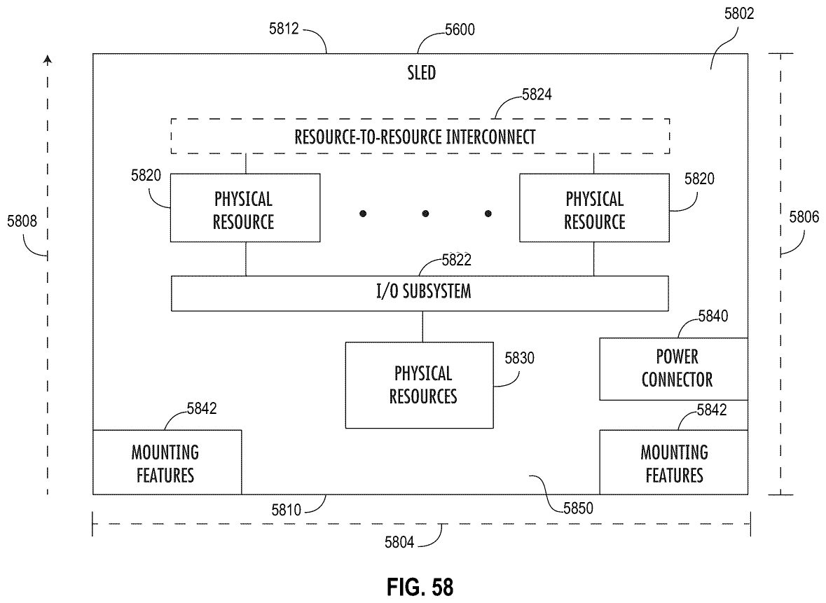

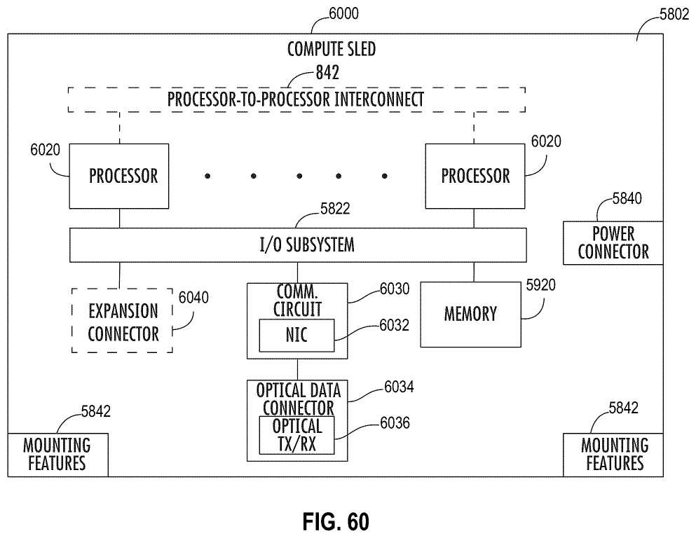

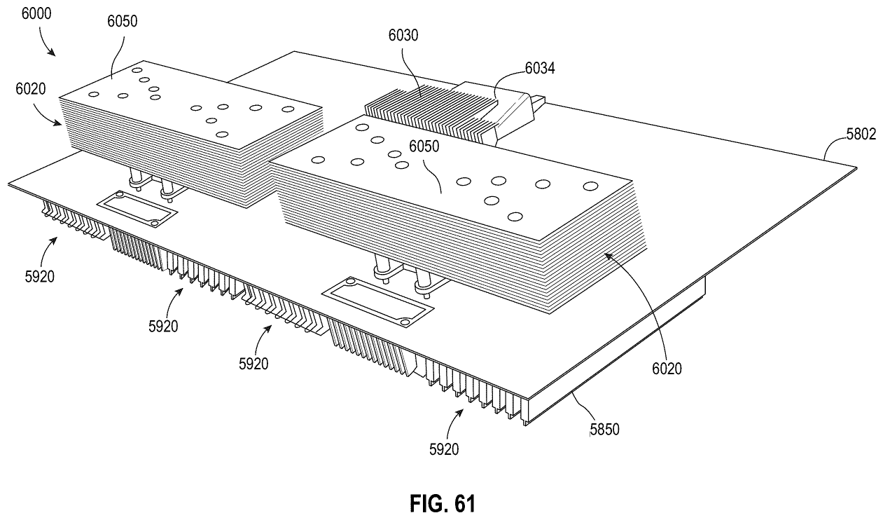

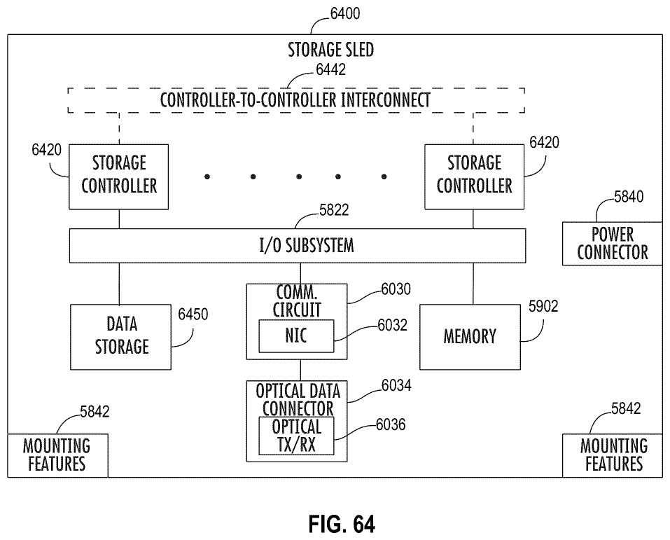

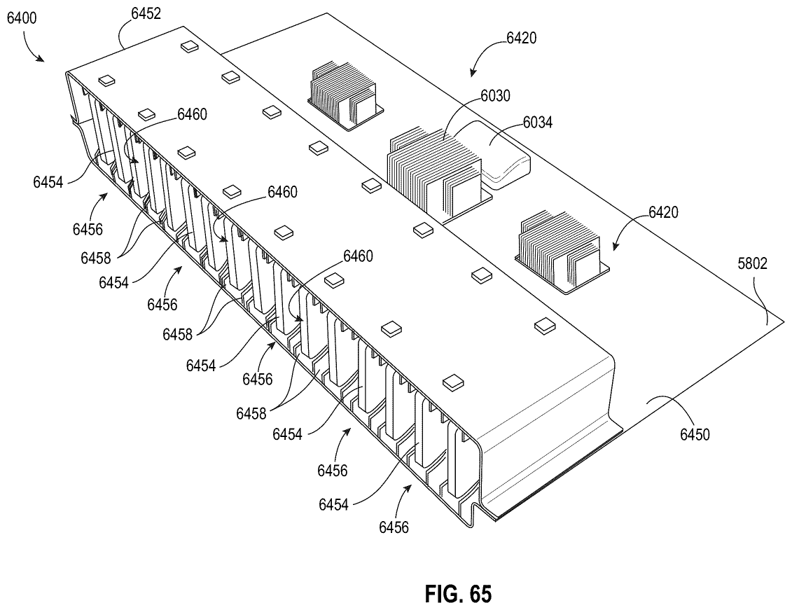

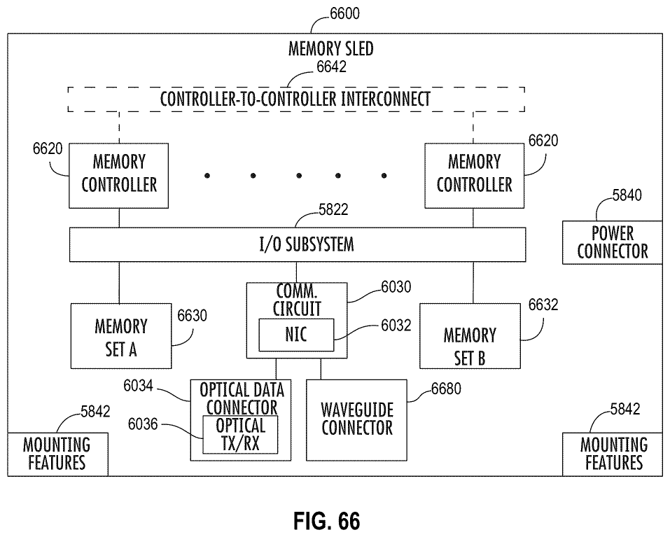

Referring now to FIG. 58, the sled 5600, in the illustrative example, is configured to be mounted in a corresponding rack 5440 of the data center 5300 as discussed above. In some examples, each sled 5600 may be optimized or otherwise configured for performing particular tasks, such as compute tasks, acceleration tasks, data storage tasks, etc. For example, the sled 5600 may be embodied as a compute sled 6000 as discussed below in regard to FIGS. 60-61, an accelerator sled 5200 as discussed below in regard to FIGS. 52-53, a storage sled 6400 as discussed below in regard to FIGS. 64-65, or as a sled optimized or otherwise configured to perform other specialized tasks, such as a memory sled 6600, discussed below in regard to FIG. 66.

As discussed above, the illustrative sled 5600 includes a chassis-less circuit board substrate 5802, which supports various physical resources (e.g., electrical components) mounted thereon. It should be appreciated that the circuit board substrate 5802 is “chassis-less” in that the sled 5600 does not include a housing or enclosure. Rather, the chassis-less circuit board substrate 5802 is open to the local environment. The chassis-less circuit board substrate 5802 may be formed from any material capable of supporting the various electrical components mounted thereon. For example, in an illustrative example, the chassis-less circuit board substrate 5802 is formed from an FR-4 glass-reinforced epoxy laminate material. Of course, other materials may be used to form the chassis-less circuit board substrate 5802 in other examples.

As discussed in more detail below, the chassis-less circuit board substrate 5802 includes multiple features that improve the thermal cooling characteristics of the various electrical components mounted on the chassis-less circuit board substrate 5802. As discussed, the chassis-less circuit board substrate 5802 does not include a housing or enclosure, which may improve the airflow over the electrical components of the sled 5600 by reducing those structures that may inhibit air flow. For example, because the chassis-less circuit board substrate 5802 is not positioned in an individual housing or enclosure, there is no vertically-arranged backplane (e.g., a backplate of the chassis) attached to the chassis-less circuit board substrate 5802, which could inhibit air flow across the electrical components. Additionally, the chassis-less circuit board substrate 5802 has a geometric shape configured to reduce the length of the airflow path across the electrical components mounted to the chassis-less circuit board substrate 5802. For example, the illustrative chassis-less circuit board substrate 5802 has a width 5804 that is greater than a depth 5806 of the chassis-less circuit board substrate 5802. In one particular example, the chassis-less circuit board substrate 5802 has a width of about 21 inches and a depth of about 9 inches, compared to a typical server that has a width of about 17 inches and a depth of about 39 inches. As such, an airflow path 5808 that extends from a front edge 5810 of the chassis-less circuit board substrate 5802 toward a rear edge 5812 has a shorter distance relative to typical servers, which may improve the thermal cooling characteristics of the sled 5600. Furthermore, although not illustrated in FIG. 58, the various physical resources mounted to the chassis-less circuit board substrate 5802 are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 5802 linearly in-line with each other along the direction of the airflow path 5808 (i.e., along a direction extending from the front edge 5810 toward the rear edge 5812 of the chassis-less circuit board substrate 5802).

As discussed above, the illustrative sled 5600 includes one or more physical resources 5820 mounted to a top side 5850 of the chassis-less circuit board substrate 5802. Although two physical resources 5820 are shown in FIG. 58, it should be appreciated that the sled 5600 may include one, two, or more physical resources 5820 in other examples. The physical resources 5820 may be embodied as any type of processor, controller, or other compute circuit capable of performing various tasks such as compute functions and/or controlling the functions of the sled 5600 depending on, for example, the type or intended functionality of the sled 5600. For example, as discussed in more detail below, the physical resources 5820 may be embodied as high-performance processors in examples in which the sled 5600 is embodied as a compute sled, as accelerator co-processors or circuits in examples in which the sled 5600 is embodied as an accelerator sled, storage controllers in examples in which the sled 5600 is embodied as a storage sled, or a set of memory devices in examples in which the sled 5600 is embodied as a memory sled.

The sled 5600 also includes one or more additional physical resources 5830 mounted to the top side 5850 of the chassis-less circuit board substrate 5802. In the illustrative example, the additional physical resources include a network interface controller (NIC) as discussed in more detail below. Of course, depending on the type and functionality of the sled 5600, the physical resources 5830 may include additional or other electrical components, circuits, and/or devices in other examples.

The physical resources 5820 are communicatively coupled to the physical resources 5830 via an input/output (I/O) subsystem 5822. The I/O subsystem 5822 may be embodied as circuitry and/or components to facilitate input/output operations with the physical resources 5820, the physical resources 5830, and/or other components of the sled 5600. For example, the I/O subsystem 5822 may be embodied as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 5822 is embodied as, or otherwise includes, a double data rate 56 (DDR4) data bus or a DDR5 data bus.

In some examples, the sled 5600 may also include a resource-to-resource interconnect 5824. The resource-to-resource interconnect 5824 may be embodied as any type of communication interconnect capable of facilitating resource-to-resource communications. In the illustrative example, the resource-to-resource interconnect 5824 is embodied as a high-speed point-to-point interconnect (e.g., faster than the I/O subsystem 5822). For example, the resource-to-resource interconnect 5824 may be embodied as a QuickPath Interconnect (QPI), an UltraPath Interconnect (UPI), or other high-speed point-to-point interconnect dedicated to resource-to-resource communications.

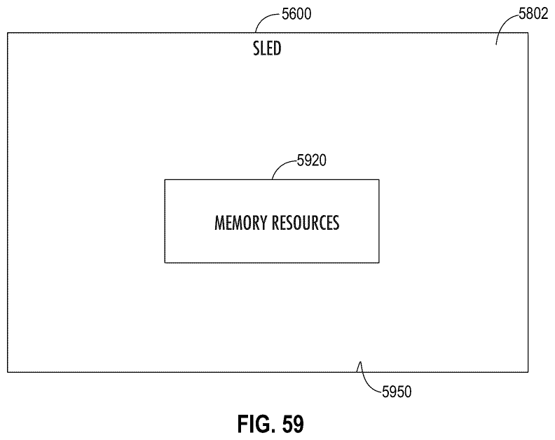

The sled 5600 also includes a power connector 5840 configured to mate with a corresponding power connector of the rack 5440 when the sled 5600 is mounted in the corresponding rack 5440. The sled 5600 receives power from a power supply of the rack 5440 via the power connector 5840 to supply power to the various electrical components of the sled 5600. That is, the sled 5600 does not include any local power supply (i.e., an on-board power supply) to provide power to the electrical components of the sled 5600. The exclusion of a local or on-board power supply facilitates the reduction in the overall footprint of the chassis-less circuit board substrate 5802, which may increase the thermal cooling characteristics of the various electrical components mounted on the chassis-less circuit board substrate 5802 as discussed above. In some examples, voltage regulators are placed on a bottom side 5950 (see FIG. 59) of the chassis-less circuit board substrate 5802 directly opposite of the processors 6020 (see FIG. 60), and power is routed from the voltage regulators to the processors 6020 by vias extending through the circuit board substrate 5802. Such a configuration provides an increased thermal budget, additional current and/or voltage, and better voltage control relative to typical printed circuit boards in which processor power is delivered from a voltage regulator, in part, by printed circuit traces.

In some examples, the sled 5600 may also include mounting features 5842 configured to mate with a mounting arm, or other structure, of a robot to facilitate the placement of the sled 5800 in a rack 5440 by the robot. The mounting features 5842 may be embodied as any type of physical structures that allow the robot to grasp the sled 5600 without damaging the chassis-less circuit board substrate 5802 or the electrical components mounted thereto. For example, in some examples, the mounting features 5842 may be embodied as non-conductive pads attached to the chassis-less circuit board substrate 5802. In other examples, the mounting features may be embodied as brackets, braces, or other similar structures attached to the chassis-less circuit board substrate 5802. The particular number, shape, size, and/or make-up of the mounting feature 5842 may depend on the design of the robot configured to manage the sled 5600.

Referring now to FIG. 59, in addition to the physical resources 5830 mounted on the top side 5850 of the chassis-less circuit board substrate 5802, the sled 5600 also includes one or more memory devices 5920 mounted to a bottom side 5950 of the chassis-less circuit board substrate 5802. That is, the chassis-less circuit board substrate 5802 is embodied as a double-sided circuit board. The physical resources 5820 are communicatively coupled to the memory devices 5920 via the I/O subsystem 5822. For example, the physical resources 5820 and the memory devices 5920 may be communicatively coupled by one or more vias extending through the chassis-less circuit board substrate 5802. Each physical resource 5820 may be communicatively coupled to a different set of one or more memory devices 5920 in some examples. Alternatively, in other examples, each physical resource 5820 may be communicatively coupled to each memory device 5920.

The memory devices 5920 may be embodied as any type of memory device capable of storing data for the physical resources 5820 during operation of the sled 5600, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may comprise a transistor-less stackable cross point architecture in which memory cells sit at the intersection of word lines and bit lines and are individually addressable and in which bit storage is based on a change in bulk resistance.

Referring now to FIG. 60, in some examples, the sled 5600 may be embodied as a compute sled 6000. The compute sled 6000 is optimized, or otherwise configured, to perform compute tasks. Of course, as discussed above, the compute sled 6000 may rely on other sleds, such as acceleration sleds and/or storage sleds, to perform such compute tasks. The compute sled 6000 includes various physical resources (e.g., electrical components) similar to the physical resources of the sled 5600, which have been identified in FIG. 60 using the same reference numbers. The description of such components provided above in regard to FIGS. 58 and 59 applies to the corresponding components of the compute sled 6000 and is not repeated herein for clarity of the description of the compute sled 6000.

In the illustrative compute sled 6000, the physical resources 5820 are embodied as processors 6020. Although only two processors 6020 are shown in FIG. 60, it should be appreciated that the compute sled 6000 may include additional processors 6020 in other examples. Illustratively, the processors 6020 are embodied as high-performance processors 6020 and may be configured to operate at a relatively high power rating. Although the processors 6020 generate additional heat operating at power ratings greater than typical processors (which operate at around 155-230 W), the enhanced thermal cooling characteristics of the chassis-less circuit board substrate 5802 discussed above facilitate the higher power operation. For example, in the illustrative example, the processors 6020 are configured to operate at a power rating of at least 5450 W. In some examples, the processors 6020 may be configured to operate at a power rating of at least 5550 W.

In some examples, the compute sled 6000 may also include a processor-to-processor interconnect 6042. Similar to the resource-to-resource interconnect 5824 of the sled 5600 discussed above, the processor-to-processor interconnect 6042 may be embodied as any type of communication interconnect capable of facilitating processor-to-processor interconnect 6042 communications. In the illustrative example, the processor-to-processor interconnect 6042 is embodied as a high-speed point-to-point interconnect (e.g., faster than the I/O subsystem 5822). For example, the processor-to-processor interconnect 6042 may be embodied as a QuickPath Interconnect (QPI), an UltraPath Interconnect (UPI), or other high-speed point-to-point interconnect dedicated to processor-to-processor communications.

The compute sled 6000 also includes a communication circuit 6030. The illustrative communication circuit 6030 includes a network interface controller (NIC) 6032, which may also be referred to as a host fabric interface (HFI). The NIC 6032 may be embodied as, or otherwise include, any type of integrated circuit, discrete circuits, controller chips, chipsets, add-in-boards, daughtercards, network interface cards, or other devices that may be used by the compute sled 6000 to connect with another compute device (e.g., with other sleds 5600). In some examples, the NIC 6032 may be embodied as part of a system-on-a-chip (SoC) that includes one or more processors, or included on a multichip package that also contains one or more processors. In some examples, the NIC 6032 may include a local processor (not shown) and/or a local memory (not shown) that are both local to the NIC 6032. In such examples, the local processor of the NIC 6032 may be capable of performing one or more of the functions of the processors 6020. Additionally or alternatively, in such examples, the local memory of the NIC 6032 may be integrated into one or more components of the compute sled at the board level, socket level, chip level, and/or other levels.

The communication circuit 6030 is communicatively coupled to an optical data connector 6034. The optical data connector 6034 is configured to mate with a corresponding optical data connector of the rack 5440 when the compute sled 6000 is mounted in the rack 5440. Illustratively, the optical data connector 6034 includes a plurality of optical fibers which lead from a mating surface of the optical data connector 6034 to an optical transceiver 6036. The optical transceiver 6036 is configured to convert incoming optical signals from the rack-side optical data connector to electrical signals and to convert electrical signals to outgoing optical signals to the rack-side optical data connector. Although shown as forming part of the optical data connector 6034 in the illustrative example, the optical transceiver 6036 may form a portion of the communication circuit 6030 in other examples.

In some examples, the compute sled 6000 may also include an expansion connector 6040. In such examples, the expansion connector 6040 is configured to mate with a corresponding connector of an expansion chassis-less circuit board substrate to provide additional physical resources to the compute sled 6000. The additional physical resources may be used, for example, by the processors 6020 during operation of the compute sled 6000. The expansion chassis-less circuit board substrate may be substantially similar to the chassis-less circuit board substrate 5802 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 61, an illustrative example of the compute sled 6000 is shown. As shown, the processors 6020, communication circuit 6030, and optical data connector 6034 are mounted to the top side 5850 of the chassis-less circuit board substrate 5802. Any suitable attachment or mounting technology may be used to mount the physical resources of the compute sled 6000 to the chassis-less circuit board substrate 5802. For example, the various physical resources may be mounted in corresponding sockets (e.g., a processor socket), holders, or brackets. In some cases, some of the electrical components may be directly mounted to the chassis-less circuit board substrate 5802 via soldering or similar techniques.

As discussed above, the individual processors 6020 and communication circuit 6030 are mounted to the top side 5850 of the chassis-less circuit board substrate 5802 such that no two heat-producing, electrical components shadow each other. In the illustrative example, the processors 6020 and communication circuit 6030 are mounted in corresponding locations on the top side 5850 of the chassis-less circuit board substrate 5802 such that no two of those physical resources are linearly in-line with others along the direction of the airflow path 5808. It should be appreciated that, although the optical data connector 6034 is in-line with the communication circuit 6030, the optical data connector 6034 produces no or nominal heat during operation.

The memory devices 5920 of the compute sled 6000 are mounted to the bottom side 5950 of the of the chassis-less circuit board substrate 5802 as discussed above in regard to the sled 5600. Although mounted to the bottom side 5950, the memory devices 5920 are communicatively coupled to the processors 6020 located on the top side 5850 via the I/O subsystem 5822. Because the chassis-less circuit board substrate 5802 is embodied as a double-sided circuit board, the memory devices 5920 and the processors 6020 may be communicatively coupled by one or more vias, connectors, or other mechanisms extending through the chassis-less circuit board substrate 5802. Of course, each processor 6020 may be communicatively coupled to a different set of one or more memory devices 5920 in some examples. Alternatively, in other examples, each processor 6020 may be communicatively coupled to each memory device 5920. In some examples, the memory devices 5920 may be mounted to one or more memory mezzanines on the bottom side of the chassis-less circuit board substrate 5802 and may interconnect with a corresponding processor 6020 through a ball-grid array.

Each of the processors 6020 includes a heat sink 6050 secured thereto. Due to the mounting of the memory devices 5920 to the bottom side 5950 of the chassis-less circuit board substrate 5802 (as well as the vertical spacing of the sleds 5600 in the corresponding rack 5440), the top side 5850 of the chassis-less circuit board substrate 5802 includes additional “free” area or space that facilitates the use of heat sinks 6050 having a larger size relative to traditional heat sinks used in typical servers. Additionally, due to the improved thermal cooling characteristics of the chassis-less circuit board substrate 5802, none of the processor heat sinks 6050 include cooling fans attached thereto. That is, each of the heat sinks 6050 is embodied as a fan-less heat sink. In some examples, the heat sinks 6050 mounted atop the processors 6020 may overlap with the heat sink attached to the communication circuit 6030 in the direction of the airflow path 5808 due to their increased size, as illustratively suggested by FIG. 61.

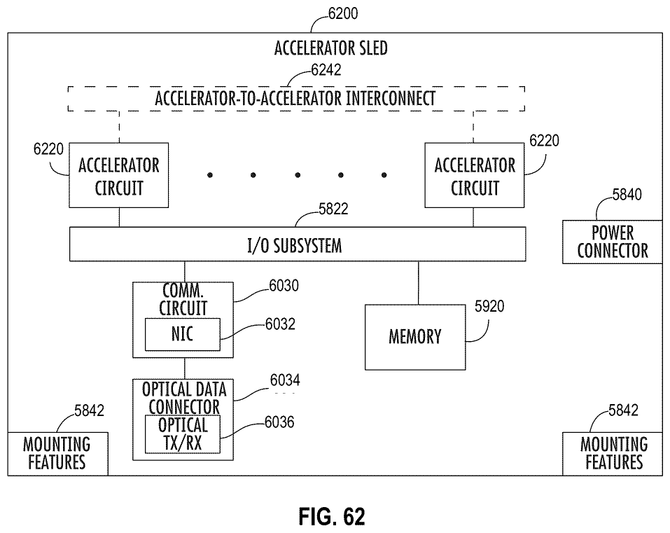

Referring now to FIG. 62, in some examples, the sled 5600 may be embodied as an accelerator sled 6200. The accelerator sled 6200 is configured, to perform specialized compute tasks, such as machine learning, encryption, hashing, or other computational-intensive task. In some examples, for example, a compute sled 6000 may offload tasks to the accelerator sled 6200 during operation. The accelerator sled 6200 includes various components similar to components of the sled 5600 and/or compute sled 6000, which have been identified in FIG. 62 using the same reference numbers. The description of such components provided above in regard to FIGS. 58, 59, and 60 apply to the corresponding components of the accelerator sled 6200 and is not repeated herein for clarity of the description of the accelerator sled 6200.

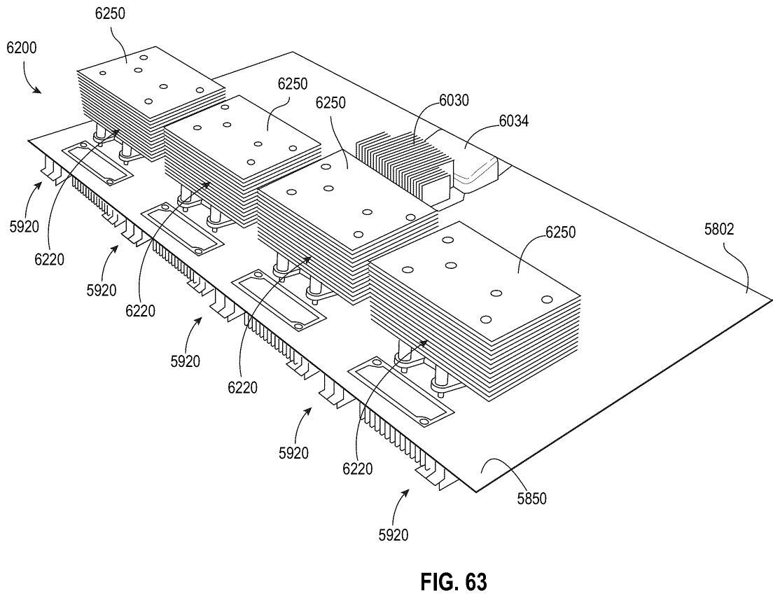

In the illustrative accelerator sled 6200, the physical resources 5820 are embodied as accelerator circuits 6220. Although only two accelerator circuits 6220 are shown in FIG. 62, it should be appreciated that the accelerator sled 6200 may include additional accelerator circuits 6220 in other examples. For example, as shown in FIG. 63, the accelerator sled 6200 may include four accelerator circuits 6220 in some examples. The accelerator circuits 6220 may be embodied as any type of processor, co-processor, compute circuit, or other device capable of performing compute or processing operations. For example, the accelerator circuits 6220 may be embodied as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 6200 may also include an accelerator-to-accelerator interconnect 6242. Similar to the resource-to-resource interconnect 5824 of the sled 5800 discussed above, the accelerator-to-accelerator interconnect 6242 may be embodied as any type of communication interconnect capable of facilitating accelerator-to-accelerator communications. In the illustrative example, the accelerator-to-accelerator interconnect 6242 is embodied as a high-speed point-to-point interconnect (e.g., faster than the I/O subsystem 5822). For example, the accelerator-to-accelerator interconnect 6242 may be embodied as a QuickPath Interconnect (QPI), an UltraPath Interconnect (UPI), or other high-speed point-to-point interconnect dedicated to processor-to-processor communications. In some examples, the accelerator circuits 6220 may be daisy-chained with a primary accelerator circuit 6220 connected to the NIC 6032 and memory 5920 through the I/O subsystem 5822 and a secondary accelerator circuit 6220 connected to the NIC 6032 and memory 5920 through a primary accelerator circuit 6220.

Referring now to FIG. 63, an illustrative example of the accelerator sled 6200 is shown. As discussed above, the accelerator circuits 6220, communication circuit 6030, and optical data connector 6034 are mounted to the top side 5850 of the chassis-less circuit board substrate 5802. Again, the individual accelerator circuits 6220 and communication circuit 6030 are mounted to the top side 5850 of the chassis-less circuit board substrate 5802 such that no two heat-producing, electrical components shadow each other as discussed above. The memory devices 5920 of the accelerator sled 6200 are mounted to the bottom side 5950 of the of the chassis-less circuit board substrate 5802 as discussed above in regard to the sled 5800. Although mounted to the bottom side 5950, the memory devices 5920 are communicatively coupled to the accelerator circuits 6220 located on the top side 5850 via the I/O subsystem 5822 (e.g., through vias). Further, each of the accelerator circuits 6220 may include a heat sink 6270 that is larger than a traditional heat sink used in a server. As discussed above with reference to the heat sinks 6070, the heat sinks 6270 may be larger than traditional heat sinks because of the “free” area provided by the memory resources 5920 being located on the bottom side 5950 of the chassis-less circuit board substrate 5802 rather than on the top side 5850.

Referring now to FIG. 64, in some examples, the sled 5600 may be embodied as a storage sled 6400. The storage sled 6400 is configured, to store data in a data storage 6450 local to the storage sled 6400. For example, during operation, a compute sled 6000 or an accelerator sled 6200 may store and retrieve data from the data storage 6450 of the storage sled 6400. The storage sled 6400 includes various components similar to components of the sled 5600 and/or the compute sled 6000, which have been identified in FIG. 64 using the same reference numbers. The description of such components provided above in regard to FIGS. 58, 59, and 60 apply to the corresponding components of the storage sled 6400 and is not repeated herein for clarity of the description of the storage sled 6400.

In the illustrative storage sled 6400, the physical resources 5820 are embodied as storage controllers 6420. Although only two storage controllers 6420 are shown in FIG. 64, it should be appreciated that the storage sled 6400 may include additional storage controllers 6420 in other examples. The storage controllers 6420 may be embodied as any type of processor, controller, or control circuit capable of controlling the storage and retrieval of data into the data storage 6450 based on requests received via the communication circuit 6030. In the illustrative example, the storage controllers 6420 are embodied as relatively low-power processors or controllers. For example, in some examples, the storage controllers 6420 may be configured to operate at a power rating of about 75 watts.

In some examples, the storage sled 6400 may also include a controller-to-controller interconnect 6442. Similar to the resource-to-resource interconnect 5824 of the sled 5600 discussed above, the controller-to-controller interconnect 6442 may be embodied as any type of communication interconnect capable of facilitating controller-to-controller communications. In the illustrative example, the controller-to-controller interconnect 6442 is embodied as a high-speed point-to-point interconnect (e.g., faster than the I/O subsystem 5822). For example, the controller-to-controller interconnect 6442 may be embodied as a QuickPath Interconnect (QPI), an UltraPath Interconnect (UPI), or other high-speed point-to-point interconnect dedicated to processor-to-processor communications.

Referring now to FIG. 65, an illustrative example of the storage sled 6400 is shown. In the illustrative example, the data storage 6450 is embodied as, or otherwise includes, a storage cage 6452 configured to house one or more solid state drives (SSDs) 6454. To do so, the storage cage 6452 includes a number of mounting slots 6456, each of which is configured to receive a corresponding solid state drive 6454. Each of the mounting slots 6456 includes a number of drive guides 6458 that cooperate to define an access opening 6460 of the corresponding mounting slot 6456. The storage cage 6452 is secured to the chassis-less circuit board substrate 5802 such that the access openings face away from (i.e., toward the front of) the chassis-less circuit board substrate 5802. As such, solid state drives 6454 are accessible while the storage sled 6400 is mounted in a corresponding rack 5404. For example, a solid state drive 6454 may be swapped out of a rack 5440 (e.g., via a robot) while the storage sled 6400 remains mounted in the corresponding rack 5440.

The storage cage 6452 illustratively includes sixteen mounting slots 6456 and is capable of mounting and storing sixteen solid state drives 6454. Of course, the storage cage 6452 may be configured to store additional or fewer solid state drives 6454 in other examples. Additionally, in the illustrative example, the solid state drivers are mounted vertically in the storage cage 6452, but may be mounted in the storage cage 6452 in a different orientation in other examples. Each solid state drive 6454 may be embodied as any type of data storage device capable of storing long term data. To do so, the solid state drives 6454 may include volatile and non-volatile memory devices discussed above.

As shown in FIG. 65, the storage controllers 6420, the communication circuit 6030, and the optical data connector 6034 are illustratively mounted to the top side 5850 of the chassis-less circuit board substrate 5802. Again, as discussed above, any suitable attachment or mounting technology may be used to mount the electrical components of the storage sled 6400 to the chassis-less circuit board substrate 5802 including, for example, sockets (e.g., a processor socket), holders, brackets, soldered connections, and/or other mounting or securing techniques.

As discussed above, the individual storage controllers 6420 and the communication circuit 6030 are mounted to the top side 5850 of the chassis-less circuit board substrate 5802 such that no two heat-producing, electrical components shadow each other. For example, the storage controllers 6420 and the communication circuit 6030 are mounted in corresponding locations on the top side 5850 of the chassis-less circuit board substrate 5802 such that no two of those electrical components are linearly in-line with each other along the direction of the airflow path 5808.

The memory devices 5920 of the storage sled 6400 are mounted to the bottom side 5950 of the of the chassis-less circuit board substrate 5802 as discussed above in regard to the sled 5600. Although mounted to the bottom side 5950, the memory devices 5920 are communicatively coupled to the storage controllers 6420 located on the top side 5850 via the I/O subsystem 5822. Again, because the chassis-less circuit board substrate 5802 is embodied as a double-sided circuit board, the memory devices 5920 and the storage controllers 6420 may be communicatively coupled by one or more vias, connectors, or other mechanisms extending through the chassis-less circuit board substrate 5802. Each of the storage controllers 6420 includes a heat sink 6470 secured thereto. As discussed above, due to the improved thermal cooling characteristics of the chassis-less circuit board substrate 5802 of the storage sled 6400, none of the heat sinks 6470 include cooling fans attached thereto. That is, each of the heat sinks 6470 is embodied as a fan-less heat sink.

Referring now to FIG. 66, in some examples, the sled 5600 may be embodied as a memory sled 6600. The storage sled 6600 is optimized, or otherwise configured, to provide other sleds 5600 (e.g., compute sleds 6000, accelerator sleds 6200, etc.) with access to a pool of memory (e.g., in two or more sets 6630, 6632 of memory devices 5920) local to the memory sled 6400. For example, during operation, a compute sled 6000 or an accelerator sled 6200 may remotely write to and/or read from one or more of the memory sets 6630, 6632 of the memory sled 6400 using a logical address space that maps to physical addresses in the memory sets 6630, 6632. The memory sled 6600 includes various components similar to components of the sled 5600 and/or the compute sled 6000, which have been identified in FIG. 66 using the same reference numbers. The description of such components provided above in regard to FIGS. 58, 59, and 60 apply to the corresponding components of the memory sled 6600 and is not repeated herein for clarity of the description of the memory sled 6600.

In the illustrative memory sled 6600, the physical resources 5820 are embodied as memory controllers 6620. Although only two memory controllers 6620 are shown in FIG. 66, it should be appreciated that the memory sled 6600 may include additional memory controllers 6620 in other examples. The memory controllers 6620 may be embodied as any type of processor, controller, or control circuit capable of controlling the writing and reading of data into the memory sets 6630, 6632 based on requests received via the communication circuit 6030. In the illustrative example, each memory controller 6620 is connected to a corresponding memory set 6630, 6632 to write to and read from memory devices 5920 within the corresponding memory set 6630, 6632 and enforce any permissions (e.g., read, write, etc.) associated with sled 5600 that has sent a request to the memory sled 6600 to perform a memory access operation (e.g., read or write).

In some examples, the memory sled 6600 may also include a controller-to-controller interconnect 6642. Similar to the resource-to-resource interconnect 5824 of the sled 5600 discussed above, the controller-to-controller interconnect 6642 may be embodied as any type of communication interconnect capable of facilitating controller-to-controller communications. In the illustrative example, the controller-to-controller interconnect 6642 is embodied as a high-speed point-to-point interconnect (e.g., faster than the I/O subsystem 5822). For example, the controller-to-controller interconnect 6642 may be embodied as a QuickPath Interconnect (QPI), an UltraPath Interconnect (UPI), or other high-speed point-to-point interconnect dedicated to processor-to-processor communications. As such, in some examples, a memory controller 6620 may access, through the controller-to-controller interconnect 6642, memory that is within the memory set 6632 associated with another memory controller 6620. In some examples, a scalable memory controller is made of multiple smaller memory controllers, referred to herein as “chiplets”, on a memory sled (e.g., the memory sled 6600). The chiplets may be interconnected (e.g., using EMIB (Embedded Multi-Die Interconnect Bridge)). The combined chiplet memory controller may scale up to a relatively large number of memory controllers and I/O ports, (e.g., up to 16 memory channels). In some examples, the memory controllers 6620 may implement a memory interleave (e.g., one memory address is mapped to the memory set 6630, the next memory address is mapped to the memory set 6632, and the third address is mapped to the memory set 6630, etc.). The interleaving may be managed within the memory controllers 6620, or from CPU sockets (e.g., of the compute sled 6000) across network links to the memory sets 6630, 6632, and may improve the latency associated with performing memory access operations as compared to accessing contiguous memory addresses from the same memory device.

Further, in some examples, the memory sled 6600 may be connected to one or more other sleds 5600 (e.g., in the same rack 5440 or an adjacent rack 5440) through a waveguide, using the waveguide connector 6680. In the illustrative example, the waveguides are 584 millimeter waveguides that provide 16 Rx (i.e., receive) lanes and 16 Tx (i.e., transmit) lanes. Each lane, in the illustrative example, is either 16 GHz or 32 GHz. In other examples, the frequencies may be different. Using a waveguide may provide high throughput access to the memory pool (e.g., the memory sets 6630, 6632) to another sled (e.g., a sled 5600 in the same rack 5440 or an adjacent rack 5440 as the memory sled 6600) without adding to the load on the optical data connector 6034.

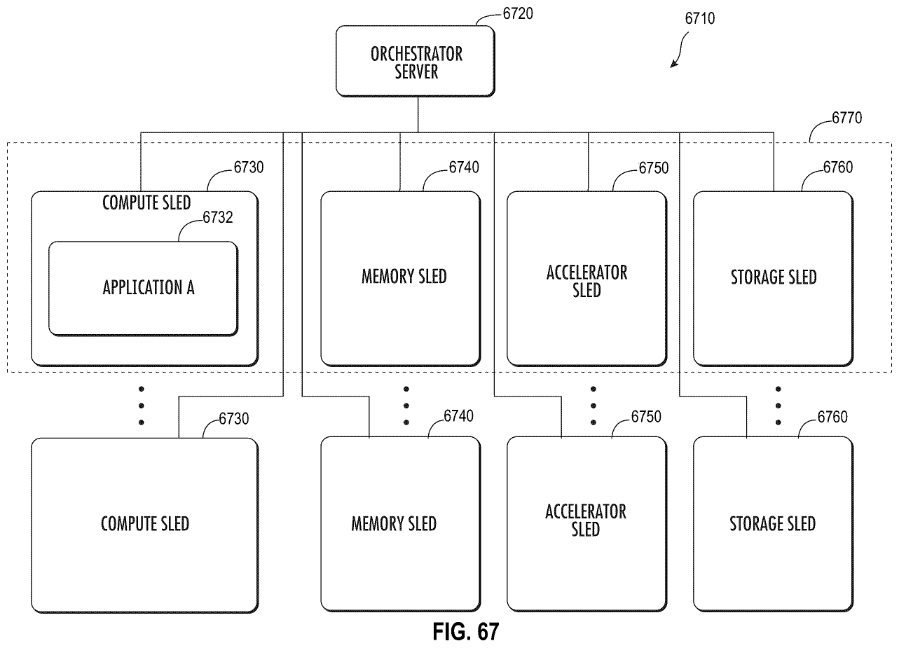

Referring now to FIG. 67, a system for executing one or more workloads (e.g., applications) may be implemented in accordance with the data center 5300. In the illustrative example, the system 6710 includes an orchestrator server 6720, which may be embodied as a managed node comprising a compute device (e.g., a processor 6020 on a compute sled 6000) executing management software (e.g., a cloud operating environment, such as OpenStack) that is communicatively coupled to multiple sleds 5600 including a large number of compute sleds 6730 (e.g., each similar to the compute sled 6000), memory sleds 6740 (e.g., each similar to the memory sled 6600), accelerator sleds 6750 (e.g., each similar to the memory sled 1000), and storage sleds 6760 (e.g., each similar to the storage sled 6400). One or more of the sleds 6730, 6740, 6750, 6760 may be grouped into a managed node 6770, such as by the orchestrator server 6720, to collectively perform a workload (e.g., an application 6732 executed in a virtual machine or in a container). The managed node 6770 may be embodied as an assembly of physical resources 5820, such as processors 6020, memory resources 5920, accelerator circuits 6220, or data storage 6450, from the same or different sleds 5600. Further, the managed node may be established, defined, or “spun up” by the orchestrator server 6720 at the time a workload is to be assigned to the managed node or at any other time, and may exist regardless of whether any workloads are presently assigned to the managed node. In the illustrative example, the orchestrator server 6720 may selectively allocate and/or deallocate physical resources 5820 from the sleds 5600 and/or add or remove one or more sleds 5600 from the managed node 6770 as a function of quality of service (QOS) targets (e.g., a target throughput, a target latency, a target number of instructions per second, etc.) associated with a service level agreement for the workload (e.g., the application 6732). In doing so, the orchestrator server 6720 may receive telemetry data indicative of performance conditions (e.g., throughput, latency, instructions per second, etc.) in each sled 5600 of the managed node 6770 and compare the telemetry data to the quality of service targets to determine whether the quality of service targets are being satisfied. The orchestrator server 6720 may additionally determine whether one or more physical resources may be deallocated from the managed node 6770 while still satisfying the QoS targets, thereby freeing up those physical resources for use in another managed node (e.g., to execute a different workload). Alternatively, if the QoS targets are not presently satisfied, the orchestrator server 6720 may determine to dynamically allocate additional physical resources to assist in the execution of the workload (e.g., the application 6732) while the workload is executing. Similarly, the orchestrator server 6720 may determine to dynamically deallocate physical resources from a managed node if the orchestrator server 6720 determines that deallocating the physical resource would result in QoS targets still being met.

Additionally, in some examples, the orchestrator server 6720 may identify trends in the resource utilization of the workload (e.g., the application 6732), such as by identifying phases of execution (e.g., time periods in which different operations, each having different resource utilizations characteristics, are performed) of the workload (e.g., the application 6732) and pre-emptively identifying available resources in the data center 5300 and allocating them to the managed node 6770 (e.g., within a predefined time period of the associated phase beginning). In some examples, the orchestrator server 6720 may model performance based on various latencies and a distribution scheme to place workloads among compute sleds and other resources (e.g., accelerator sleds, memory sleds, storage sleds) in the data center 5300. For example, the orchestrator server 6720 may utilize a model that accounts for the performance of resources on the sleds 5600 (e.g., FPGA performance, memory access latency, etc.) and the performance (e.g., congestion, latency, bandwidth) of the path through the network to the resource (e.g., FPGA). As such, the orchestrator server 6720 may determine which resource(s) should be used with which workloads based on the total latency associated with each potential resource available in the data center 5300 (e.g., the latency associated with the performance of the resource itself in addition to the latency associated with the path through the network between the compute sled executing the workload and the sled 5600 on which the resource is located).

In some examples, the orchestrator server 6720 may generate a map of heat generation in the data center 5300 using telemetry data (e.g., temperatures, fan speeds, etc.) reported from the sleds 5600 and allocate resources to managed nodes as a function of the map of heat generation and predicted heat generation associated with different workloads, to maintain a target temperature and heat distribution in the data center 5300. Additionally or alternatively, in some examples, the orchestrator server 6720 may organize received telemetry data into a hierarchical model that is indicative of a relationship between the managed nodes (e.g., a spatial relationship such as the physical locations of the resources of the managed nodes within the data center 5300 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 6720 may determine the differences based on the telemetry data stored in the hierarchical model and factor the differences into a prediction of future resource utilization of a workload if the workload is reassigned from one managed node to another managed node, to accurately balance resource utilization in the data center 5300. In some examples, the orchestrator server 6720 may identify patterns in resource utilization phases of the workloads and use the patterns to predict future resource utilization of the workloads.

To reduce the computational load on the orchestrator server 6720 and the data transfer load on the network, in some examples, the orchestrator server 6720 may send self-test information to the sleds 5600 to enable each sled 5600 to locally (e.g., on the sled 5600) determine whether telemetry data generated by the sled 5600 satisfies one or more conditions (e.g., an available capacity that satisfies a predefined threshold, a temperature that satisfies a predefined threshold, etc.). Each sled 5600 may then report back a simplified result (e.g., yes or no) to the orchestrator server 6720, which the orchestrator server 6720 may utilize in determining the allocation of resources to managed nodes.

From the foregoing, it will be appreciated that example systems, methods, apparatus, and articles of manufacture have been disclosed that improve immersion cooling systems and/or facilitate cooling of electronic components within such cooling systems.

Example 1 includes an apparatus comprising a first chamber including a first coolant disposed therein, the first coolant having a first boiling point; and a second chamber disposed in the first chamber, the second chamber to receive an electronic component therein, the second chamber including a second coolant having a second boiling point different that the first boiling point, the second chamber to separate the electronic component and the second coolant from the first coolant.

Example 2 includes the apparatus of example 1, wherein the first boiling point is higher than the second boiling point.

Example 3 includes the apparatus of examples 1 or 2, further including a condenser disposed in the first chamber, the condenser to carry heated water in response to boiling of the first coolant; and a heat exchanger fluidly coupled to the condenser, the heat exchanger to reclaim low grade hot water from the heated water.

Example 4 includes the apparatus of any of examples 1-3, further including a second condenser disposed in the second chamber.

Example 5 includes the apparatus of any of examples 1-4, further including a dry cooler fluidly coupled to the second condenser.

Example 6 includes the apparatus of any of examples 1-5, further including a pump in communication with the dry cooler and the second condenser; a sensor disposed in the second chamber; and pump control circuitry to cause the pump to adjust a flow of fluid to the second condenser based on sensor data generated by the sensor.

Example 7 includes the apparatus of any of examples 1-6, wherein the electronic component is a first electronic component and further including a third chamber disposed in the first chamber, the third chamber including the second coolant, the third chamber to separate a second electronic component and the second coolant from the first coolant.

Example 8 includes the apparatus of any of examples 1-7, wherein the second chamber and the first chamber are fluidly coupled.

Example 9 includes the apparatus of any of examples 1-8, further including a plate coupled to an exterior surface of the second chamber, the plate to affect a flow of the first coolant in the first chamber.

Example 10 includes a method, comprising performing the following within an immersion chamber of an immersion cooling system: cooling a first semiconductor chip in a first package with a first coolant; and cooling a second semiconductor chip in a second package with a second coolant, the second package immersed in the second coolant, the second coolant having a higher boiling point that the first coolant.

Example 11 includes the method of example 10, wherein the first coolant runs through a cold plate that is coupled to the first package.

Example 12 includes the method of examples 10 or 11, wherein the first package is immersed in the first coolant, the second coolant has a lower density than the first coolant and the second coolant floats on top of the first coolant.

Example 13 includes the method of any of examples 10-12, wherein the method further comprises at least one of i) and ii) below: i) cooling the second semiconductor chip by vaporizing liquid within a sealed tube within a mass block that is thermally coupled to the second package; and ii) nucleating bubbles in the second coolant within a molded non-planar surface of a mass block that is thermally coupled to the second package.

Example 14 includes the method of any of examples 10-13, wherein the second package is disposed on an electronic circuit board and an elastic thermal interface material covers the second package such that the second package is sealed from the second coolant.

Example 15 includes the method of any of examples 10-14, further including determining that opening a lid of the immersion chamber raises a risk of dew formation within the immersion chamber; and, in response, retaining a lock that is coupled to the lid in a locked state.

Example 16 includes the method of any of examples 10-15, further including a shape memory alloy baffle within the second coolant changing its shape based on a temperature change sensed by the shape memory alloy baffle, the changing of the shape of the shape memory alloy baffle changing fluid flow of the second coolant within the immersion chamber.

Example 17 includes the method of any of examples 10-16, further comprising an item of equipment immersed in the second coolant, the item of equipment having a depth dimension of 14″ or less, a width dimension of 14″ or less and a thickness dimension of 3.5″ or less, the item of equipment to operate within a disaggregated computing environment.

Example 18 includes an apparatus comprising a heat exchanger; an immersion tank, the immersion tank including a cooling fluid, the immersion tank to sealingly separate the cooling fluid from the heat exchanger; and a chassis, the heat exchanger and the immersion tank carried by the chassis, the heat exchanger supported by a first surface of the chassis, the immersion tank spaced apart from the first surface of the chassis.

Example 19 includes the apparatus of example 18, further including a fan carried by the chassis.

Example 20 includes the apparatus of examples 18 or 19, further including a power source carried by the chassis.

Example 21 includes the apparatus of any of examples 18-20, further including a first pump fluidly coupled to the heat exchanger and the immersion tank, the first pump carried by the chassis.

Example 22 includes the apparatus of any of examples 18-21, further including a second pump fluidly coupled to the heat exchanger and the immersion tank, the second pump carried by the chassis.

Example 23 includes a system comprising a heat exchanger; an immersion tank; a pump fluidly coupled to the immersion tank and the heat exchanger, the pump to provide for a flow of fluid from the immersion tank to the heat exchanger; a chassis, the heat exchanger and the immersion tank carried by the chassis, the immersion tank to sealingly separate the fluid in the immersion tank from the heat exchanger; and a fan, the fan to cause air to circulate in the chassis relative to the heat exchanger to cool the fluid flowing through the heat exchanger.

Example 24 includes the system of example 23, wherein the fan is carried by the chassis.

Example 25 includes the system of examples 23 or 24, wherein the heat exchanger is supported by a first surface of the chassis and the immersion tank is spaced apart from the first surface.

Example 26 includes the system of any of examples 23-25, wherein the heat exchanger and the chassis are supported by a first surface of the chassis.

Example 27 includes the system of any of examples 23-26, further including a power source carried by the chassis.

Example 28 includes an apparatus comprising a chassis; a heat exchanger carried by the chassis; and an immersion tank carried by the chassis and fluidly coupled to the heat exchanger, a first plane extending longitudinally through the heat exchanger parallel to a second plane extending longitudinally through the immersion tank.

Example 29 includes the apparatus of example 28, wherein the chassis includes an inlet and an outlet and further including a fan carried by the chassis, the fan to draw air into the chassis via the inlet, the air to circulate relative to the heat exchanger.

Example 30 includes the apparatus of examples 28 or 29, further including a power source carried by the chassis.

Example 31 includes the apparatus of any of examples 28-30, further including a pump carried by the chassis, the pump fluidly coupled to the immersion tank and the heat exchanger.

Example 32 includes the apparatus of any of examples 28-32, wherein a first electronic component is to be disposed in the immersion tank and the chassis is to support a second electronic component external to the immersion tank.

Example 33 includes an apparatus comprising a rack mountable item of equipment comprising: i) a chassis; ii) an immersion chamber within the chassis; iii) electronics within the immersion chamber; and iv) a heat exchanger within the chassis, the heat exchanger fluidically coupled to the immersion chamber.

Example 34 includes the apparatus of example 33, wherein the rack mountable item of equipment further comprises fans, the fans to draw air through the heat exchanger.

Example 35 includes the apparatus of examples 33 or 34, wherein the immersion chamber and the heat exchanger reside at different vertical levels within the chassis.

Example 36 includes the apparatus of any of examples 33-35, wherein the rack mountable item of equipment has a 2U thickness or greater.

Example 37 includes the apparatus of any of examples 33-36, wherein the immersion chamber and heat exchanger share space on a same vertical level of the rack mountable item of equipment.

Example 38 includes the apparatus of any of examples 33-37, wherein the rack mountable item of equipment has a 1U thickness.

Example 39 includes the apparatus of any of examples 33-38, further comprising second electronics that are within the chassis but are not within the immersion chamber.

Example 40 includes an apparatus comprising memory; instructions; and processor circuitry to execute the instructions to determine a dew point of air in an ambient environment relative to an immersion tank based on sensor data indicative of humidity and temperature of the air in the ambient environment; cause a lock to move from a locked state to an unlocked state when a temperature of cooling fluid in the immersion tank is higher than the dew point, the lock to provide access to the immersion tank; and maintain the lock in the locked state when the temperature of the cooling fluid is less than the dew point.

Example 41 includes the apparatus of example 40, wherein the lock is coupled to the immersion tank.

Example 42 includes the apparatus of examples 40 or 41, wherein the lock is associated with an environment in which the immersion tank is located.

Example 43 includes the apparatus of any of examples 40-42, wherein in response to the temperature of the cooling fluid being less than the dew point, the processor circuitry is to cause an operational state of a pump communicatively coupled to the immersion tank to be adjusted.

Example 44 includes the apparatus of any of examples 40-43, wherein the processor circuitry is to cause the operational state of the pump to move to a disabled state; monitor a time for which the pump is in the disabled state; and cause the operational state of the pump to move to an activated state based on the time for which the pump is in the disabled state.

Example 45 includes the apparatus of any of examples 40-44, wherein in response to the temperature of the cooling fluid being less than the dew point, the processor circuitry is to cause a heater disposed in the immersion tank to activate.

Example 46 includes the apparatus of any of examples 40-45, wherein in response to the temperature of the cooling fluid being less than the dew point, the processor circuitry is to cause an operational state of a temperature control device in the ambient environment to be adjusted.

Example 47 includes the apparatus of any of examples 40-46, wherein in response to the temperature of the cooling fluid being less than the dew point, the processor circuitry is to: estimate a time for the temperature of the cooling fluid to be higher than the dew point; and output a notification for presentation including the estimated time.

Example 48 includes the apparatus of any of examples 40-47, wherein when the lock is in the unlocked state, the processor circuitry is to detect a change in one or more of the temperature of the cooling fluid or the dew point; and output an alert for presentation based on the detection of the change.

Example 49 includes the apparatus of any of examples 40-48, wherein the processor circuitry is to receive a user input to cause the lock to move to the unlocked state when the temperature of the cooling fluid is less than the dew point; and cause the lock to move to the unlocked state in response to the user input.

Example 50 includes an apparatus comprising interface circuitry to receive a request to unlock an immersion tank; and processor circuitry including one or more of at least one of a central processing unit, a graphic processing unit, or a digital signal processor, the at least one of the central processing unit, the graphic processing unit, or the digital signal processor having control circuitry to control data movement within the processor circuitry, arithmetic and logic circuitry to perform one or more first operations corresponding to instructions, and one or more registers to store a result of the one or more first operations, the instructions in the apparatus; a Field Programmable Gate Array (FPGA), the FPGA including logic gate circuitry, a plurality of configurable interconnections, and storage circuitry, the logic gate circuitry and interconnections to perform one or more second operations, the storage circuitry to store a result of the one or more second operations; or Application Specific Integrate Circuitry (ASIC) including logic gate circuitry to perform one or more third operations; the processor circuitry to perform at least one of the first operations, the second operations, or the third operations to instantiate: dew point calculating circuitry to, in response to the request, determine a dew point of air in an ambient environment relative to the immersion tank based on sensor data indicative of humidity and temperature of the air; monitoring circuitry to perform a comparison of the dew point to a temperature of cooling fluid in the immersion tank; access determining circuitry to: in response to the temperature of the cooling fluid being higher than the dew point, cause a lock to move from a locked state to an unlocked state, the lock to provide access to the immersion tank; and in response to the temperature of the cooling fluid being less than the dew point, maintain the lock in the locked state.

Example 51 includes the apparatus of example 50, wherein the processor circuitry to perform at least one of the first operations, the second operations, or the third operations to instantiate alert generating circuitry to, in response to the temperature of the cooling fluid being less than the dew point, output a notification for presentation, the notification including an estimated time for the temperature of the cooling fluid to be higher than the dew point.

Example 52 includes an apparatus comprising an immersion cooling system comprising an immersion chamber having a lid, the immersion cooling system further comprising a lock coupled to the lid, the immersion cooling system further comprising electronic circuitry to determine that opening the lid raises a risk of dew formation within the immersion chamber, the electronic circuitry to cause the lock to remain in a locked state in response to the determination.

Example 53 includes the apparatus of example 52, wherein, also in response to the determination that opening the lid raises a risk of dew formation within the immersion chamber, the electronic circuitry is further to cause the immersion cooling system to reduce cooling of a coolant within the immersion chamber and then release the lock from its locked state when the risk is reduced.

Example 54 includes the apparatus of examples 52 or 53, wherein the lock has a manual override function.

Example 55 includes a server comprising a first sled, the first sled including a central processing unit; a second sled, the second sled including a memory device; and a third sled, each of the first sled, the second sled, and the third having a first end and a second end opposite the first end, the first end of each of the first sled, the second sled, and the third sled including a connector to communicatively couple with a power source when the server is disposed in an immersion tank, a second end of one or more of the first sled, the second sled, or the third sled including a second connector to provide for an input/output connection external to the server, each of the first sled, the second sled, and the third sled independently removable from the immersion tank.

Example 56 includes the server of example 55, wherein the third sled includes an accelerator.

Example 57 includes the server of examples 55 or 56, further including a network interface card coupled to the second connector of the first sled.

Example 58 includes the server of any of examples 55-57, wherein the first sled is communicatively coupled to the second sled via a cable.

Example 59 includes the server of any of examples 55-58, wherein the first sled includes a liquid metal socket.

Example 60 includes a system comprising an immersion tank; a power source disposed in the immersion tank; and a server disposed in the immersion tank, the server including a first sled, a second sled, and a third sled, a first end of each of the first sled, the second sled, and the third sled including a connector to communicatively coupled with the power source, the first end proximate to a surface of the immersion tank opposite a lid of the immersion tank.

Example 61 includes the system of example 60, wherein a second end of each of the first sled, the second sled, and the third sled is proximate to a lid of the immersion tank, the second end opposite the first end.

Example 62 includes the system of examples 60 or 61, wherein the second end of one or more of the first sled, the second sled, or the third sled includes an input/output connector.

Example 63 includes the system of any of examples 60-62, wherein the first sled includes a central processing unit and the second sled includes a memory device.

Example 64 includes an apparatus comprising an item of equipment to be immersed in an immersion cooling system, the item of equipment having a depth dimension of 14″ or less, a width dimension of 14″ or less and a thickness dimension of 3.5″ or less, the item of equipment to operate within a disaggregated computing environment, the item of equipment further characterized by one of i), ii) and iii) below: i) the item of equipment being a compute item of equipment comprising a CPU; ii) the item of equipment being a memory and/or storage item of equipment and comprising an array of memory and/or non-volatile storage devices; and iii) the item of equipment being an accelerator item of equipment and comprising an accelerator semiconductor chip.

Example 65 includes the apparatus of example 64, where the item of equipment is characterized by ii) above and the memory and/or non-volatile storage devices have exposed communication interfaces on their respective packages to which respective cables are to be connected to communicate with the memory and/or non-volatile storage devices.

Example 66 includes the apparatus of examples 64 or 65, wherein the item of equipment is characterized by iii) above and the accelerator semiconductor chip is mounted on an Open Compute Project Accelerator Module (OAM).

Example 67 includes an immersion cooling system comprising a tank; a first cooling liquid disposed in the tank, a first electronic component to be immersed in and cooled by the first cooling liquid; and a second cooling liquid disposed in the tank, the first and second cooling liquids immiscible relative to one another, a second electronic component to be immersed in and cooled by the second cooling liquid.

Example 68 includes the immersion cooling system of example 67, wherein the first cooling liquid has a first density, and the second cooling liquid has a second density, the first density greater than the second density such that the second cooling liquid floats on top of the first cooling liquid.

Example 69 includes the immersion cooling system of examples 67 or 68, wherein the first cooling liquid has a first boiling temperature, and the second cooling liquid has a second boiling temperature, the first cooling temperature lower than the second boiling temperature, the first boiling temperature below an operating temperature of the first electronic component such that the first cooling liquid is to boil in response to heat generated by the first electronic component when in operation.

Example 70 includes the immersion cooling system of any of examples 67-69, wherein the second cooling liquid is to have a bulk temperature during operation that is above a condensing temperature of the first cooling liquid.

Example 71 includes the immersion cooling system of any of examples 67-70, wherein the second cooling liquid is to have a bulk temperature during operation that is below a condensing temperature of the first cooling liquid.

Example 72 includes the immersion cooling system of any of examples 67-71, wherein the bulk temperature of the second cooling liquid and a depth of the second cooling liquid are such that a majority of vapor from the boiling of the first cooling liquid condenses in the second cooling liquid before rising to a vapor space above the second cooling liquid.

Example 73 includes the immersion cooling system of any of examples 67-72, wherein the second cooling liquid is to remain in liquid form regardless of whether the first cooling liquid boils.

Example 74 includes the immersion cooling system of any of examples 67-73, wherein the second electronic components are associated with a circuit board that is positioned at a non-vertical angle above the first electronic components.

Example 75 includes the immersion cooling system of any of examples 67-74, wherein the first electronic component is to dissipate more heat than the second electronic component.

Example 76 includes the immersion cooling system of any of examples 67-75, further including a cooling element within the tank.

Example 77 includes the immersion cooling system of any of examples 67-76, wherein the cooling element is disposed within a vapor space in the tank above the second cooling liquid.

Example 78 includes the immersion cooling system of any of examples 67-77, wherein there is no cooling element within the second cooling liquid.

Example 79 includes the immersion cooling system of any of examples 67-78, wherein the cooling element is disposed within the second cooling liquid.

Example 80 includes the immersion cooling system of any of examples 67-79, wherein the cooling element is disposed within the first cooling liquid.

Example 81 includes the immersion cooling system of any of examples 67-80, further including tubing to be fluidly coupled to the tank, the tubing to facilitate replenishment of at least one of the first cooling liquid or the second cooling liquid within the tank.

Example 82 includes a method comprising placing a first cooling liquid in a tank, the first cooling liquid having a first density; placing a second cooling liquid in a tank, the second cooling liquid having a second density; immersing a first electronic component in the first cooling liquid, the first cooling liquid to cool the first electronic component based on two-phase immersion cooling; and immersing a second electronic component in the second cooling liquid, the first cooling liquid to cool the first electronic component based on single-phase immersion cooling.

Example 83 includes the method of example 82, further including maintaining a bulk operating temperature of the second cooling liquid above a condensing temperature of the first cooling liquid.

Example 84 includes the method of examples 82 or 83, further including maintaining a bulk operating temperature of the second cooling liquid below a condensing temperature of the first cooling liquid.

Example 85 includes an apparatus comprising an immersion cooling system comprising a first coolant and a second coolant, at least the second coolant being an immersion coolant, the second coolant having a higher boiling point than the first coolant.

Example 86 includes the apparatus of example 85 wherein the first coolant is an immersion coolant and the second coolant is less dense than the first coolant and wherein the second coolant floats on top of the first coolant.

Example 87 includes the apparatus of examples 85 or 86 wherein a cooling element is immersed within the second coolant.

Example 88 includes the apparatus of any of examples 85-87, wherein a first semiconductor chip in a first package is cooled with the first coolant and a second semiconductor chip in a second package is cooled with the second coolant.

Example 89 includes the apparatus of any of examples 85-88, wherein the first semiconductor chip dissipates more power than the second semiconductor chip.

Example 90 includes an immersion cooling system comprising an electronic component to be cooled by an immersion cooling liquid; and a baffle including at least one of a memory alloy or a multi-metallic strip, the at least one of the memory alloy or the multi-metallic strip to change shape in response to a change in an amount of heat dissipated by the electronic component, the change in shape to cause a change in flow of the cooling liquid passed the electronic component.

Example 91 includes the immersion cooling system of example 90, wherein the baffle includes the memory alloy.

Example 92 includes the immersion cooling system of examples 90 or 19, wherein the baffle includes the multi-metallic strip.

Example 93 includes the immersion cooling system of any of examples 90-92, wherein the at least one of the memory alloy or the multi-metallic strip is downstream from the electronic component in a direction of flow of the cooling liquid.

Example 94 includes the immersion cooling system of any of examples 90-93, wherein the at least one of the memory alloy or the multi-metallic strip is upstream from the electronic component in a direction of flow of the cooling liquid, the immersion cooling system further including a conductive material to thermally couple the at least one of the memory alloy or the multi-metallic strip to at least one of the electronic component or the cooling liquid at a point downstream from the electronic component.

Example 95 includes the immersion cooling system of any of examples 90-94, further including a server chassis, the electronic component within the server chassis, the baffle coupled to the server chassis.

Example 96 includes the immersion cooling system of any of examples 90-95, further including a circuit board to carry the electronic component and to carry the baffle.

Example 97 includes the immersion cooling system of any of examples 90-96, wherein the baffle includes a support wall to define a channel for the cooling liquid; and a flap coupled to the support wall, the flap to move relative to the support wall based on the change in shape of the at least one of the memory alloy or the multi-metallic strip.

Example 98 includes the immersion cooling system of any of examples 90-97, wherein the support wall extends away from the circuit board beyond an outward facing surface of the electronic component.

Example 99 includes the immersion cooling system of any of examples 90-98, wherein the support wall extends at least half a length of an edge of the electronic component.

Example 100 includes the immersion cooling system of any of examples 90-99, wherein the baffle is a first baffle, and the support wall is a first support wall, the immersion cooling system including a second baffle having a second support wall, the first and second support walls on opposite sides of the electronic component.

Example 101 includes the immersion cooling system of any of examples 90-100, further including a cross beam extending between the first and second support walls, the channel to extend between the electronic component and the cross beam.

Example 102 includes an apparatus comprising an immersion cooling system comprising a shape memory alloy baffle to change fluid flow within an immersion cooling chamber of the immersion cooling system based on a temperature change sensed by the shape memory alloy baffle.

Example 103 includes an apparatus comprising a circuit board; an electronic component carried by the circuit board; and a thermal interface material in contact with the circuit board around the electronic component, the thermal interface material to cover the electronic component.

Example 104 includes the apparatus of example 103, wherein the thermal interface material extends between the circuit board and the electronic component.

Example 105 includes the apparatus of examples 103 or 104, wherein the electronic component is one of a plurality of electronic components carried by the circuit board, the thermal interface material to encapsulate the plurality of electronic components.

Example 106 includes the apparatus of any of examples 103-105, wherein the circuit board and the electronic components are parts of a dual in-line memory module to be selectively inserted into a socket adjacent a cold plate, the thermal interface material dimensioned to extend from the electronic components to the cold plate without an anti-scratch film between the thermal interface material and the electronic components.

Example 107 includes the apparatus of any of examples 103-106, wherein the electronic component is one of a plurality of electronic components carried by the circuit board, the thermal interface material to be spaced apart from different ones of the plurality of electronic components.

Example 108 includes the apparatus of any of examples 103-107, wherein the circuit board is to be immersed in an immersion cooling fluid, the thermal interface material to separate the electronic component from the immersion cooling fluid.

Example 109 includes the apparatus of any of examples 103-108, wherein the thermal interface material does not include indium.

Example 110 includes the apparatus of any of examples 103-109, further including a heat sink disposed on an exterior surface of the thermal interface material, the electronic component positioned between the circuit board and the heat sink, the thermal interface material positioned between the electronic component and the heat sink.

Example 111 includes the apparatus of any of examples 103-110, wherein the electronic component is a first electronic component, the apparatus further including a second electronic component carried by the circuit board, the second electronic component distinct from and spaced apart from the first electronic component, the second electronic component positioned between the circuit board and the heat sink.

Example 112 includes the apparatus of any of examples 103-111, wherein the thermal interface material is clastic.

Example 113 includes the apparatus of any of examples 103-112, wherein the thermal interface material is a cured thermal gel material.

Example 114 includes an apparatus comprising an electronic circuit board; one or more packaged semiconductor chips disposed on the electronic circuit board; and, an clastic thermal interface material covering the one or more packaged semiconductor chips such that the one or more packaged semiconductor chips are sealed from the electronic circuit board's environment.

Example 115 includes the apparatus of example 114, wherein the electronic circuit board and the one or more packaged semiconductor chips are components of a dual in-line memory module.

Example 116 includes the apparatus of example 115, wherein the electronic circuit board is to be immersed in an immersion cooling system.

Example 117 includes an apparatus comprising a main body for a boiler plate in an immersion cooling system assembly, the main body having a first surface and a second surface opposite the first surface, the first surface to be thermally coupled to an integrated circuit chip, the second surface including irregularities to promote boiling of a cooling fluid when the boiler plate is immersed in the cooling fluid; and a protrusion positioned on and extending away from the second surface, both the protrusion and the irregularities integrally formed with the main body.

Example 118 includes the apparatus of example 117, wherein the protrusion is a pin extending transverse to the second surface.

Example 119 includes the apparatus of examples 117 or 118, wherein the pin is a first pin in a pin fin array on the second surface.

Example 120 includes the apparatus of any of examples 117-119, wherein the protrusion has a different porosity than the main body.

Example 121 includes the apparatus of any of examples 117-120, wherein the protrusion has a first porosity along an exposed exterior surface of the protrusion, and a second porosity within a core of the protrusion.

Example 122 includes the apparatus of any of examples 117-121, wherein a first porosity of the main body at the first surface is different than a second porosity of the main body at the second surface.

Example 123 includes the apparatus of any of examples 117-122, wherein the irregularities correspond to micro-pores between discrete particles of metal bonded together.

Example 124 includes the apparatus of any of examples 117-123, wherein the boiler plate does not include a bonding material to position the irregularities on the second surface of the main body.

Example 125 includes the apparatus of any of examples 117-124, wherein the main body includes a base and a lid, the apparatus further including a heat pipe enclosed between the base and the lid.

Example 126 includes a boiler plate, comprising a first surface to face toward a semiconductor die, the first surface to be thermally coupled to the semiconductor die to draw heat away from the semiconductor die when the semiconductor die is in operation; a second surface to face away from the semiconductor die to interface with a two-phase immersion cooling fluid; and a base extending between the first and second surfaces, the base including a first region adjacent the first surface and a second region adjacent the second surface, the first region having a first porosity and the second region having a second porosity, the second porosity higher than the first porosity.

Example 127 includes the boiler plate of example 126, wherein the first region has a first thickness, and the second region has a second thickness, the second thickness smaller than the first thickness.

Example 128 includes the boiler plate of examples 126 or 127, wherein the second surface is non-planar.

Example 129 includes the boiler plate of any of examples 126-128, wherein the second surface is non-planar due to three-dimensional features protruding from the second surface.

Example 130 includes the boiler plate of any of examples 126-129, further including a protrusion extending out of a baseline surface of the second surface, the protrusion having a third porosity, the third porosity different than the first porosity and different than the second porosity.

Example 131 includes the boiler plate of any of examples 126-130, wherein the first surface, the second surface, the base, and the protrusion are integrally formed through a metal injection molding process.

Example 132 includes the boiler plate of any of examples 126-131, wherein the second surface includes irregularities that promote boiling of the immersion cooling fluid, the irregularities included on the second surface without attachment of a separate material to that of the base.

Example 133 includes an apparatus comprising a solid mass block of an immersion cooled cooling assembly, the solid mass block including at least one of i) or ii) below: i) a sealed tube within the solid mass block, the sealed tube comprising fluid so that two-phase cooling occurs within the sealed tube; and ii) a molded non-planar surface to be exposed to an immersion coolant.

Example 134 includes the apparatus of example 133, wherein the solid mass block includes i) and ii) above.

Example 135 includes the apparatus of examples 133 or 134, wherein the solid mass block includes ii) above, the molded non-planar surface being porous.

Example 136 includes the apparatus of any of examples 133-135, further including pins extending from the porous non-planar molded surface.

Example 137 includes an apparatus comprising a base for a boiler plate in an immersion cooling system assembly, the base a first surface and a second surface opposite the first surface, the first surface to be thermally coupled to an integrated circuit chip, the second surface including a recessed opening; a heat pipe disposed within the recessed opening; and a lid having a third surface and a fourth surface opposite the third surface, the third surface to bond with the second surface around the heat pipe to enclose the heat pipe between the base and the lid.

Example 138 includes the apparatus of example 137, further including: first solder between the base and the heat pipe; and second solder between the heat pipe and the lid.

Example 139 includes the apparatus of examples 137 or 138, wherein the second solder has a lower melting temperature than the first solder.

Example 140 includes the apparatus of any of examples 137-140, wherein the lid is a sheet of metal foil.

Example 141 includes the apparatus of any of examples 135-138, wherein the heat pipe includes a planar surface that is positioned substantially flush with the second surface of the base.

Example 142 includes the apparatus of any of examples 137-141, wherein the base has a first thickness, and the heat pipe has a second thickness, the second thickness less than half the first thickness.

Example 143 includes the apparatus of any of examples 137-142, wherein the base has a first thickness, and the heat pipe has a second thickness, the second thickness more than half the first thickness.

Example 144 includes the apparatus of any of examples 137-143, wherein the heat pipe is spaced apart from the first surface of the base.

Example 145 includes the apparatus of any of examples 137-144, further including a boiling enhancement features on the fourth surface of the lid.

Example 146 includes the apparatus of any of examples 137-145, wherein the boiling enhancement features correspond to a stack of metal meshes attached to the fourth surface.

Example 147 includes the apparatus of any of examples 137-146, wherein the boiling enhancement features correspond to micro-pores within the lid.

Example 148 includes the apparatus of any of examples 137-147, wherein the fourth surface of the lid is a non-planar molded surface.

Example 149 includes a method to manufacture a boiler plate, the method comprising providing a main body for the boiler plate, the main body to include a groove in a first surface of the main body; inserting a heat pipe within the groove; and attaching a lid to the main body to enclose the heat pipe.

Example 150 includes the method of example 149, further including attaching the heat pipe to the main body using a first solder; and attaching the lid to the main body and the heat pipe using a second solder.

Example 151 includes the method of examples 149 or 150, wherein the first solder has a higher melting temperature than the second solder.

Example 152 includes the method of any of examples 149-151, further including providing boiling enhancement features to the lid.

Example 153 includes the method of any of examples 149-152, wherein the providing of the boiling enhancement features including bonding a stack of metal meshes to the lid.

Example 154 includes the method of any of examples 149-153, wherein the providing of the boiling enhancement features includes fabricating the lid with a metal injection molding process, the boiling enhancement features corresponding to micro-pores resulting from the metal injection molding process.

Example 155 includes the method of any of examples 149-154, adding protrusions to a surface of the lid during the metal injection molding process.

Example 156 include an apparatus comprising memory; instruction; and processor circuitry to execute the instructions to identify one or more of (a) first conditions associated with a coolant of an immersion tank, a plurality of electronic components disposed in the coolant, the plurality of electronic components including one or more of memory devices, graphical processing units, or central processing units, or (b) second conditions associated with an environment in which the immersion tank is located, the second conditions different than the first conditions associated with the coolant; enable access to the at least one of the immersion tank or the environment based on the one or more of the first conditions or the second conditions; and adjust a first control device associated with the immersion tank or a second control device associated with the environment based on the enablement of the access to the at least one of the immersion tank or the environment.

Example 157 includes the apparatus of example 156, wherein the second control device includes a heater in the environment and the processor circuitry is to cause an operational state of the heater to be adjusted.

Example 158 includes the apparatus of examples 156 or 157, wherein the first control device includes a pump and the processor circuitry is to cause a flow rate associated with the pump to be adjusted.

Example 159 includes the apparatus of any of examples 156-158, wherein the first control device includes a valve operator and processor circuitry is to cause the valve operator to adjust a state of a valve to control a flow rate.

Example 160 includes the apparatus of any of examples 156-159, wherein the immersion tank includes an access port and the processor circuitry is to enable access to the immersion tank by causing a lock associated with the access port to move to an unlocked state.

Example 161 includes the apparatus of any of examples 156-160, wherein the environment includes an enclosure and the processor circuitry is to enable access to the environment by causing a lock associated with an opening of the enclosure to move to an unlocked state.

Example 162 includes the apparatus of any of examples 156-161, wherein the processor circuitry is to cause an alert to be presented via a display screen associated with at least one of the immersion tank or the environment, the alert associated with one or more of (a) the enablement of access to the at least one of the immersion tank or the environment or (b) the conditions associated with the immersion tank or the environment.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1.-46. (canceled)

47. An apparatus comprising:
a circuit board;
an electronic component carried by the circuit board; and
a thermal interface material in contact with the circuit board around the electronic component, the thermal interface material to cover the electronic component.

48. The apparatus of claim 47, wherein the thermal interface material extends between the circuit board and the electronic component.

49. The apparatus of claim 47, wherein the electronic component is one of a plurality of electronic components carried by the circuit board, the thermal interface material to encapsulate the plurality of electronic components.

50. The apparatus of claim 49, wherein the circuit board and the electronic components are parts of a dual in-line memory module to be selectively inserted into a socket adjacent a cold plate, the thermal interface material dimensioned to extend from the electronic components to the cold plate without an anti-scratch film between the thermal interface material and the electronic components.

51. The apparatus of claim 47, wherein the electronic component is one of a plurality of electronic components carried by the circuit board, the thermal interface material to be spaced apart from different ones of the plurality of electronic components.

52. The apparatus of claim 47, wherein the circuit board is to be immersed in an immersion cooling fluid, the thermal interface material to separate the electronic component from the immersion cooling fluid.

53. The apparatus of claim 47, further including a heat sink disposed on an exterior surface of the thermal interface material, the electronic component positioned between the circuit board and the heat sink, the thermal interface material positioned between the electronic component and the heat sink.

54. The apparatus of claim 53, wherein the electronic component is a first electronic component, the apparatus further including a second electronic component carried by the circuit board, the second electronic component distinct from and spaced apart from the first electronic component, the second electronic component positioned between the circuit board and the heat sink.

55. The apparatus of claim 47, wherein the thermal interface material is elastic.

56. The apparatus of claim 47, wherein the thermal interface material is a cured thermal gel material.

57.-70. (canceled)

71. An apparatus comprising:
a circuit board;
an electronic component disposed on the circuit board; and
a thermal interface material covering the electronic component such that the electronic component is sealed from an environment of the circuit board.

72. The apparatus of claim 71, wherein the circuit board and the electronic component are components of a dual in-line memory module.

73. The apparatus of claim 72, wherein the circuit board is to be immersed in an immersion cooling system.

74. The apparatus of claim 71, wherein the thermal interface material is a resiliently compliant solid.

75. The apparatus of claim 71, wherein the electronic component includes one or more packaged semiconductor chips.

76. A method comprising:
applying a thermal interface material over an electronic component on a circuit board, the thermal interface material in at least one of a liquid form or a gel form when being applied over the electronic component; and
allowing the thermal interface material to cure through a curing process, the thermal interface material to be a solid after the curing process.

77. The method of claim 76, wherein the curing process includes application of heat to the thermal interface material.

78. The method of claim 76, further including flattening the thermal interface material after the curing process through a planarization process.

79. The method of claim 76, further including attaching a heat sink to the thermal interface material after the curing process.

80. The method of claim 79, wherein the electronic component is one of a plurality of electronic components on the circuit board, the method including selectively applying the thermal interface material to encapsulate a first subset of the electronic components, the thermal interface material to be spaced apart from a second subset of the electronic components.
